(19) United States
(12) Patent Application Publication
(10) Pub. No.: US 2007/0215944 A1
(43) Pub. Date: Sep. 20, 2007

(54) SEMICONDUCTOR DEVICE

(76) Inventor: Futoshi Komatsu, Itami (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/682,473

(22) Filed: Mar. 6, 2007

(30) Foreign Application Priority Data
Mar. 6, 2006 (JP) 2006-58954

(51) Int. Cl. H01L 27/12

(52) U.S. Cl. 257/347

(57) ABSTRACT

The semiconductor device which has the resistor element which was formed in the SOI layer of an SOI substrate and suppressed the influence of leak to the minimum is obtained.

N⁺ diffusion region is selectively formed in an SOI layer, and a full isolation region is formed covering all the peripheral regions of N⁺ diffusion region. A full isolation region penetrates an SOI layer, and reaches a buried oxide film, and N⁺ diffusion region is electrically thoroughly insulated from the outside by the full isolation region. N⁺ diffusion region extends in the longitudinal direction in a drawing, and is formed in lengthwise rectangular shape in plan view. And a silicide film is formed in the front surface at the side of one end of N⁺ diffusion region, a silicide film is formed in the front surface at the side of the other end, and a metal plug is formed on a silicide film, respectively.

### CROSS-REFERENCE TO RELATED APPLICATION

The present application claims priority from Japanese patent application No. 2006-58954 filed on Mar. 6, 2006, the content of which is hereby incorporated by reference into this application.

### 1. Field of the Invention

This invention relates to the semiconductor device which has a resistor element, a capacitative element, etc. which are formed on an SOI substrate.

### 2. Description of the Background Art

The term “MOS” is used for the laminated structure of metal/oxide/semiconductor in the old days, and was having the initial of Metal-Oxide-Semiconductor taken. However, especially in the field-effect transistor which has a MOS structure (a “MOS transistor” is only called hereafter), the material of a gate insulating film or a gate electrode is improved from viewpoints of an improvement of integration or a manufacturing process in recent years etc.

For example, in a MOS transistor, polycrystalline silicon has been adopted instead of metal as a material of a gate electrode from a viewpoint of mainly forming a source/drain in self align. Although the material of a high dielectric constant is adopted as a material of a gate insulating film from a viewpoint which improves an electrical property, the material concerned is not necessarily limited to an oxide.

Therefore, the term “MOS” is not necessarily adopted limiting only to the laminated structure of metal/oxide/semiconductor, and it is not premised on such limitation on this specification, either. That is, in view of common general technical knowledge, the term “MOS” is not only as an abbreviation resulting from the origin of the word, but also has the meaning also including the laminated structure of an electric conductor/insulator/semiconductor widely here.

FIG. 92 is a cross-sectional view showing the diffusion resistance formed on a conventional bulk substrate (Si substrate 51). As shown in the same drawing, STI (shallow trench isolation) region 52 for element isolation is selectively formed in the upper layer portion of Si substrate 51 of P type, and N⁺ diffusion region 53 is formed in the upper layer portion of Si substrate 51 between STI regions 52 and 52.

Silicide region 54a is formed in the front surface of the one side end region (left-hand side of FIG. 92) of N⁺ diffusion region 53, silicide region 54b is formed in the front surface of the other side end region (right-hand side of FIG. 92), and metal plugs 55 and 55 are formed on silicide region 54a and 54b.

In such structure, N⁺ diffusion region 53 constitutes a resistor and the resistor element which used silicide region 54a as one end, and used silicide region 54b as the other end is realized.

The semiconductor device which has the resistor element (a gate electrode material is used) formed on the trench isolation insulating film as a resistor element formed on the SOI layer of an SOI substrate is disclosed by Patent Reference 1, for example.

[Patent Reference 1] Japanese Unexamined Patent Publication No. 2005-183686

### SUMMARY OF THE INVENTION

However, with the structure shown by FIG. 92, N+ diffusion region 53, and P type region of Si substrate 51 are not electrically insulated. So, there was a problem that the change of resistance and the influence of junction leak in other surrounding circuits of this resistor occurred because the junction leak between N+ diffusion region 53 and Si substrate 51 occurs.

Including above-mentioned Patent Reference 1, resistor elements which were formed in the SOI layer of an SOI substrate, and took the influence of junction leak into consideration, such as diffusion resistance, did not exist.

This invention was made in order to solve the above-mentioned problem, and aims at obtaining the semiconductor device which has the resistor element which was formed in the SOI layer of an SOI substrate and suppressed the influence of leak to the minimum.

The semiconductor device according to claim 1 concerning this invention comprises a diffusion resistance formed in an SOI layer of an SOI substrate which has a semiconductor substrate, a buried insulating film formed over the semiconductor substrate, and the SOI layer formed over the buried insulating film, wherein the diffusion resistance includes a diffusion region of a first conductivity type formed in the SOI layer; and a one side and an other side silicide films formed in a front surface of the diffusion region only in a neighboring region of a one side end and an other side end in a predetermined formation direction, respectively; wherein a region which does not have the one side and the other side silicide films in an upper layer portion in the diffusion region is specified as a resistor main part; wherein the semiconductor device further comprises a full isolation region which is formed in all regions of a peripheral region of the diffusion region by penetrating the SOI layer and which has insulation.

The semiconductor device according to claim 2 concerning this invention comprises a body resistance formed in an SOI layer of an SOI substrate which has a semiconductor substrate, a buried insulating film formed over the semiconductor substrate, and the SOI layer formed over the buried insulating film, wherein the body resistance includes a body region of a first conductivity type formed in the SOI layer; and a one side and an other side diffusion regions of a first conductivity type which is formed in the SOI layer and which is respectively formed adjoining one side and other side of a predetermined formation direction of the body region; wherein an impurity concentration of a first conductivity type of the one side and the other side diffusion regions is set up more highly than the body region; further including a one side and an other side silicide films which are formed at least in a front surface of the one side and the other side diffusion regions, and which are mutually independent; wherein a region which does not have the one side and the other side silicide films in an upper layer portion in the body region is specified as a resistor main part; wherein the semiconductor device further comprises a full isolation region which is formed in all regions of a peripheral region of the body region and the one side and the other side diffusion regions by penetrating the SOI layer and which has insulation.

The semiconductor device according to claim 10 concerning this invention comprises an MOS capacitor formed in an SOI layer of an SOI substrate which has a semiconductor substrate, a buried insulating film formed over the semiconductor substrate, and the SOI layer formed over the buried insulating film, wherein the MOS capacitor includes a capacitor electrode region of a first impurity concentration of a first conductivity type formed in the SOI layer; and a one side and an other side diffusion regions of a first conductivity type which is formed in the SOI layer, and which is formed adjoining one side and other side of a predetermined formation direction of the capacitor electrode region; wherein an impurity concentration of a first conductivity type of the one side and the other side diffusion regions is set up more highly than the first impurity concentration; further including a gate electrode formed via a gate insulating film over the capacitor electrode region; wherein the MOS capacitor is specified by the gate electrode, the gate insulating film, and the capacitor electrode region; further including a one side and an other side silicide films which are formed in a front surface of the one side and the other side diffusion regions, and which are mutually independent; and a full isolation region which is formed in all regions of a peripheral region of the capacitor electrode region and the one side and the other side diffusion regions by penetrating the SOI layer and which has insulation; wherein the capacitor electrode region has only the first impurity concentration in a region of a bottom of the gate electrode, and its neighboring region.

As for the semiconductor device according to claim 1 in this invention, the full isolation region which is formed by penetrating the SOI layer and which has insulation is formed in all the regions of the peripheral region of the diffusion region which forms a resistor main part, and, as for the lower part of a diffusion region, the buried insulating film is formed. Therefore, since a diffusion region is thoroughly insulated from the outside, the effect that the leak from the diffusion region can be suppressed effectively is performed.

The effect that the resistance increase of a resistor main part becomes possible is performed by forming the one side and the other side silicide films only in the portion in the front surface of a diffusion region (one side end and the other side end neighboring region).

As for the semiconductor device according to claim 2 in this invention, the full isolation region which is formed by penetrating an SOI layer and which has insulation is formed in all the regions of the peripheral region of the body region which forms a resistor main part, and, as for the lower part of the body region, the buried insulating film is formed. Therefore, since a body region is thoroughly insulated from the outside, the effect that the leak from a body region can be suppressed effectively is performed.

The effect that the resistance increase of a resistor main part can carry out comparatively easily is performed by making a body region into a resistor main part.

As for the semiconductor device according to claim 10 in this invention, the full isolation region which is formed by penetrating the SOI layer and which has insulation is formed in all the regions of the peripheral region of the capacitor electrode region which forms an MOS capacitor, and, as for the lower part of the capacitor electrode region, the buried insulating film is formed. Therefore, since a capacitor electrode region is thoroughly insulated from the outside, the effect that the leak from the capacitor electrode region can be suppressed effectively is performed.

In the region of the bottom of the gate electrode, and its neighboring region, since the capacitor electrode region has only the first impurity concentration, the effect that a capacitance value can be set up with sufficient accuracy is performed.

### BRIEF DESCRIPTION OF THE DRAWINGS

FIG. 1 is a plan view showing the structure of the semiconductor device which is Embodiment 1 of this invention;

FIG. 2 is a cross-sectional view showing the A-A section of FIG. 1;

FIG. 3 is a cross-sectional view showing the B-B section of FIG. 1;

FIG. 4 is a plan view showing the size characteristics of the semiconductor device of Embodiment 1;

FIG. 5 is an explanatory diagram showing the size characteristics of width LX and length LY in N⁺ diffusion region of Embodiment 1 according to tabular form;

FIG. 6 is a plan view showing the structure of the semiconductor device which is Embodiment 2 of this invention;

FIG. 7 is a cross-sectional view showing the C-C section of FIG. 6;

FIG. 8 is a cross-sectional view showing the D-D section of FIG. 6;

FIG. 9 is a cross-sectional view showing other modes of Embodiment 2;

FIG. 10 is a plan view showing the size characteristics of the semiconductor device of Embodiment 2;

FIG. 11 is a plan view showing the structure of the semiconductor device which is Embodiment 3 of this invention;

FIG. 12 is a cross-sectional view showing the E-E section of FIG. 11;

FIG. 13 is a cross-sectional view showing the F-F section of FIG. 11;

FIG. 14 is a plan view showing the size characteristics of the semiconductor device of Embodiment 3;

FIG. 15 is a cross-sectional view showing other modes of the semiconductor device of Embodiment 3;

FIG. 16 is a plan view showing the structure of the semiconductor device which is Embodiment 4 of this invention;

FIG. 17 is a cross-sectional view showing the G-G section of FIG. 16;

FIG. 18 is a cross-sectional view showing other modes of the semiconductor device of Embodiment 4;

FIG. 19 is an explanatory diagram showing the concept of an MOS capacitor;

FIG. 20 is a graph which shows the relation between gate voltage Vg and capacitance value Cg in a usual MOS capacitor and a capacitor dope MOS capacitor;

FIG. 21 is a cross-sectional view showing an element isolation region forming step common to Embodiment 1-Embodiment 4;

FIGS. 22 to 29 are cross-sectional views showing an element isolation region forming step;

FIGS. 30 to 35 are cross-sectional views showing the manufacturing process of the diffusion resistance of Embodiment 1;

FIGS. 36 to 45 are cross-sectional views showing the manufacturing process of the basic constitution of body resistance of Embodiment 2;

FIG. 46 is a cross-sectional view showing a part of manufacturing process of other modes of body resistance of Embodiment 2;

FIGS. 47 to 49 are cross-sectional views showing the manufacturing process of the first structure of the body resistance with a gate electrode of Embodiment 3;

FIGS. 50 to 51 are cross-sectional views showing a part of manufacturing process of the second mode of the body resistance with a gate electrode of Embodiment 3;

FIG. 52 is a cross-sectional view showing the manufacturing process of the capacitor dope MOS capacitor which are other modes of the MOS capacitor of Embodiment 4;

FIGS. 53 to 55 are cross-sectional views showing the manufacturing process of other modes of the MOS capacitor of Embodiment 4;

FIG. 56 is a cross-sectional view showing the structure of the semiconductor device which formed diffusion resistance with two or more sorts of transistors on the conventional bulk substrate;

FIG. 57 is a cross-sectional view showing the structure of the semiconductor device which formed the diffusion resistance of Embodiment 1 with two or more sorts of transistors;

FIG. 58 is an explanatory diagram showing the variation of the resistance in the case of forming body region 21 of body resistance of Embodiment 2 using a Well mask and a CD mask according to tabular form;

FIG. 59 is a plan view showing the semiconductor device which is an application of Embodiment 2;

FIG. 60 is a cross-sectional view showing the H-H section of FIG. 59;

FIGS. 61 to 82 are cross-sectional views showing the forming step of two or more sorts of transistors;

FIG. 83 is a plan view showing the first example of the layout pattern of the semiconductor device which has the diffusion resistance of Embodiment 1 etc.;

FIG. 84 is a cross-sectional view showing the I-I section of FIG. 83;

FIG. 85 is a cross-sectional view showing the J-J section of FIG. 83;

FIG. 86 is a plan view showing the second example of the layout pattern of the semiconductor device which has the diffusion resistance of Embodiment 1 etc.;

FIG. 87 is a cross-sectional view showing the K-K section of FIG. 86;

FIG. 88 is a cross-sectional view showing the L-L section of FIG. 86;

FIG. 89 is a plan view showing the third example of the layout pattern of the semiconductor device which has the diffusion resistance of Embodiment 1 etc.;

FIG. 90 is a cross-sectional view showing the M-M section of FIG. 89;

FIG. 91 is a cross-sectional view showing the L-L section of FIG. 89; and

FIG. 92 is a cross-sectional view showing the diffusion resistance formed on a conventional bulk substrate.

### DETAILED DESCRIPTION OF THE PREFERRED EMBODIMENTS

### Embodiment 1

### (Basic Constitution)

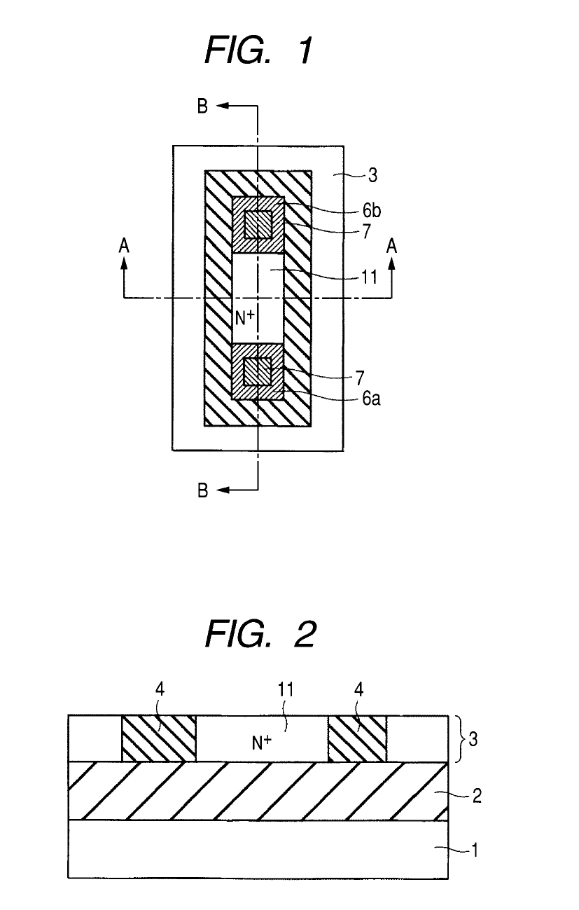

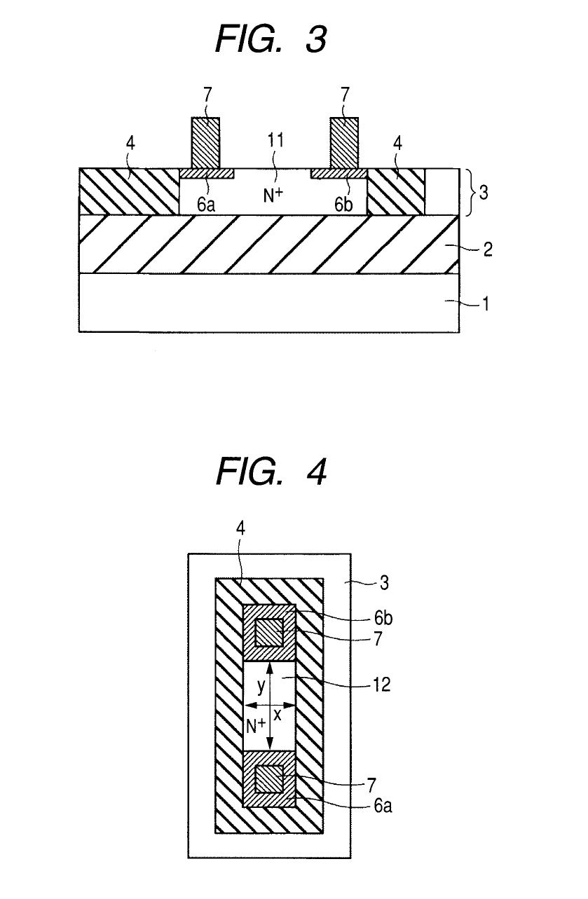

FIG. 1 is a plan view showing the structure of the semiconductor device which is Embodiment 1 of this invention, FIG. 2 is a cross-sectional view showing the A-A section of FIG. 1, and FIG. 3 is a cross-sectional view showing the B-B section of FIG. 1. The semiconductor device of Embodiment 1 has diffusion resistance inside.

As shown in these drawings, buried oxide film 2 is formed on supporting substrates 1, such as a Si substrate, and SOI layer 3 is formed on buried oxide film 2. An SOI substrate is formed by these supporting substrate 1, buried oxide film 2, and SOI layer 3.

N⁺ diffusion region 11 is selectively formed in SOI layer 3, and full isolation region 4 is formed covering all the peripheral regions of N⁺ diffusion region 11 in plan view. Full isolation region 4 penetrates SOI layer 3, and reaches buried oxide film 2, and N⁺ diffusion region 11 is electrically thoroughly insulated from the outside by full isolation region 4.

N⁺ diffusion region 11 is extended and formed in the Y direction (the longitudinal direction of FIG. 1: the predetermined formation direction), and plan view form is formed in rectangular shape. And silicide film 6a (one side silicide film) is formed in the front surface at the side of the Y direction end of N⁺ diffusion region 11 (one side end neighboring region). Silicide film 6b (other side silicide film) is formed in the front surface at the side of the Y direction other end of N⁺ diffusion region 11 (other side end neighboring region). Metal plugs 7 and 7 are formed on silicide film 6a and 6b, respectively.

In the diffusion resistance of Embodiment 1 of such structure, N⁺ diffusion region 11 constitutes a resistor, the region in N⁺ diffusion region 11 which does not have silicide films 6a and 6b in an upper layer portion is specified as a resistor main part, and the resistor element which used silicide film 6a as one end, and used silicide film 6b as the other end is realized.

Thus, as for the diffusion resistance of Embodiment 1, full isolation region 4 is formed in all the peripheral regions of N⁺ diffusion region 11, and, as for the lower layer of N⁺ diffusion region 11, buried oxide film 2 exists. Therefore, N⁺ diffusion region 11 is thoroughly insulated from the outside, and the effect which can suppress effectively the leak from N⁺ diffusion region 11 which has a resistor main part is performed.

The effect that resistance increase becomes possible as a resistor element is performed by forming silicide films 6a and 6b only in the portion in the front surface of N⁺ diffusion region 11 (a one end side, the other end side).

### (Size Characteristics)

FIG. 4 is a plan view showing the size characteristics of the semiconductor device of Embodiment 1. As shown in the same drawing, as for the resistor main part of N⁺ diffusion region 11, plan view form is assuming rectangular shape. The plan view form is specified as width LX (first length) which is the length of the X direction (the horizontal direction of FIG. 4; first direction) with length LY (second length) which is the length of the Y direction (the longitudinal direction of FIG. 4; second direction) of the rectangular shape which is the plan view form of the above-mentioned resistor main part.

When forming a transistor, a resistor element, etc. on an SOI substrate, it is necessary to take the size variation of each process into consideration. For example, when manufacturing logical circuits, such as MPU, gate electrode length becomes a minimum dimension in many cases. Here, it is assumed that the process variation of ±15% existed to minimum dimension length.

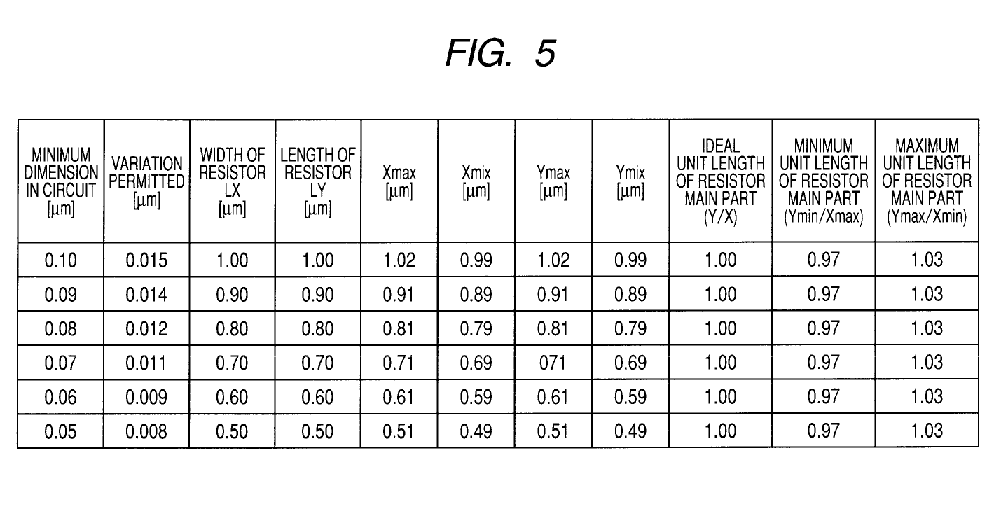

FIG. 5 is an explanatory diagram showing the size characteristics by width LX and length LY of the resistor main part in N⁺ diffusion region 11 according to tabular form. The maximum value (Ymax/Xmin) and the minimum value (Ymin/Xmax) of unit length (LY/LX) of the resistor main part of N⁺ diffusion region 11 in the case where the variation (Xmax (maximum) and Xmin (minimum) about LX, Ymax (maximum) and Ymin (minimum) about LY) in the upper and lower limit (15%) of a process is taken into consideration to width LX and length LY when the minimum dimension of a circuit is set as 0.05 □m from 0.1 □m in FIG. 5 are shown.

As shown in FIG. 5, change of the unit length of the resistor main part in N⁺ diffusion region 11 which is a resistor, i.e., change of resistance, can be stored within the limits of ±3% by making width LX into the length of 10 times of a minimum dimension in a circuit, and setting up length LY identically to width LX.

Therefore, in the semiconductor device of Embodiment 1, by setting width LX of the resistor main part in N⁺ diffusion region 11 as 10 or more times of the minimum dimension of a circuit, and setting up length LY more than width LX, the effect that N⁺ diffusion region 11 which is a resistor which hardly receives the influence of resistance by the variation in a process can be obtained is performed.

In Embodiment 1, although N⁺ diffusion region 11 was shown as a resistor, the same effect is performed even if the diffusion region of a P type is made a resistor.

### Embodiment 2

### (Basic Constitution)

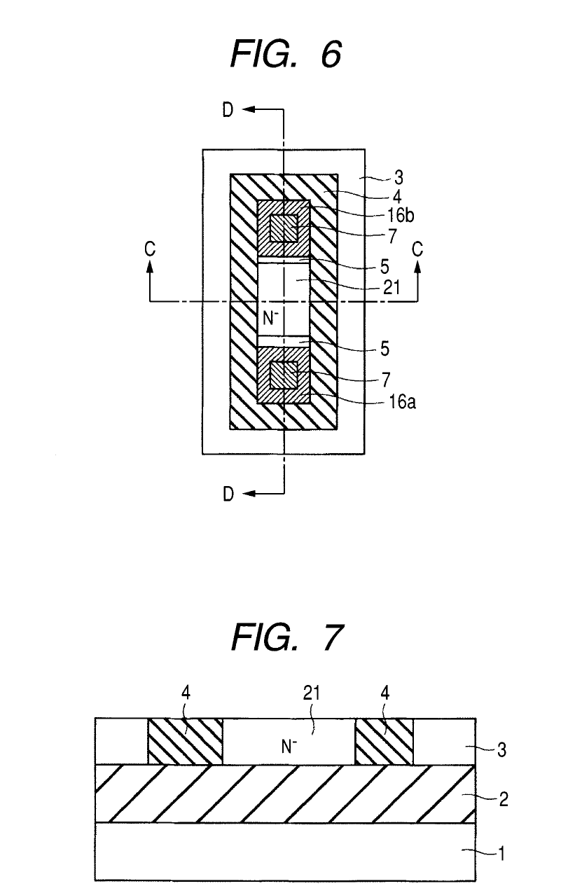

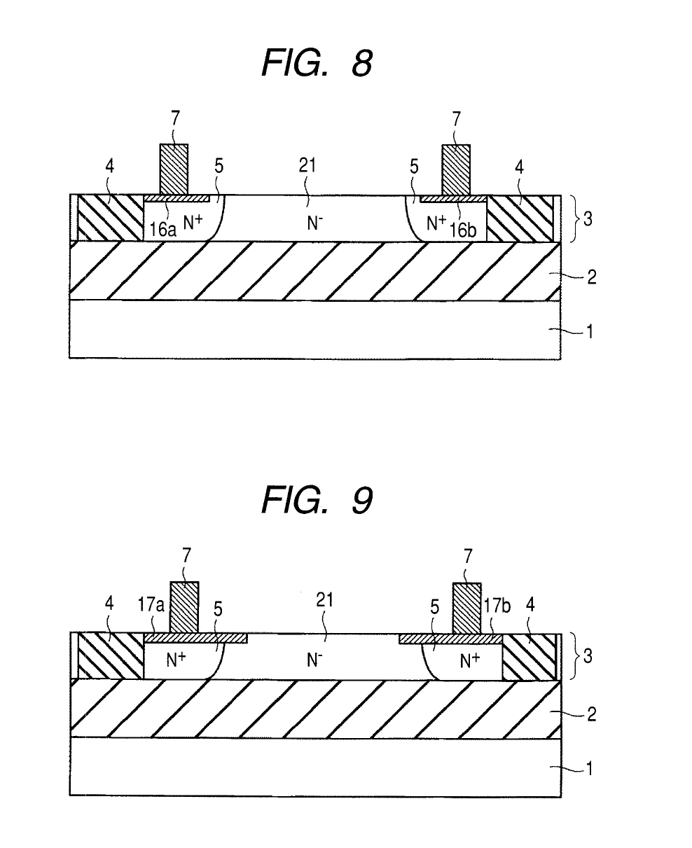

FIG. 6 is a plan view showing the structure of the semiconductor device which is Embodiment 2 of this invention, FIG. 7 is a cross-sectional view showing the C-C section of FIG. 6, and FIG. 8 is a cross-sectional view showing the D-D section of FIG. 6. The semiconductor device of Embodiment 2 has body resistance inside.

As shown in these drawings, N⁻ body region 21 is selectively formed in SOI layer 3 which forms an SOI substrate. In the ends of the Y direction of N⁻ body region 21, N⁺ diffusion regions 5 and 5 (one side and other side diffusion region) where each adjoins N⁻ body region 21 are formed, respectively.

And, full isolation region 4 is formed covering all the circumference region of N⁻ body region 21 and N⁺ diffusion regions 5 and 5 in plan view. Since full isolation region 4 penetrates SOI layer 3 and reaches buried oxide film 2, N⁻ body region 21 and N⁺ diffusion regions 5 and 5 are electrically thoroughly insulated from the outside by full isolation region 4.

Silicide film 16a (one side silicide film) is formed in the front surface of N⁺ diffusion region 5 (one side diffusion region) at the side of an end. Silicide film 16b (other side silicide film) is formed in the front surface of N⁺ diffusion region 5 (other side diffusion region) at the side of the other end, and metal plugs 7 and 7 are formed on silicide film 16a and 16b, respectively.

In body resistance of such structure, N⁻ body region 21, and N⁺ diffusion regions 5 and 5 of the ends constitute a resistor, the region which does not have silicide films 16a and 16b in an upper layer portion in N⁻ body region 21 is specified as a resistor main part, and the resistor element which used silicide film 16a as one end, and used silicide film 16b as the other end is realized.

Thus, as for body resistance of Embodiment 2, full isolation region 4 is formed in all the peripheral regions of N⁻ body region 21 and N⁺ diffusion region 5, and, as for the lower layer of N⁻ body region 21 and N⁺ diffusion regions 5 and 5, buried oxide film 2 exists. Therefore, N⁻ body region 21 and N⁺ diffusion regions 5 and 5 are thoroughly insulated from the outside, and the effect that the leak from N⁻ body region 21 and N⁺ diffusion regions 5 and 5 can be suppressed effectively is performed.

The effect that resistance increase becomes possible as a resistor element is performed by forming silicide films 16a and 16b only in the front surface of N⁺ diffusion region 5 (a one end side, the other end side). In addition, the effect that N⁻ body region 21 can set up high resistance comparatively easily more rather than N⁺ diffusion region 11 of Embodiment 1 is performed.

### (Other Modes)

FIG. 9 is a cross-sectional view showing other modes of Embodiment 2. FIG. 9 is equivalent to the D-D section of FIG. 6. As shown in the same drawing, silicide films 17a and 17b are formed from the front surface of N⁺ diffusion region 5 to the portion in the front surface of N⁻ body region 21. Other structures are the same as the basic constitution shown by FIG. 6-FIG. 8, and explanation is omitted.

Silicide films 17a and 17b in other modes have a formation area wider than silicide films 16a and 16b of basic constitution. Therefore, the effect of being easier to secure the superposition margin at the time of the contact hole opening at the time of formation of metal plug 7 is performed.

### (Size Characteristics)

FIG. 10 is a plan view showing the size characteristics of the semiconductor device of Embodiment 2. As shown in the same drawing, there are width LX which is the length of the X direction (horizontal direction of FIG. 10) of the plan view region of the rectangular shape of the resistor main part of N⁻ body region 21, and length LY which is the length of the Y direction (longitudinal direction of FIG. 10).

In this case, like Embodiment 1, width LX of the resistance main part in N⁻ body region 21 is set as 10 or more times of the minimum dimension of a circuit, and length LY is set up more than width LX. This performs the effect that N⁻ body region 21 which is a resistor hardly influenced by the resistance by the variation in a process can be obtained.

In Embodiment 2, although N⁻ body region 21 and N⁺ diffusion region 5 were shown as a resistor, even if the body region and diffusion region of a P type is made a resistor, the same effect is performed.

### Embodiment 3

### (Basic Constitution)

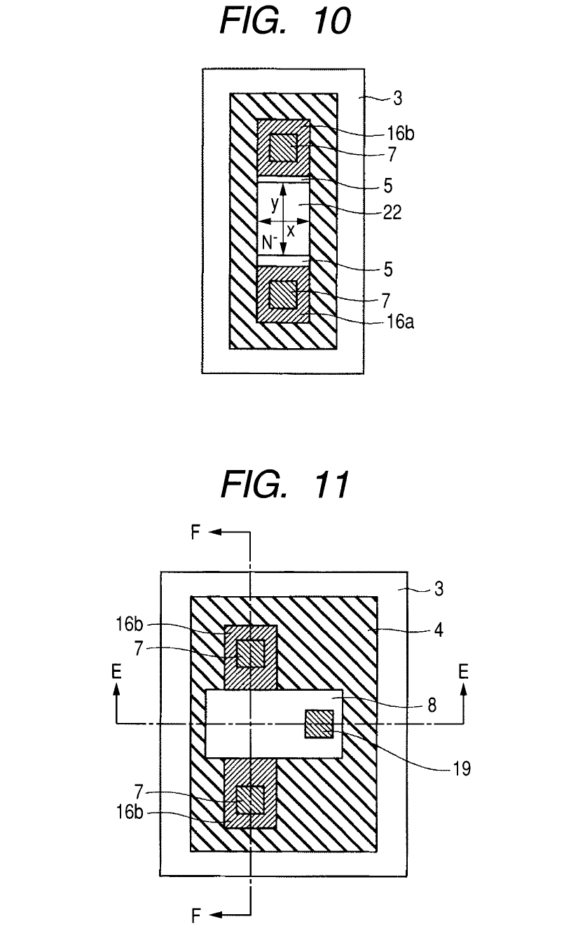

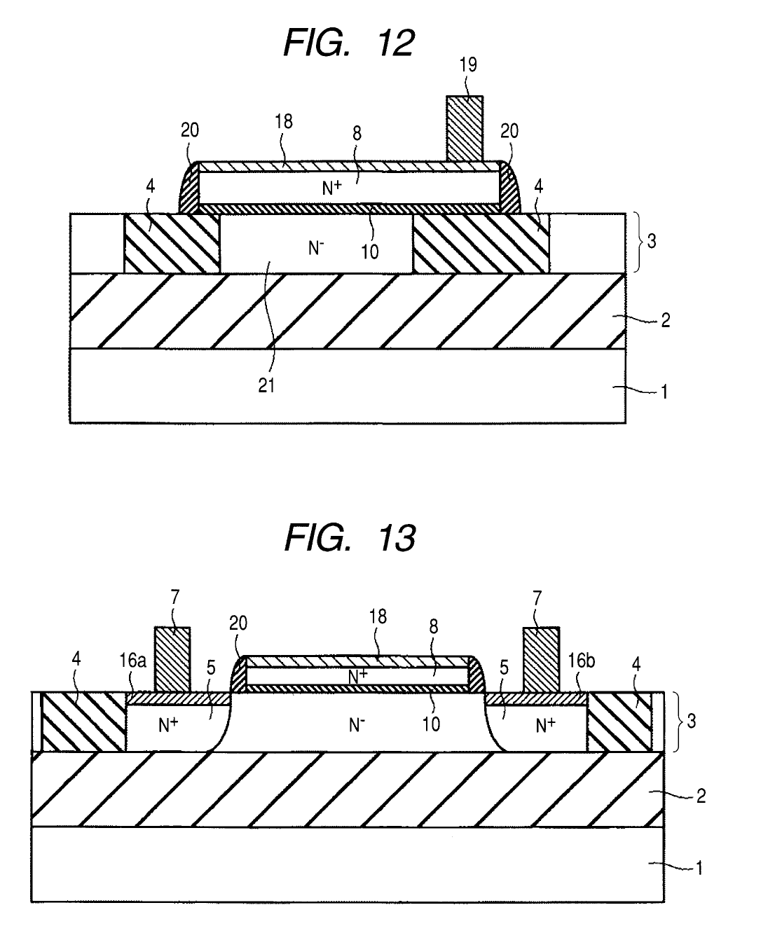

FIG. 11 is a plan view showing the structure of the semiconductor device which is Embodiment 3 of this invention, FIG. 12 is a cross-sectional view showing the E-E section of FIG. 11, and FIG. 13 is a cross-sectional view showing the F-F section of FIG. 11. The semiconductor device of Embodiment 5 has the body resistance with a gate electrode.

As shown in these drawings, N⁻ body region 21 is selectively formed in SOI layer 3 which forms an SOI substrate. In the ends of the Y direction of N⁻ body region 21, N⁺ diffusion regions 5 and 5 where each adjoins N⁻ body region 21 are formed, respectively.

And full isolation region 4 is formed covering the perimeter side region of N⁻ body region 21 and N⁺ diffusion regions 5 and 5 in plan view. Full isolation region 4 penetrates SOI layer 3, and reaches buried oxide film 2, and N⁻ body region 21 and N⁺ diffusion regions 5 and 5 are electrically thoroughly insulated from the outside by full isolation region 4.

Silicide film 16a is formed in the front surface of N⁺ diffusion region 5 at the side of one end, silicide film 16b is formed in the front surface of N⁺ diffusion region 5 at the side of the other end, and metal plugs 7 and 7 are formed on silicide film 16a and 16b.

Furthermore, gate oxide film 10 is formed crossing N⁻ body region 21 to the X direction (horizontal direction of FIG. 11), and on a part of full isolation region 4 of both sides. Gate electrode 8 which consists of polysilicon (N⁺PO) of an N type is formed on gate oxide film 10. Silicide film 18 is formed on gate electrode 8, and metal plug 19 is formed on a part of silicide film 18. Sidewall 20 is formed in all the side surfaces of gate oxide film 10, gate electrode 8, and silicide film 18. In FIG. 11, illustration of silicide film 18 and sidewall 20 is omitted on account of explanation.

In the body resistance with a gate electrode of such structure, N⁻ body region 21 and N⁺ diffusion regions 5 and 5 of the ends constitute a resistor. In N⁻ body region 21, the region which does not have silicide films 16a and 16b in an upper layer portion is specified as a resistor main part, and the resistor element which used silicide film 16a as one end, and used silicide film 16b as the other end is realized.

The resistance of the above-mentioned resistor main part is controllable by gate voltage Vg given to gate electrode 8 via metal plug 19.

Thus, as for the body resistance with a gate electrode of Embodiment 3, full isolation region 4 is formed in all the peripheral regions of N⁻ body region 21 and N⁺ diffusion region 5, and, as for the lower layer of N⁻ body region 21 and N⁺ diffusion regions 5 and 5, buried oxide film 2 exists. Therefore, the effect that the leak from N⁻ body region 21 and N⁺ diffusion regions 5 and 5 can be suppressed effectively is performed like Embodiment 2.

The effect that resistance increase becomes possible as a resistor element is performed by forming silicide films 16a and 16b only in the front surface of N⁺ diffusion region 5. In addition, the effect that N⁻ body region 21 can set up high resistance comparatively easily more rather than N⁺ diffusion region 11 of Embodiment 1 is performed.

The body resistance with a gate electrode of Embodiment 3 performs the effect that the variable control of the resistance in a resistance main part can be carried out with gate voltage Vg given to gate electrode 8.

### (Size Characteristics)

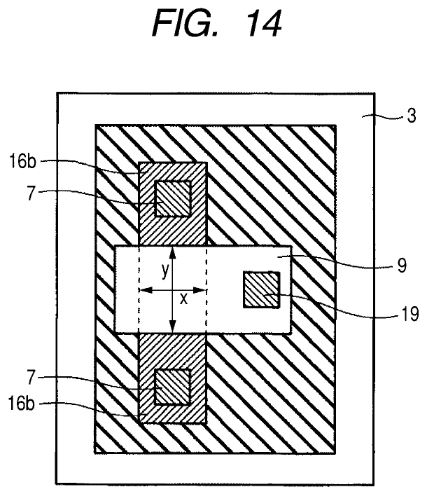

FIG. 14 is a plan view showing the size characteristics of the semiconductor device of Embodiment 3. As shown in the same drawing, there are width LX which is the length of the X direction (horizontal direction of FIG. 14) of the plan view region of the rectangular shape in the resistor main part of N⁻ body region 21, and length LY which is the length of the Y direction (longitudinal direction of FIG. 14).

In this case, like Embodiment 1 and Embodiment 2, width LX of N⁻ body region 21 is set as 10 or more times of the minimum dimension of a circuit, and length LY is set up more than width LX. This performs the effect that N⁻ body region 21 which is a resistor hardly influenced by resistance by the variation in a process can be obtained.

Embodiment 3 showed the resistor which consists of N⁻ body region 21 and N⁺ diffusion region 5, and gate electrode 8 which consists of N⁺PO. However, even if the body region and diffusion region of a P type are made into a resistor, and a gate electrode is made by polysilicon (P⁺PO) of a P type, the same effect is performed.

The side which set the conductivity type of gate electrode 8 as the same conductivity type as the conductivity type of N⁻ body region 21 performs the effect that the controllability of the resistance of N⁻ body region 21 is high.

### (Other Modes)

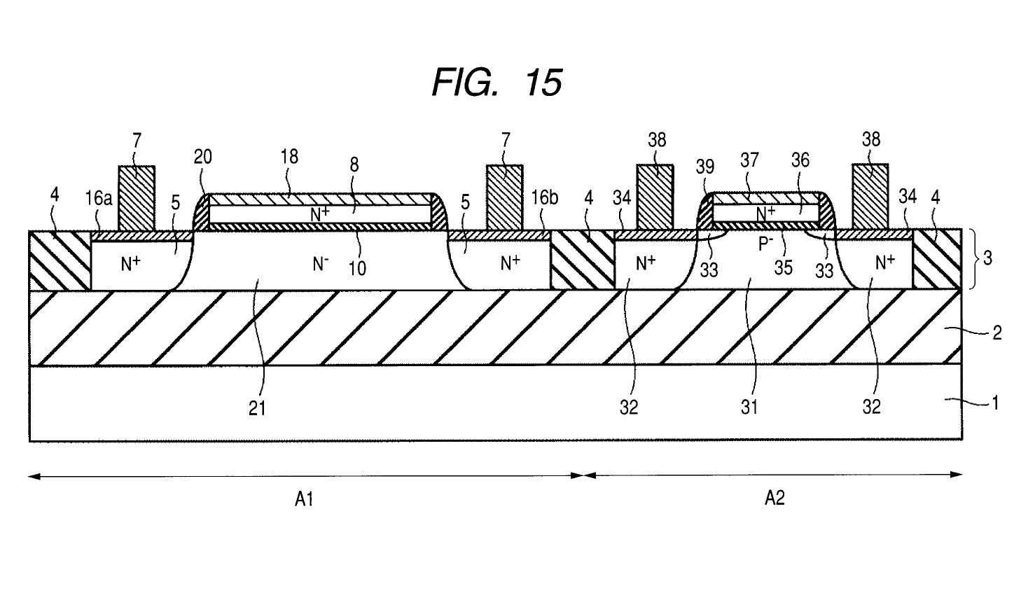

FIG. 15 is a cross-sectional view showing other modes of the semiconductor device of Embodiment 3. The semiconductor device of other modes has the body resistance with a gate electrode, and an MOS transistor inside.

In the same drawing, since body resistance region (with gate electrode) A1 is equivalent to the F-F section of FIG. 11, explanation is omitted. Hereafter, N type transistor region A2 is explained. N type transistor region A2 and body resistance region A1 are electrically separated by full isolation region 4 and buried oxide film 2. Therefore, the body resistance with a gate electrode formed in body resistance region A1 and the NMOS transistor formed in N type transistor region A2 are electrically separated thoroughly.

In N type transistor region A2, N⁺ diffusion regions 32 and 32 (one side and other side electrode region) are formed at the both sides of P⁻ body region 31 in SOI layer 3. Gate electrode 36 is formed via gate oxide film 35 on P⁻ body region 31 between N⁺ diffusion regions 32 and 32. Silicide film 37 is formed on gate electrode 36. Sidewall 39 is formed in the side surface of gate oxide film 35, gate electrode 36, and silicide film 37.

And, from each of N⁺ diffusion regions 32 and 32 to the bottom of sidewall 39 and 39, and the bottom of a part of gate oxide film 35, N type LDD regions 33 and 33 (low concentration area) are formed. On the other hand, as for the body resistance with a gate electrode formed in body resistance region A1, at the bottom of gate electrode 8 (gate oxide film 10), and at its all neighborhood, the region corresponding to N type LDD region 33 does not exist, but impurity concentration lower than N type LDD region 33 is presented.

In the usual MOS transistor, N type LDD region 33 is formed for the improvement in reliability. Therefore, when forming the body resistance with a gate electrode of Embodiment 3 simultaneously with an MOS transistor, a region corresponding to N type LDD region 33 will usually be formed also in N-body region 21 of the body resistance with a gate electrode.

In this case, there is a source of anxiety that variation occurs in the resistance of N⁻ body region 21 with the impurity injected at the time of region formation corresponding to N type LDD region 33. In other modes of Embodiment 3, the effect that the above-mentioned source of anxiety is surely avoidable is performed with the manufacturing method mentioned later by not forming a region corresponding to N type LDD region 33 in N⁻ body region 21 of the body resistance with a gate electrode.

Other modes of Embodiment 3 showed the resistor which consists of N⁻ body region 21 and N⁺ diffusion region 5, and gate electrode 8 which consists of N⁺PO. However, even if the body region and diffusion region of a P type are made into a resistor, and polysilicon of a P type is used as a (P⁺PO) gate electrode, the same effect is performed.

### Embodiment 4

### (Basic Constitution)

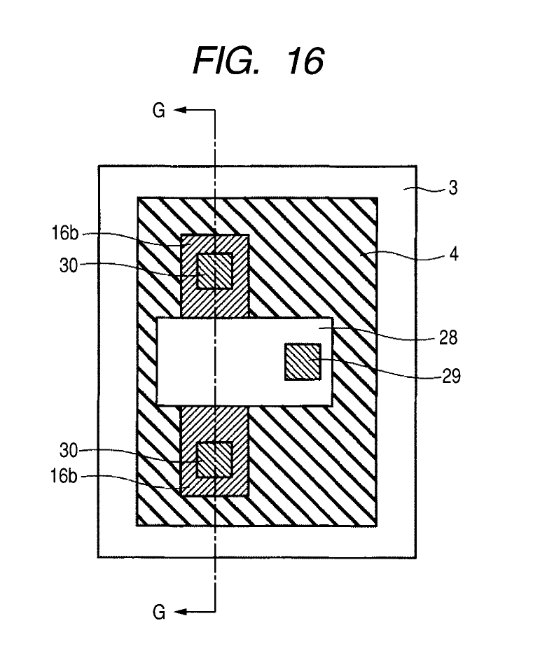

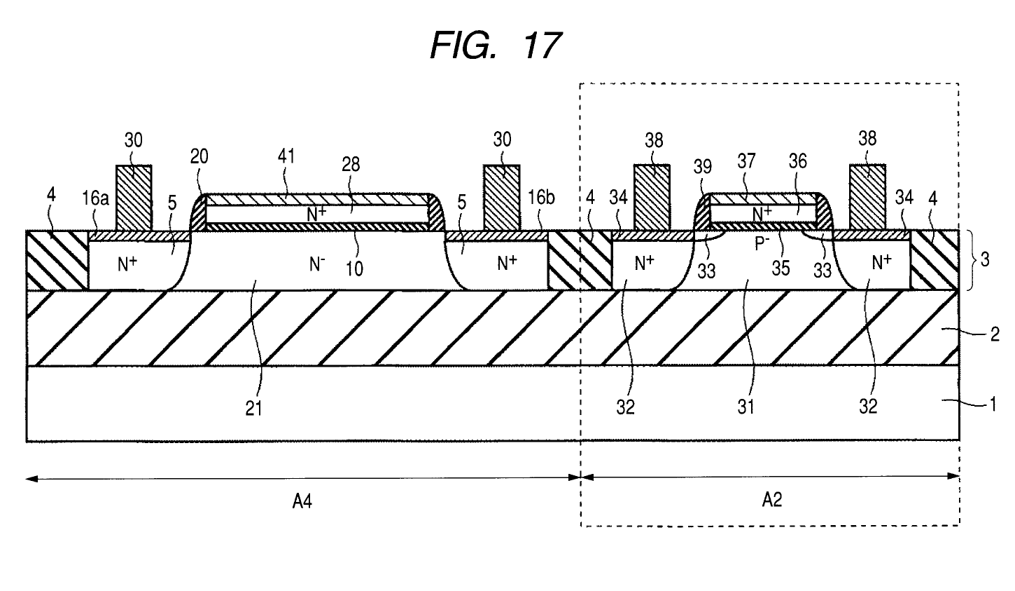

FIG. 16 is a plan view showing the structure of the semiconductor device which is Embodiment 4 of this invention, and FIG. 17 is a cross-sectional view corresponding to the G-G section of FIG. 16. The semiconductor device of Embodiment 4 has a MOS (gate) capacitor.

With reference to FIG. 16 and FIG. 17, the MOS capacitor formed in MOS capacitor formation area A4 is explained. N⁻ body region 21 (capacitor electrode region) is selectively formed in SOI layer 3 which forms an SOI substrate. In the ends of the longitudinal direction in the drawing of N⁻ body region 21, N⁺ diffusion regions 5 and 5 (one side and other side electrode region) where each adjoins N⁻ body region 21 are formed, respectively.

And full isolation region 4 is formed covering all the circumference region of N⁻ body region 21 and N⁺ diffusion regions 5 and 5 in plan view. Since full isolation region 4 penetrates SOI layer 3 and reaches buried oxide film 2, N⁻ body region 21 and N⁺ diffusion regions 5 and 5 are electrically thoroughly insulated from the outside by full isolation region 4.

Silicide film 16a is formed in the front surface of N⁺ diffusion region 5 at the side of one end, silicide film 16b is formed in the front surface of N⁺ diffusion region 5 at the side of the other end, and metal plugs 30 and 30 are formed on silicide film 16a and 16b.

Furthermore, gate oxide film 10 is formed on a part of full isolation region 4 of both sides, crossing N⁻ body region 21 to the X direction (horizontal direction of FIG. 16). Gate electrode 28 which consists of polysilicon of an N type (N⁺PO) is formed on gate oxide film 10. A MOS capacitor is formed by gate electrode 28, gate oxide film 10, and N⁻ body region 21.

Silicide film 41 is formed on gate electrode 28. Metal plug 29 is formed on a part of silicide film 41. Sidewall 20 is formed in all the side surfaces of gate oxide film 10, gate electrode 28, and silicide film 41. In FIG. 16, illustration of silicide film 41 and sidewall 20 is omitted on account of explanation.

In N type transistor region A2, the NMOS transistor of the same structure as the NMOS transistor formed in N type transistor region A2 shown by FIG. 15 is formed. And an NMOS transistor and a MOS capacitor are electrically thoroughly separated by full isolation region 4 and buried oxide film 2.

As for the MOS capacitor of such structure, the MOS capacitor which used as one electrode silicide film 41 formed on gate electrode 28, and used as the electrode of the other silicide films 16a and 16b formed on N⁺ diffusion region 5 is realized.

Thus, as for the MOS capacitor of Embodiment 4, full isolation region 4 is formed in all the peripheral regions of N⁻ body region 21 and N⁺ diffusion region 5, and, as for the lower layer of N⁻ body region 21 and N⁺ diffusion regions 5 and 5, buried oxide film 2 exists. Therefore, the effect that the leak from N⁻ body region 21 and N⁺ diffusion regions 5 and 5 can be suppressed effectively is performed like Embodiment 2 and Embodiment 3.

Also in when formed with an NMOS transistor like other modes of Embodiment 3, N⁻ body region 21 of a MOS capacitor has only impurity concentration lower than the impurity concentration of N type LDD region 33 by not forming a region corresponding to N type LDD region 33 in the bottom of gate electrode 28, and its neighboring region. The effect that a capacitance value can be set up with sufficient accuracy is performed.

In Embodiment 4, although N⁻ body region 21, N⁺ diffusion region 5, and gate electrode 28 of N⁺PO were shown, the body region and diffusion region of a P type, and the gate electrode of polysilicon (P⁺PO) of a P type also perform the same effect. On this occasion, the region corresponding to the LDD region of a P type is not formed, of course.

The side which set the conductivity type of gate electrode 28 as the same conductivity type as the conductivity type of N⁻ body region 21 performs the effect that the accuracy of the capacitance value as an MOS capacitor can be raised.

### (Other Modes)

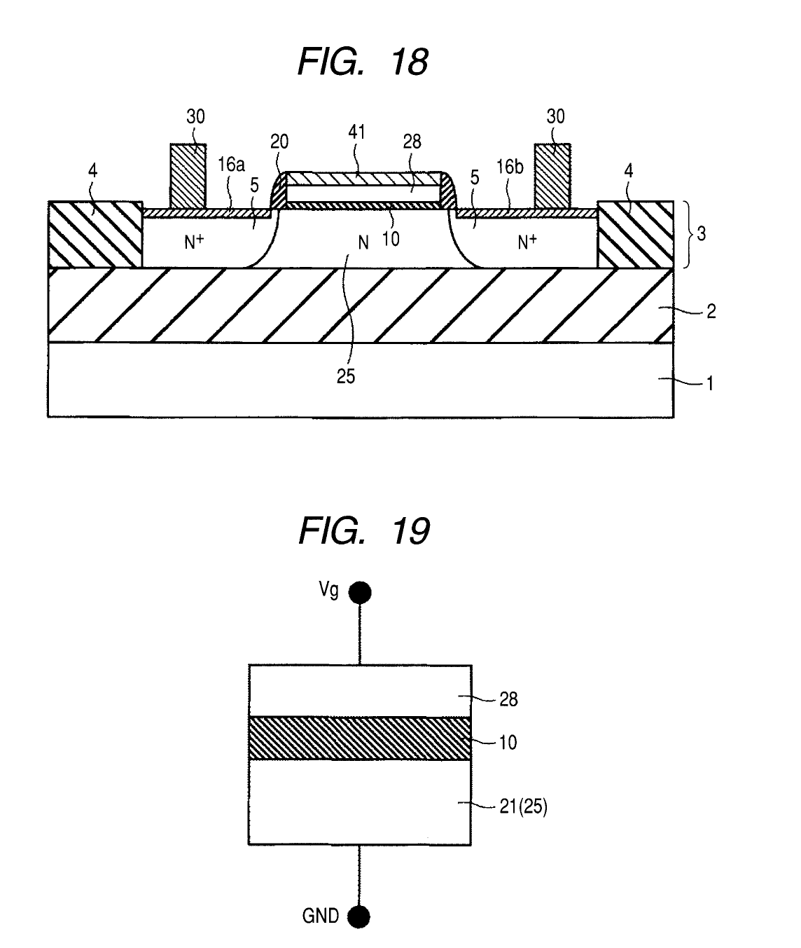

FIG. 18 is a cross-sectional view showing other modes of the semiconductor device of Embodiment 4. FIG. 18 is equivalent to the G-G section of FIG. 16 like FIG. 17.

As shown in the same drawing, in other modes, high concentration region 25 where the impurity concentration of an N type is higher than N⁻ body region 21 is formed in the inside as a capacitor electrode region instead of N⁻ body region 21.

As a formation method of N⁺ diffusion region 5, it is possible to implant phosphorus etc. by the implantation energy of 40-80 keV and at the high concentration whose impurity concentration is about 1□10×10¹⁵/cm², for example. Since other structures are the same as the basic constitution of Embodiment 4 shown by FIG. 16, explanation is omitted.

Thus, in other modes of Embodiment 4, the capacitor dope MOS capacitor which has high concentration region 25 of an N type under gate electrode 28 is realized.

FIG. 19 is an explanatory diagram showing the concept of a MOS capacitor. A MOS capacitor is formed by gate electrode 28, gate oxide film 10, and N⁻ body region 21 (high concentration region 25) as shown in the same drawing. The state where gate voltage Vg is applied to gate electrode 28, and N⁻ body region 21 is grounded is shown in the same drawing.

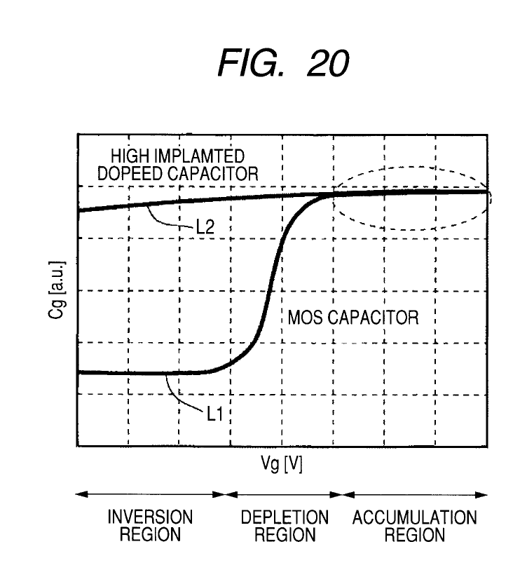

FIG. 20 is a graph which shows the relation between gate voltage Vg and capacitance value Cg in a usual MOS capacitor (MOS capacitor of the basic constitution shown by FIG. 16 and FIG. 17), and a highly implanted doped capacitor (MOS capacitor of other modes shown by FIG. 18). In the same drawing, L1 shows the characteristics of a usual MOS capacitor, and L2 shows the characteristics of the highly implanted doped capacitor.

Generally, as for the usual MOS capacitor, capacity Cox of gate oxide film 10 is defined by the capacitance value of an accumulation region. Therefore, depending on operating conditions (voltage setup of each electrode), an operating state becomes a depletion region and an inversion region, and a capacitance value falls.

On the other hand, in a highly implanted doped capacitor, since high concentration region 25 turns into an other electrode region, the threshold voltage as an NMOS transistor shifts to the low-voltage side (the minimum of an accumulation region shifts to the low-voltage side more). For this reason, in a capacitor dope MOS capacitor, the effect that operation in an accumulation region, i.e., the stable capacitance value, is maintainable regardless of operating conditions is performed.

### <Manufacturing Method>

### (Element Isolation Region Forming Step)

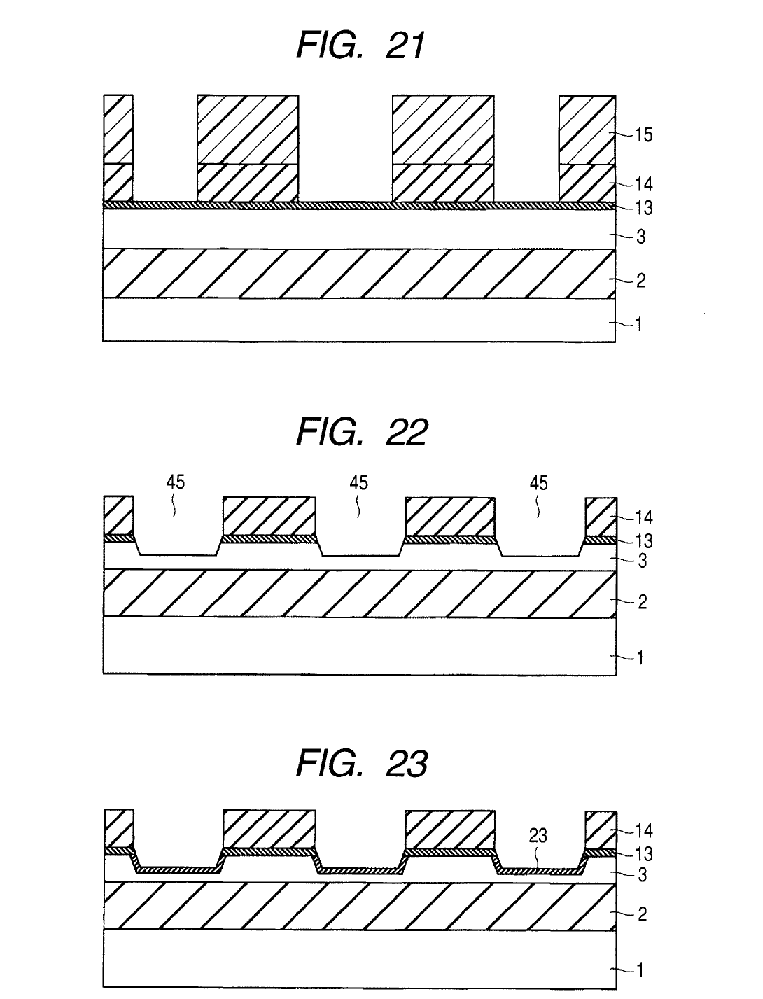

FIG. 21-FIG. 29 are the cross-sectional views showing an element isolation region forming step common to Embodiment 1-Embodiment 4. Hereafter, with reference to these drawings, the procedure of an element isolation region forming step is explained.

First, as shown in FIG. 21, silicon oxide film 13 of the thickness of a few (2-3) 10 nm is formed all over SOI layer 3 upper part on the SOI substrate which comprises supporting substrate 1, buried oxide film 2, and SOI layer 3. Silicon nitride film 14 of the thickness of a few hundreds nm is formed on silicon oxide film 13. And patterned resist pattern 15 is formed on silicon nitride film 14, etching to silicon nitride film 14 is performed by using resist pattern 15 as a mask, and silicon nitride film 14 is patterned.

Next, as shown in FIG. 22, after removing resist pattern 15, etching removal of silicon oxide film 13, and a part of SOI layer 3 is done by using patterned silicon nitride film 14 as a mask, and non-penetrating trench 45 is formed. That is, SOI layer 3 under non-penetrating trench 45 is made to remain by desired thickness.

And as shown in FIG. 23, inner wall oxide film 23 of the thickness of about a few tens nm is formed in the inner wall of SOI layer 3 exposed by non-penetrating trench 45.

Next, as shown in FIG. 24, after applying resist, patterning is done and resist pattern 100 is obtained. The opening of this resist pattern 100 constitutes a full isolation region formation area.

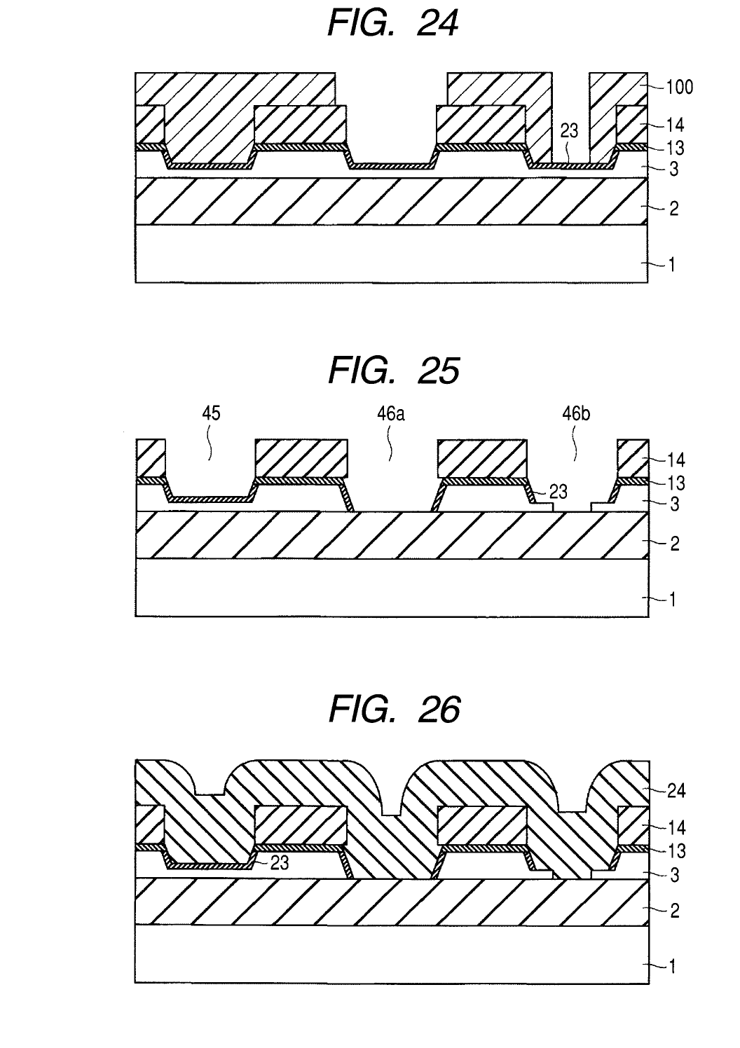

Then, as shown in FIG. 25, after obtaining penetration trench 46a and penetration trench 46b which penetrate SOI layer 3 by doing etching removal of inner wall oxide film 23 and the SOI layer 3 by using resist pattern 100 as a mask, resist pattern 100 is removed. As a through hole, any one of penetration trench 46a made to penetrate by the opening of a size comparable as the opening of non-penetrating trench 45, and penetration trench 46b made to penetrate by an opening narrower than the opening of non-penetrating trench 45 is sufficient.

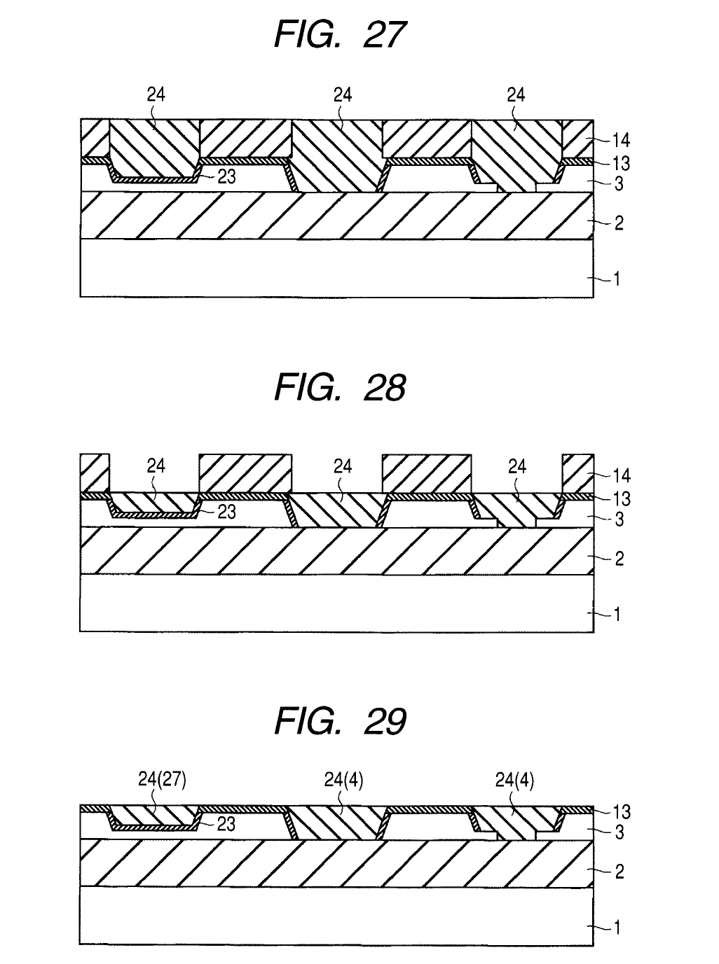

Then, as shown in FIG. 26, after depositing silicon oxide film 24 on the whole surface, as shown in FIG. 27, flattening of the silicon oxide film 24 is done in the height on silicon nitride film 14 by CMP treatment. And etching removal is done until silicon oxide film 24 reaches desired thickness, as shown in FIG. 28.

Finally, as shown in FIG. 29, partial isolation region 27 which has a part of SOI layer 3 below, and full isolation region 4 which penetrated SOI layer 3 are formed respectively by silicon oxide film 24 which remained, by removing silicon nitride film 14. SOI layer 3 between silicon oxide films 24 and 24 constitutes element formation regions, such as resistance of Embodiments 1-3, and a capacitor of Embodiment 4.

### (Manufacturing Method of Embodiment 1)

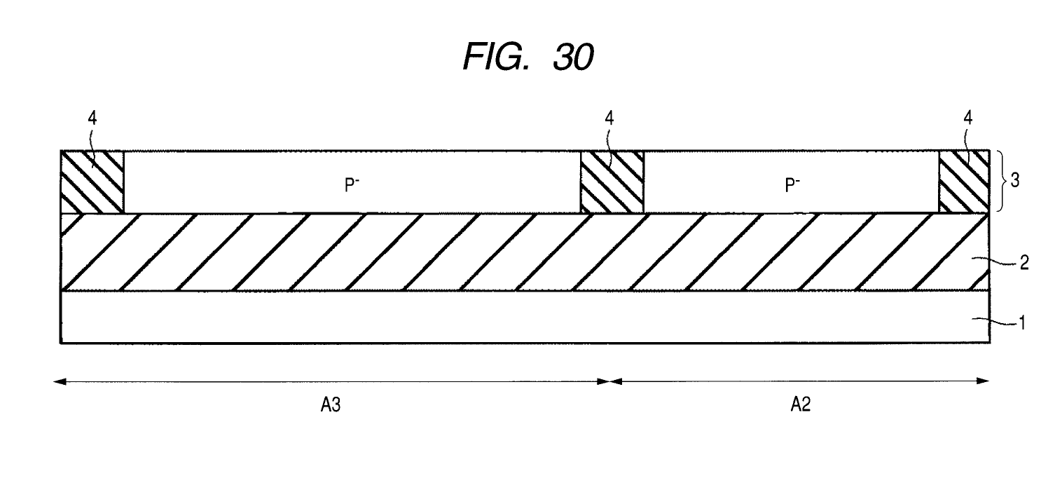

FIG. 30-FIG. 35 are the cross-sectional views showing the manufacturing process of the diffusion resistance of Embodiment 1. FIG. 30-FIG. 35 show the manufacturing process from the state (state shown by FIG. 29) after full isolation region 4 separated according to the element isolation region forming step mentioned above. FIG. 30-FIG. 35 show the step in which an NMOS transistor is formed as well as the diffusion resistance of Embodiment 1. FIG. 30-FIG. 35 are equivalent to the B-B section of FIG. 1.

First, as shown in FIG. 30, in diffusion resistance region A3 and N type transistor region A2, impurity implantation processing of the boron (ion) for well region formation is performed. After setting SOI layer 3 of diffusion resistance region A3 and MOS capacitor formation area A4 as P⁻, silicon oxide film 24 (refer to FIG. 29) formed in the front surface of SOI layer 3 is removed. It carries out as implantation conditions for a boron, for example by hundreds keV for implantation energy and several 10¹³/cm² for impurity concentration. When forming the well region of an N type, phosphorus is performed on the implantation conditions of hundreds keV for implantation energy and several 10¹³/cm² for impurity concentration, for example.

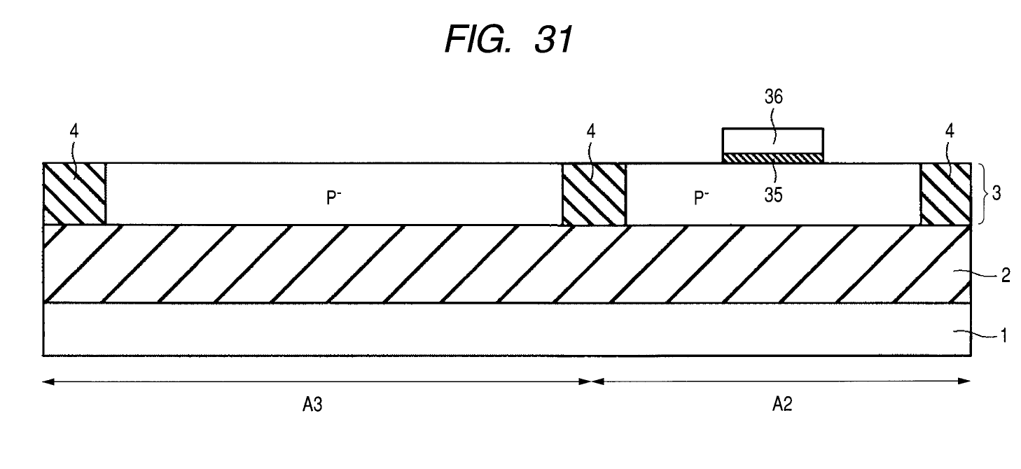

Next, as shown in FIG. 31, the native oxide film (not shown in FIG. 30 and FIG. 31) formed in the front surface is removed. Patterning is done, after depositing an oxide film in the thickness of several nm and depositing polysilicon in the thickness about tens to 100 nm one by one. This obtains the laminated structure of gate oxide film 35 and gate electrode 36 in N type transistor region A2.

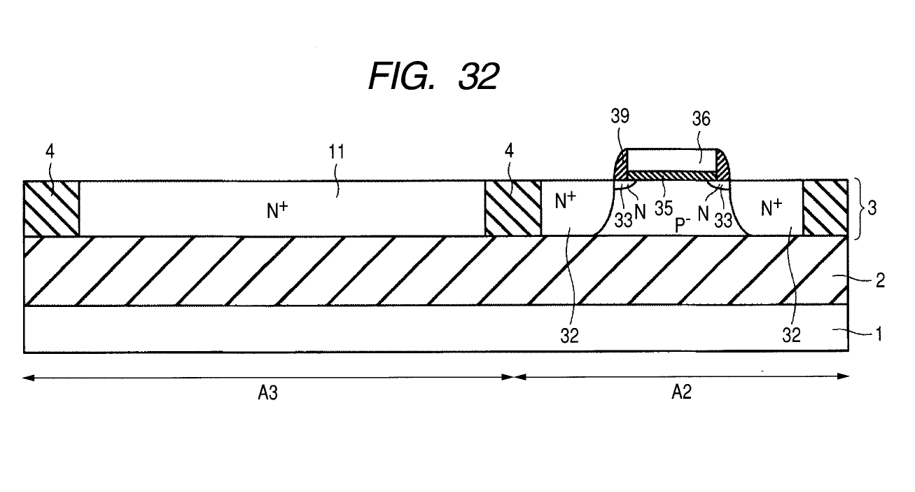

As shown in FIG. 32, in N type transistor region A2, impurity implantation processing of an N type for N type LDD region 33 formation is performed by using gate electrode 36 as a mask, and N type LDD regions 33 and 33 are formed. Sidewall 39 is formed in the side surface of gate electrode 36 by depositing a silicon oxide film on the whole surface, and etching back it. Impurity implantation processing of the N type for source/drain region formation is performed by using gate electrode 36 and sidewall 39 as a mask, and N⁺ diffusion regions 32 and 32 are formed.

Since diffusion resistance region A1 is not masked, N⁺ diffusion region 11 is formed by impurity implantation processing of an N type for N type LDD region 33 formation, and impurity implantation processing of an N type for source/drain region formation.

It is possible as impurity implantation processing of an N type for N type LDD region 33 formation to implant arsenic on the implantation conditions of several-tens keV for implantation energy and several number*10¹⁴-1*10¹⁵/cm² for impurity concentration, for example. As impurity implantation processing of an N type for N⁺ diffusion region 32 formation, it is possible to implant arsenic on the implantation conditions of several tens keV for implantation energies and several number*10¹⁵/cm² for impurity concentration, for example.

It is possible as impurity implantation processing of a P type for P type LDD region formation to implant a boron on the implantation conditions of several to tens keV for implantation energy, and several number*10¹⁴-1*10¹⁵/cm² for impurity concentration, for example. As impurity implantation processing of a P type for P⁺ diffusion region formation, it is possible to implant a boron on the implantation conditions of tens keV for implantation energy, and several number*10¹⁵/cm² for impurity concentration, for example.

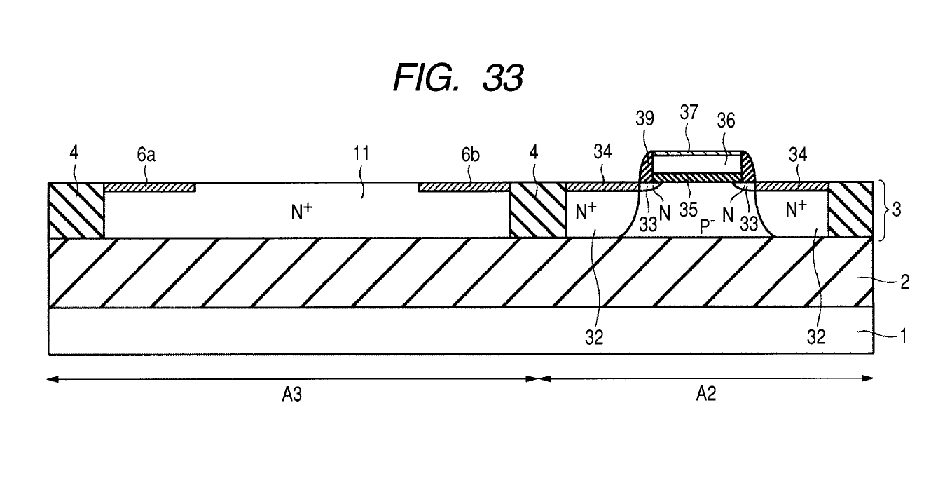

And as shown in FIG. 33, in diffusion resistance region A3, silicide films 6a and 6b are selectively formed in the front surface of the both ends of N⁺ diffusion region 11. In N type transistor region A2, silicide films 34 (TiSi, CoSi₂, NiSi, etc.) are formed in the front surface of N⁺ diffusion region 32. Selective formation of silicide films 6a and 6b is explained in full detail in the manufacturing method of Embodiment 2 mentioned later.

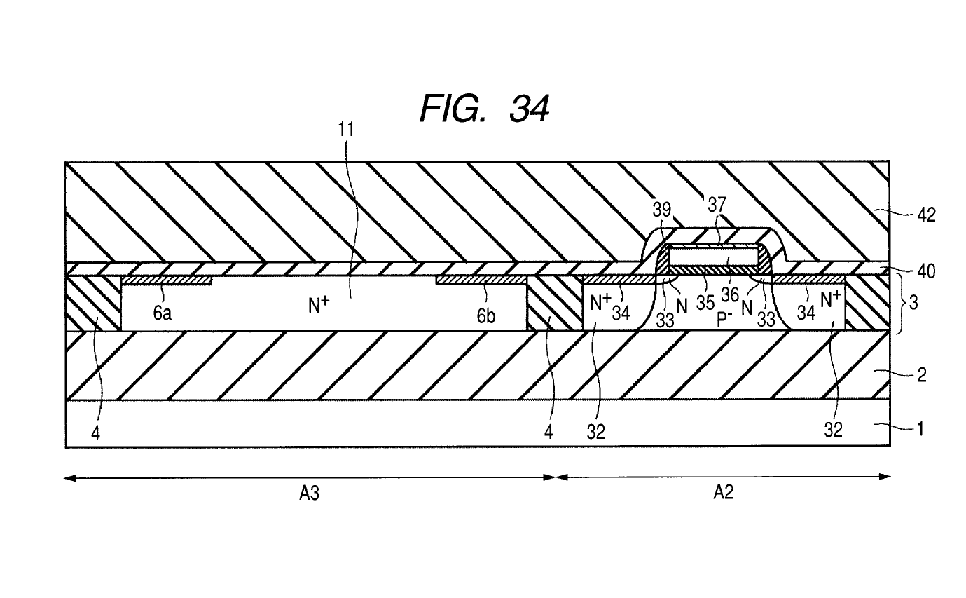

Then, as shown in FIG. 34, silicon nitride film 40 is deposited on the whole surface in tens of nm thickness, oxide film 42 is deposited in hundreds of nm thickness on silicon nitride film 40, and flattening is done performing CMP treatment.

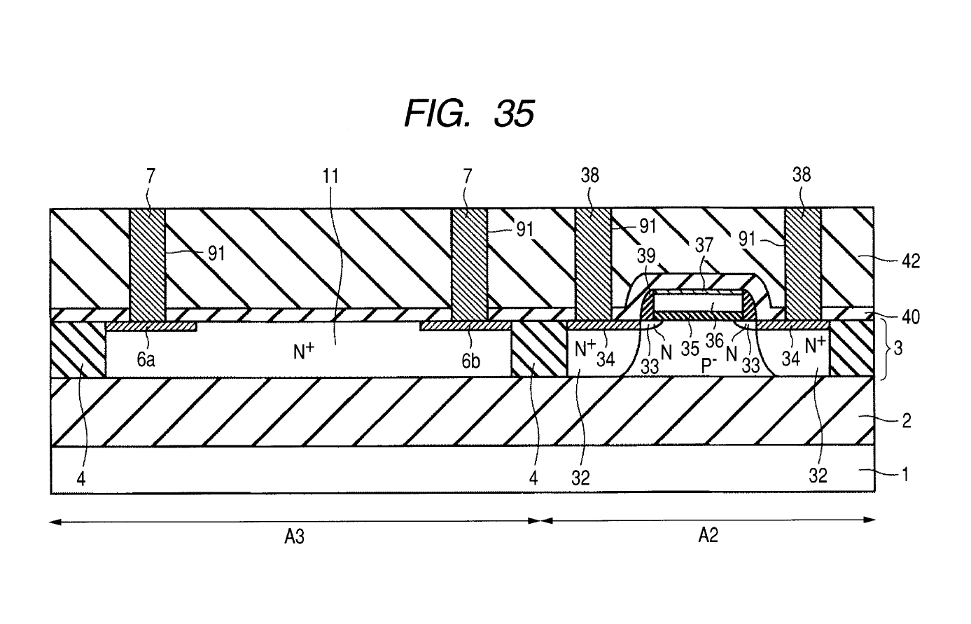

And as shown in FIG. 35, on silicide films 6a and 6b and silicide films 34 and 34, oxide film 42 is penetrated and contact hole 91 is formed. Metal layers, such as tungsten, are deposited on the whole surface, and polish removal of the metal layers other than the metal layer formed in contact hole 91 is done. Hereby, metal plugs 7 and 7 are formed on silicide film 6a and 6b, and metal plugs 38 and 38 are formed on silicide film 34 and 34. Then, a semiconductor device including the diffusion resistance of Embodiment 1 and an NMOS transistor is completed by forming a required wiring (not shown).

### (Manufacturing Method of Embodiment 2 (Basic Constitution))

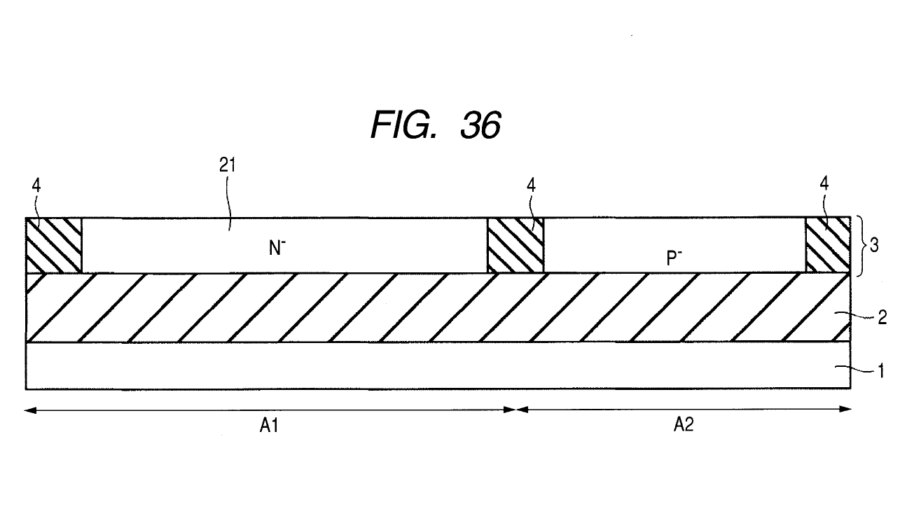

FIG. 36-FIG. 45 are the cross-sectional views showing the manufacturing process of the basic constitution (refer to FIG. 6-FIG. 8) of body resistance of Embodiment 2. FIG. 36-FIG. 45 show the manufacturing process from the state (state shown by FIG. 29) after full isolation region 4 separated according to the element isolation region forming step mentioned above. FIG. 36-FIG. 45 show the step in which an NMOS transistor is formed with body resistance of Embodiment 2. FIG. 36-FIG. 45 are equivalent to the D-D section of FIG. 6.

First, as shown in FIG. 36, in body resistance region A1, impurity implantation of the phosphorus for well region formation is performed, and N⁻ body region 21 is formed in SOI layer 3 of body resistance region A1. In N type transistor region A2, impurity implantation of the boron for well region formation is performed, and SOI layer 3 of N type transistor region A2 is set as P⁻. Then, silicon oxide film 24 (refer to FIG. 29) formed in the front surface of SOI layer 3 is removed. About phosphorus, it carries out on the implantation conditions of hundreds keV for implantation energy and several 10¹³/cm² for impurity concentration. About boron, it carries out, for example on the implantation conditions of hundreds keV for implantation energy and several 10¹³/cm² for impurity concentration.

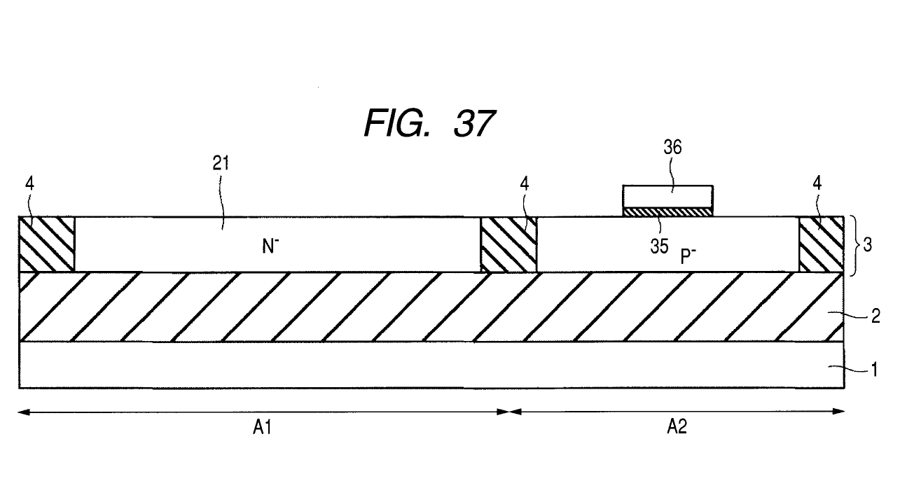

Next, as shown in FIG. 37, the native oxide film (not shown in FIG. 36 and FIG. 37) formed in the front surface is removed. It patterns, after depositing an oxide film in several nm thickness and depositing polysilicon in about tens-100 nm thickness one by one. This obtains the laminated structure of gate oxide film 35 and gate electrode 36 in N type transistor region A2.

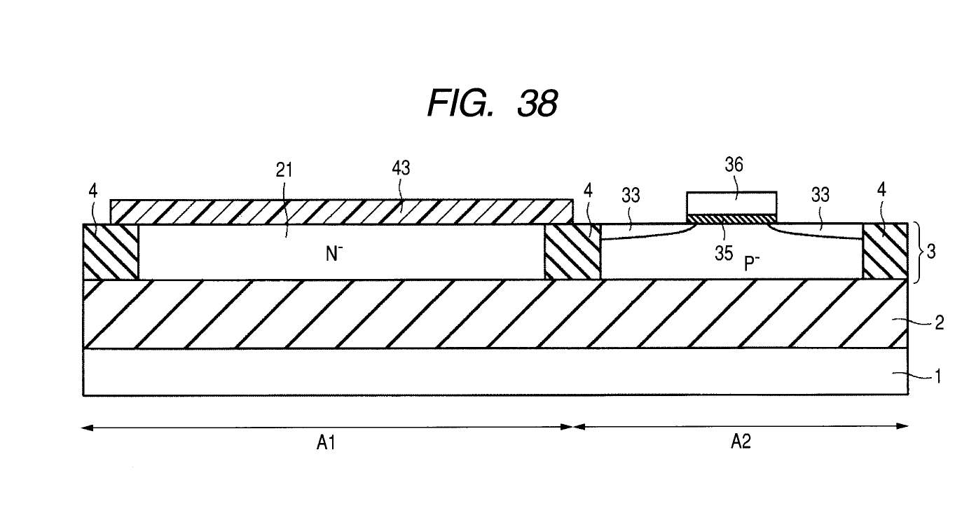

As shown in FIG. 38, after covering the whole surface on N⁻ body region 21 with resist pattern 43, impurity implantation processing of an N type for N type LDD region 33 formation is performed by using gate electrode 36 as a mask, and N type LDD regions 33 and 33 are formed in N type transistor region A2.

It is possible as impurity implantation processing of an N type for N type LDD region 33 formation to implant arsenic on the implantation conditions of several to tens keV for implantation energy, and several number*10¹⁴-1*10¹⁵/cm² for impurity concentration, for example. It is possible as impurity implantation processing of a P type for P type LDD region formation to implant a boron on the implantation conditions of several to tens keV for implantation energy, and several number*10¹⁴-1*10¹⁵/cm² for impurity concentration, for example.

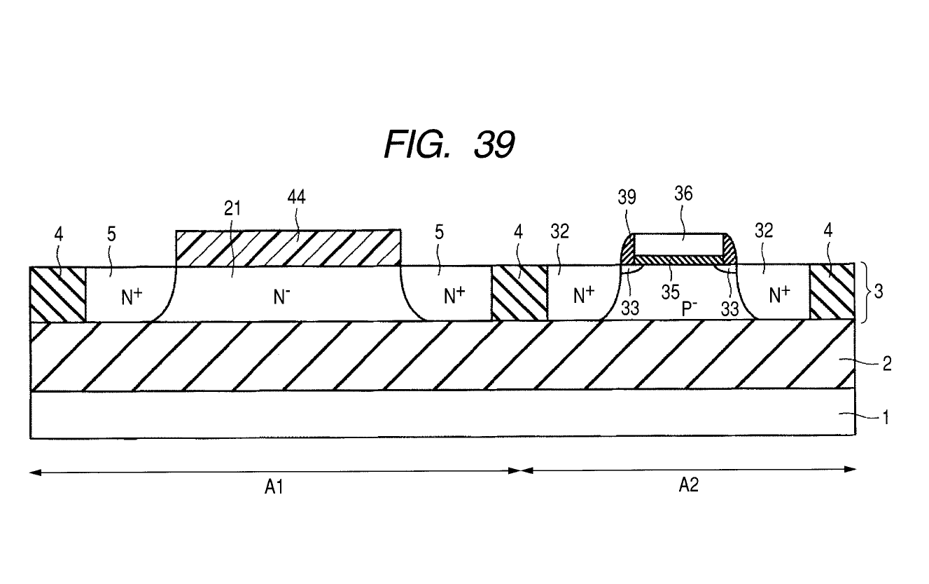

Then, as shown in FIG. 39, after removing resist pattern 43, sidewall 39 is formed in the side surface of gate electrode 36 by depositing a silicon oxide film on the whole surface, and etching back it. Resist pattern 44 is formed on the region except a both-ends region (N⁺ diffusion region 5 schedule region) of N⁻ body region 21 of body resistance region A1.

And impurity implantation processing of an N type is performed by using gate electrode 36, sidewall 39, and resist pattern 44 as a mask. N⁺ diffusion regions 5 and 5 are formed in body resistance region A1, and N⁺ diffusion regions 32 and 32 are formed in N type transistor region A2, respectively.

As impurity implantation processing of an N type at this time, it is possible to implant arsenic on the implantation conditions of tens keV for implantation energy, and several number*10¹⁵/cm² for impurity concentration, for example. As impurity implantation processing of a P type for P⁺ diffusion region formation, it is possible to implant a boron on the implantation conditions of several to tens keV for implantation energy, and several number*10¹⁵/cm² for impurity concentration, for example.

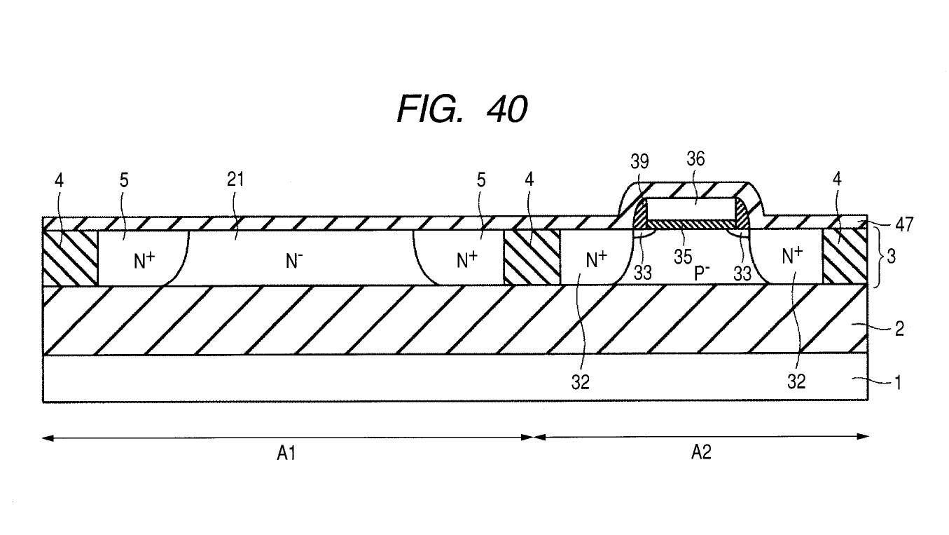

Then, as shown in FIG. 40, after removing resist pattern 44, oxide film 47 of the thickness of tens-several 100 nm is formed in the whole surface.

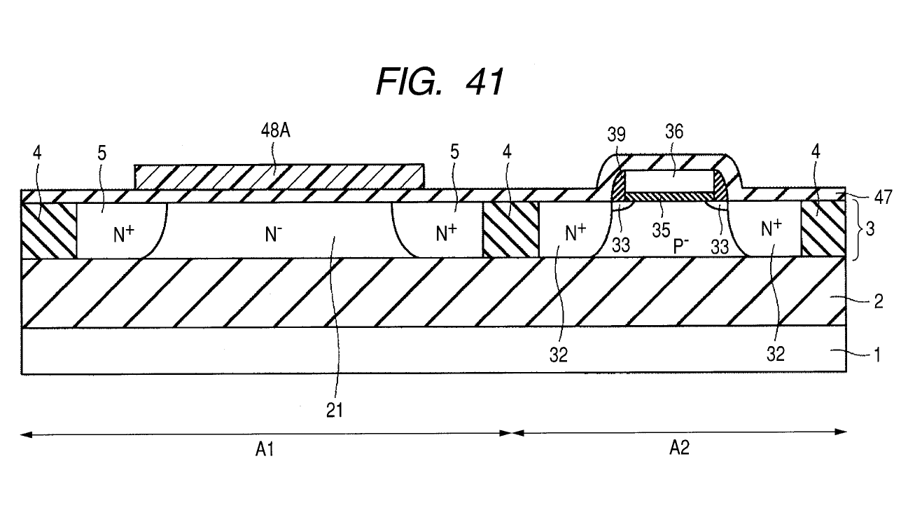

And as shown in FIG. 41, resist is applied and resist is patterned by a photolithography process in body resistance region A1. Resist pattern 48A formed from N⁻ body region 21 upper part to a part of N⁺ diffusion region 5 is obtained so that a part of N⁺ diffusion region 5 (silicide formation schedule region) may have an opening.

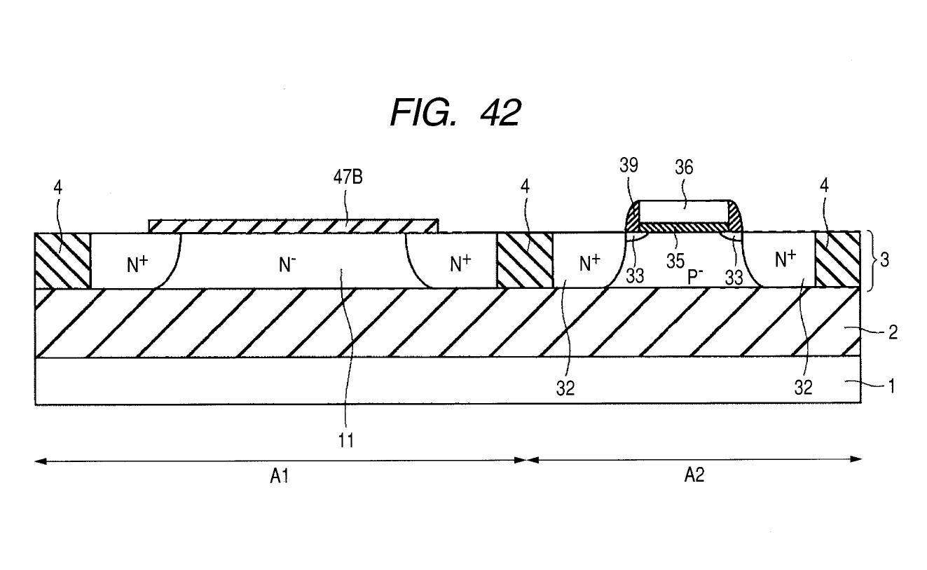

Then, as shown in FIG. 42, oxide film 47 is etched by using resist pattern 48A as a mask, and silicide block 47B is obtained.

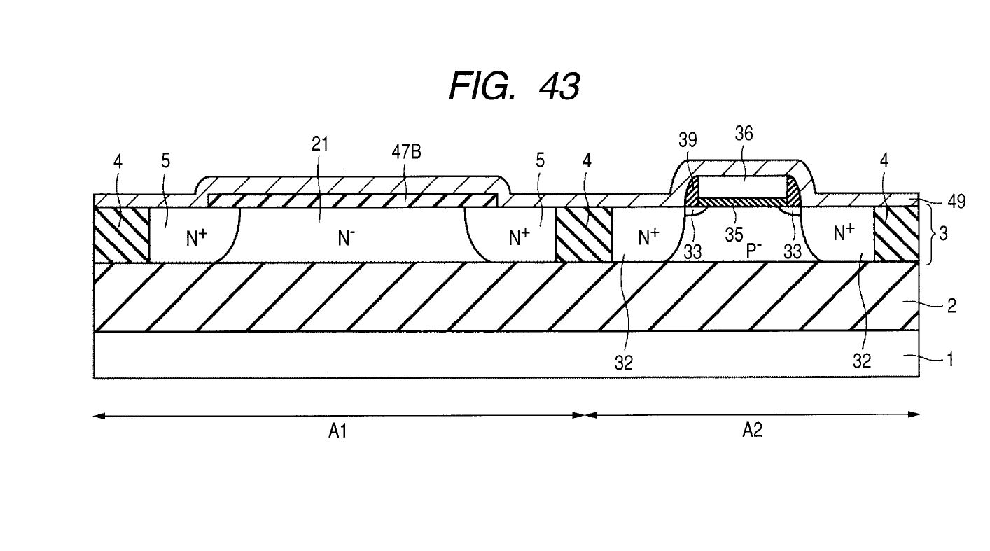

And as shown in FIG. 43, metal layer 49 which consists of metal atoms, such as Ti, Co, and Ni, is formed by sputtering by several nm-tens of nm thickness.

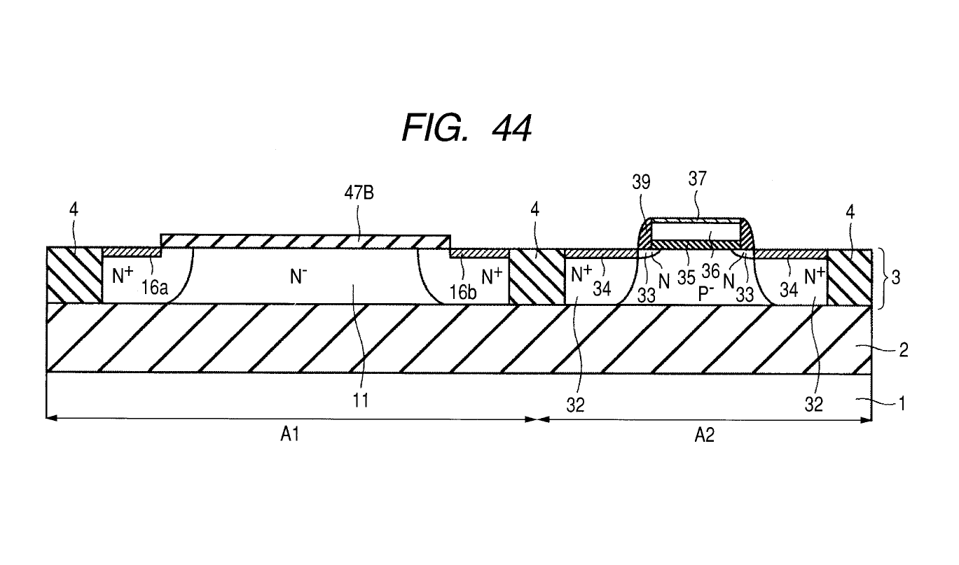

Then, as shown in FIG. 44, a metal silicidation (MxSix, M is a metallic element, and Si is silicon) of metastable condition in a metal atom is done by heat treatment of 400-700□. Then, wet process (wet etching) etc. removes selectively the unreacted portion which is not silicided of metal layer 49. By this, silicide films 16a and 16b are formed in the front surface of N⁺ diffusion regions 5 and 5, silicide films 34 and 34 are formed in the front surface of N⁺ diffusion regions 32 and 32, and silicide film 37 is formed in the upper surface of gate electrode 36.

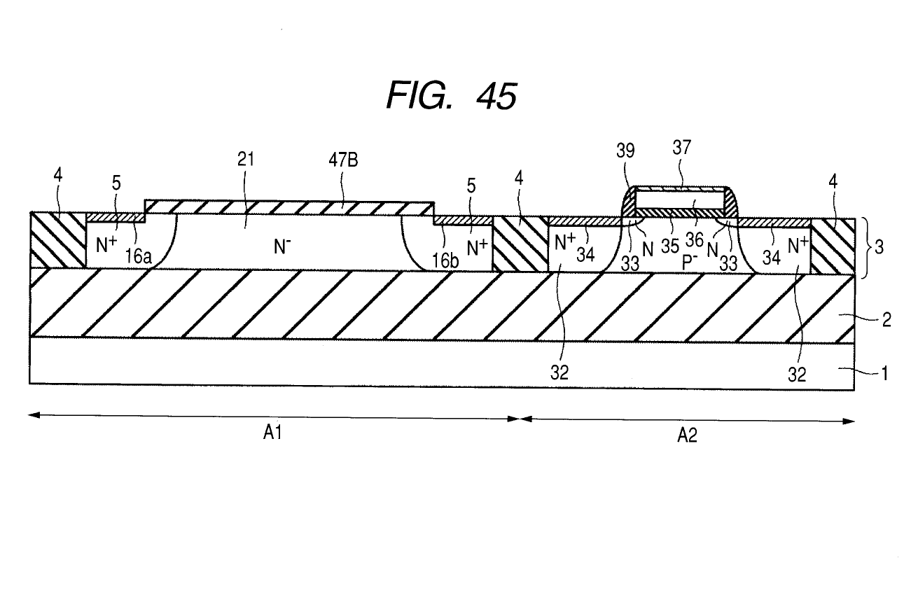

And as shown in FIG. 45, further, heat treatment is done by 700-900□, and silicide films 16a and 16b, silicide film 34, and silicide film 37 which are extremely stable and low resistance are formed.

Henceforth, passing the same processing as Embodiment 1 shown by FIG. 34 and FIG. 35, a semiconductor device including body resistance of the basic constitution (refer to FIG. 6-FIG. 8) of Embodiment 2 and an NMOS transistor is completed.

### (Manufacturing Method of Embodiment 2 (Other Modes))

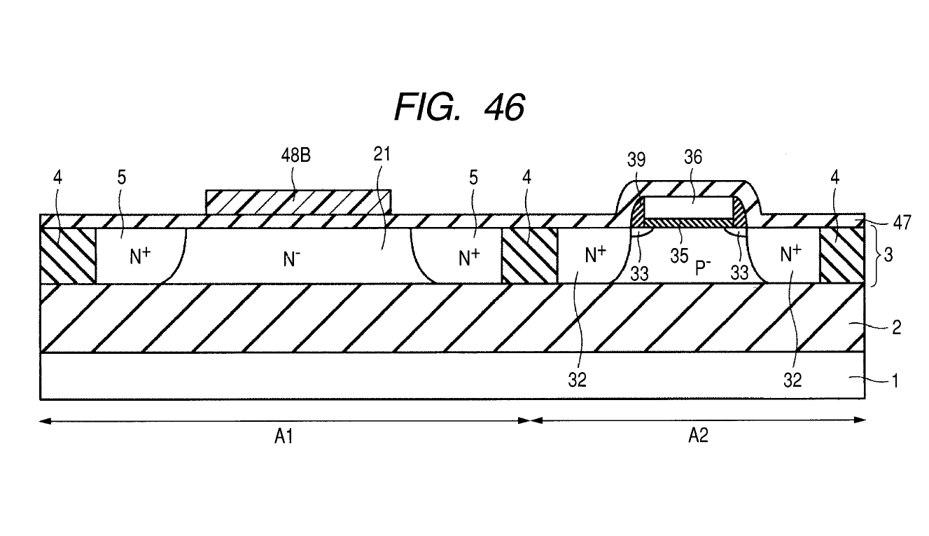

FIG. 46 is a cross-sectional view showing a part of manufacturing process of other modes of body resistance of Embodiment 2 (refer to FIG. 9). FIG. 46 shows the manufacturing process after the structure shown by FIG. 40 was acquired through the same step as the manufacturing method of the basic constitution of Embodiment 2. FIG. 46 shows a part of step in which an NMOS transistor is formed with body resistance of Embodiment 2. FIG. 46 is equivalent to the D-D section of FIG. 6.

As shown in FIG. 46, resist is applied and resist is patterned by a photolithography process in body resistance region A1. Resist pattern 48B is obtained so that only an upper part of the region of N⁻ body region 21 except all of N⁺ diffusion regions 5 and a part of both ends of N⁻ body region 21 (silicide formation schedule region) may remain.

Then, passing the manufacturing process of the basic constitution of Embodiment 1 shown by FIG. 42-45, and further passing the same processing as Embodiment 1 shown by FIG. 34 and FIG. 35, a semiconductor device including body resistance of other modes (refer to FIG. 9) of Embodiment 2 and an NMOS transistor is completed.

### (Manufacturing Method of Embodiment 3 (First Structure))

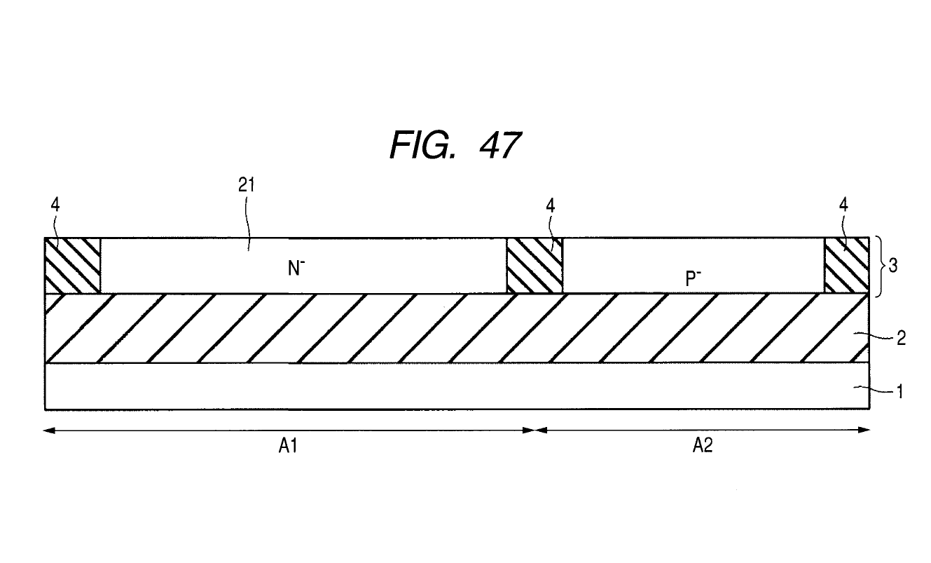

FIG. 47-FIG. 49 are the cross-sectional views showing the manufacturing process of the first structure (body resistance with a gate electrode with an LDD region of basic constitution) of the body resistance with a gate electrode of Embodiment 3. FIG. 47-FIG. 49 show the manufacturing process from the state (state shown by FIG. 29) after full isolation region 4 separated according to the element isolation region forming step mentioned above. FIG. 47-FIG. 49 show the step in which an NMOS transistor is formed with the body resistance with a gate electrode of Embodiment 3. FIG. 47-FIG. 49 are equivalent to the F-F section of FIG. 11.

First, as shown in FIG. 47, in body resistance region (with gate electrode) A1, impurity implantation of the phosphorus for well region formation is performed, and N⁻ body region 21 is formed in SOI layer 3 of body resistance region A1. In N type transistor region A2, impurity implantation of the boron for well region formation is performed, and SOI layer 3 of N type transistor region A2 is set as P⁻. Then, silicon oxide film 24 (refer to FIG. 29) formed in the front surface of SOI layer 3 is removed. About phosphorus, it carries out on the implantation conditions of hundreds keV for implantation energy, and several 10¹³/cm² for impurity concentration. About a boron, it carries out, for example on the implantation conditions of hundreds keV for implantation energy, and several 10¹³/cm² for impurity concentration.

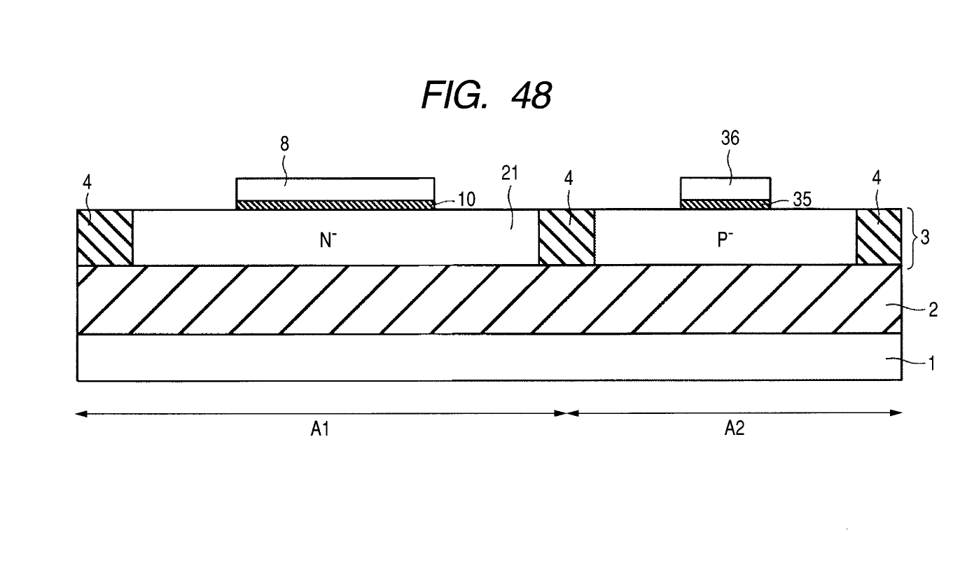

Next, as shown in FIG. 48, the native oxide film (not shown in FIG. 47 and FIG. 48) formed in the front surface is removed, an oxide film is deposited in several nanometers thickness, and polysilicon is deposited in about tens-100 nm thickness one by one. Then, by patterning, while obtaining the laminated structure of gate oxide film 10 and gate electrode 8 in body resistance region A1, the laminated structure of gate oxide film 35 and gate electrode 36 is obtained in N type transistor region A2.

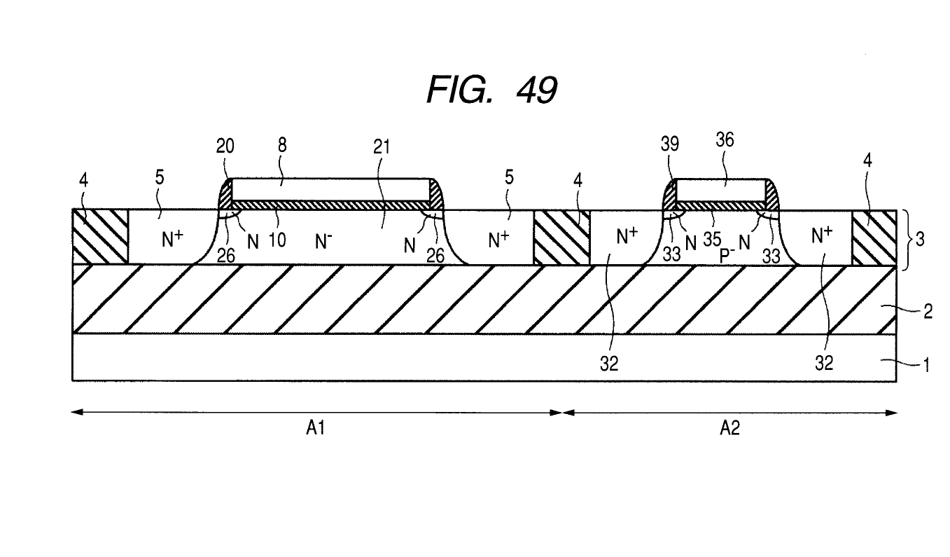

As shown in FIG. 49, impurity implantation processing of an N type for N type LDD region formation is performed by using gate electrode 8 and gate electrode 36 as a mask. While forming LDD region 26 in body resistance region A1, N type LDD region 33 is formed in N type transistor region A2.

It is possible as impurity implantation processing of an N type for N type LDD region formation to implant arsenic on the implantation conditions of several to tens keV for implantation energy, and several number*10¹⁴-1*10¹⁵/cm² for impurity concentration, for example. It is possible as impurity implantation processing of a P type for P type LDD region formation to implant a boron on the implantation conditions of several keV for implantation energy, and several number*10¹⁴-1*10¹⁵/cm² for impurity concentration, for example.

Then, sidewall 39 is formed in the side surface of gate electrode 36 while forming sidewall 20 in the side surface of gate electrode 8 by depositing a silicon oxide film on the whole surface, and etching back it, as shown in FIG. 49.

And impurity implantation processing of an N type is performed by using gate electrode 8, sidewall 20, gate electrode 36, and sidewall 39 as a mask, N⁺ diffusion regions 5 and 5 are formed in body resistance region A1, and N⁺ diffusion regions 32 and 32 are formed in N type transistor region A2, respectively.

As impurity implantation processing of an N type at this time, it is possible to implant arsenic by several tens keV for implantation energies, and several number*10¹⁵/cm² for impurity concentration, for example. As impurity implantation processing of a P type for P⁺ diffusion region formation, it is possible to implant a boron on the implantation conditions of tens keV for implantation energy, and several number*10¹⁵/cm² for impurity concentration, for example.

Henceforth, a semiconductor device including the body resistance with a gate electrode which has an LDD region which is the first structure of Embodiment 3, and an NMOS transistor is completed through the same processing as Embodiment 1 shown by FIG. 33-FIG. 35.

### (Manufacturing Method of Embodiment 3 (Second Mode))

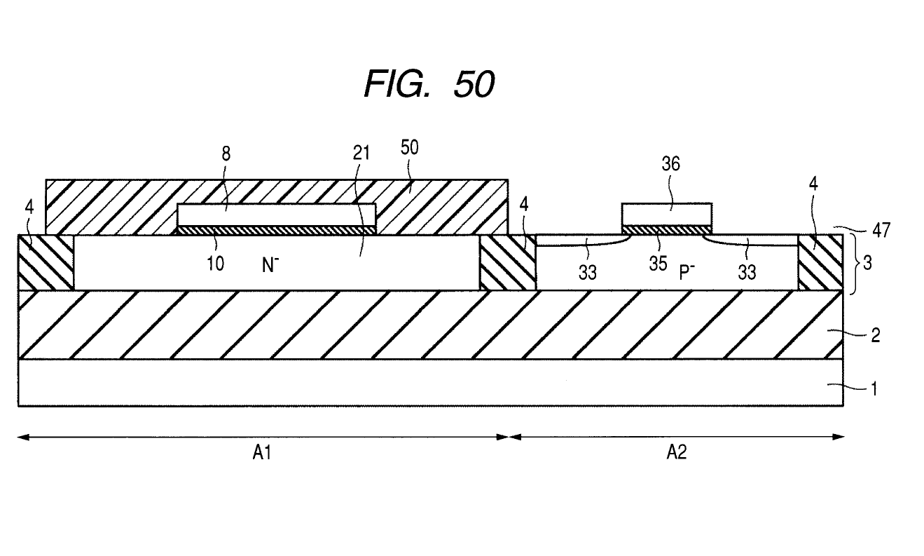

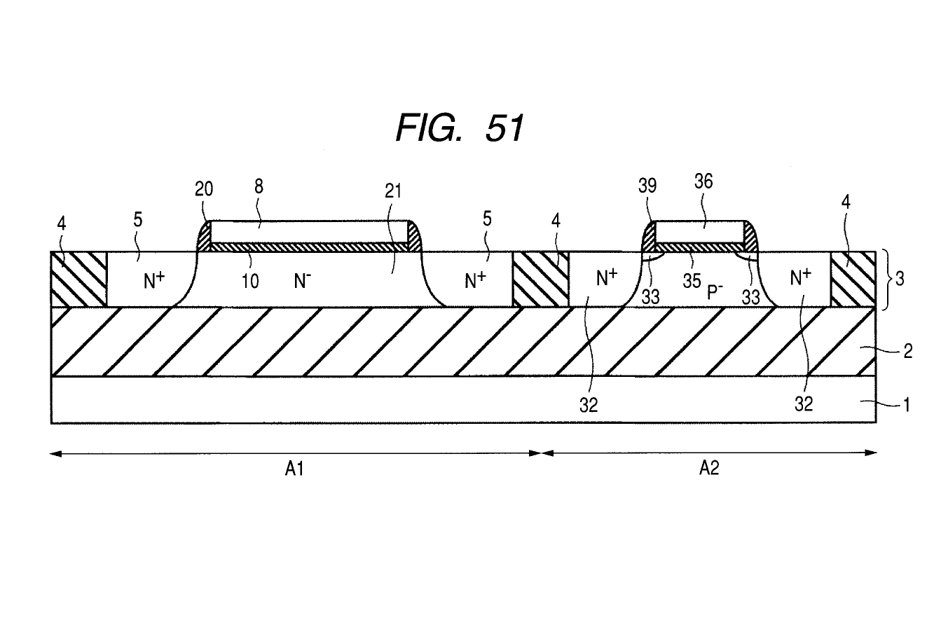

FIG. 50 and FIG. 51 are the cross-sectional views showing a part of manufacturing process of the second mode (the same body resistance with a gate electrode without an LDD region as other modes of Embodiment 3 shown by FIG. 15) of the body resistance with a gate electrode of Embodiment 3. FIG. 50 and FIG. 51 show the manufacturing process after the structure shown by FIG. 48 was acquired through the same step as the manufacturing method of the first structure of Embodiment 3. FIG. 50 and FIG. 51 show a part of step in which an NMOS transistor is formed with the body resistance with a gate electrode of Embodiment 3. FIG. 50 and FIG. 51 are equivalent to the F-F section of FIG. 11.

As shown in FIG. 50, resist pattern 50 patterned so that the N⁻ body region 21 whole surface of body resistance region A1 might be covered is formed. Then, in N type transistor region A2, impurity implantation processing of an N type for N type LDD region formation is performed by using gate electrode 8 and gate electrode 36 as a mask, and N type LDD region 33 is formed only in N type transistor region A2.

It is possible as impurity implantation processing of an N type for N type LDD region formation to implant arsenic on the implantation conditions of several to tens keV for implantation energy, and several number*10¹⁴-1*10¹⁵/cm² for impurity concentration, for example. It is possible as impurity implantation processing of a P type for P type LDD region formation to implant a boron on the implantation conditions of several keV for implantation energy, and several number*10¹⁴-1*10¹⁵/cm² for impurity concentration, for example.

Sidewall 39 is formed in the side surface of gate electrode 36 while forming sidewall 20 in the side surface of gate electrode 8 by depositing a silicon oxide film on the whole surface, and etching back it after removing resist pattern 50, as shown in FIG. 51.

And impurity implantation processing of an N type is performed by using gate electrode 8 and sidewall 20, and gate electrode 36 and sidewall 39 as a mask. N⁺ diffusion regions 5 and 5 are formed in body resistance region A1, and N⁺ diffusion regions 32 and 32 are formed in N type transistor region A2, respectively.

As impurity implantation processing of an N type at this time, it is possible to implant arsenic on the implantation conditions of tens keV for implantation energy, and several number*10¹⁵/cm² for impurity concentration, for example. As impurity implantation processing of a P type for P⁺ diffusion region formation, it is possible to implant a boron on the implantation conditions of tens keV for implantation energy, and several number*10¹⁵/cm² for impurity concentration, for example.

Henceforth, a semiconductor device including the body resistance with a gate electrode which does not have an LDD region and the NMOS transistor which are the second structure of Embodiment 3 is completed through the same processing as Embodiment 1 shown by FIG. 33-FIG. 35.

### (Manufacturing Method of Embodiment 4 (Basic Constitution))

Structurally, the MOS capacitor which is the basic constitution of Embodiment 4 is the same as that of the second mode (body resistance with an LDD-region-less gate electrode) of Embodiment 3. Therefore, the MOS capacitor (refer to FIG. 16 and FIG. 17) of the basic constitution of Embodiment 4 can be obtained with the same manufacturing method as the second mode of Embodiment 3.

### (Manufacturing Method of Embodiment 4 (Other Modes))

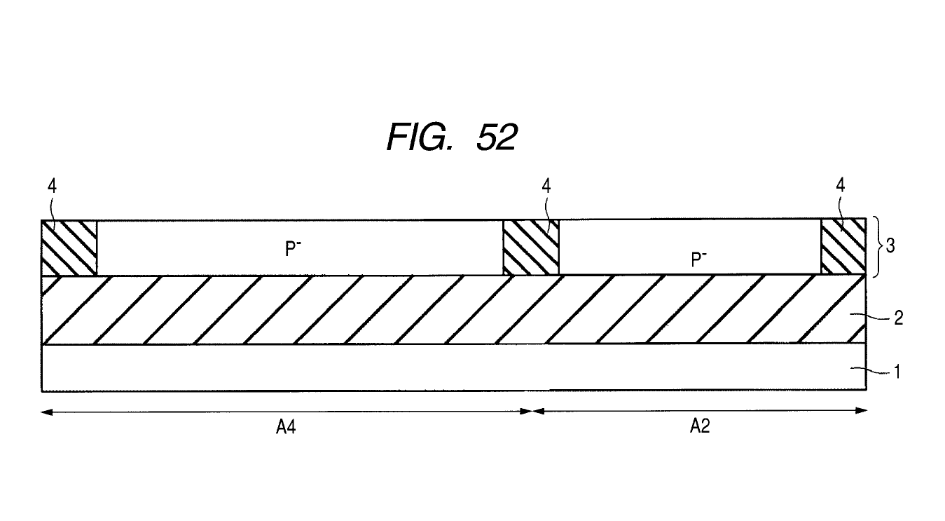

FIG. 52-FIG. 55 are the cross-sectional views showing the manufacturing process of the highly implanted doped capacitor which are other modes of the MOS capacitor of Embodiment 4 (refer to FIG. 18). FIG. 52-FIG. 55 show the manufacturing process from the state (state shown by FIG. 29) after full isolation region 4 separated according to the element isolation region forming step mentioned above. FIG. 52-FIG. 55 show the step in which an NMOS transistor is formed with the MOS capacitor of Embodiment 4. FIG. 52-FIG. 55 are equivalent to the G-G section of FIG. 16.

First, as shown in FIG. 52, after performing impurity implantation of the boron for well region formation and setting SOI layer 3 as P⁻ in MOS capacitor formation area A4 and N type transistor region A2, silicon oxide film 24 (refer to FIG. 29) formed in the front surface of SOI layer 3 is removed. Boron implantation is performed by several hundred keV for implantation energies, and several 10¹³/cm² for impurity concentration.

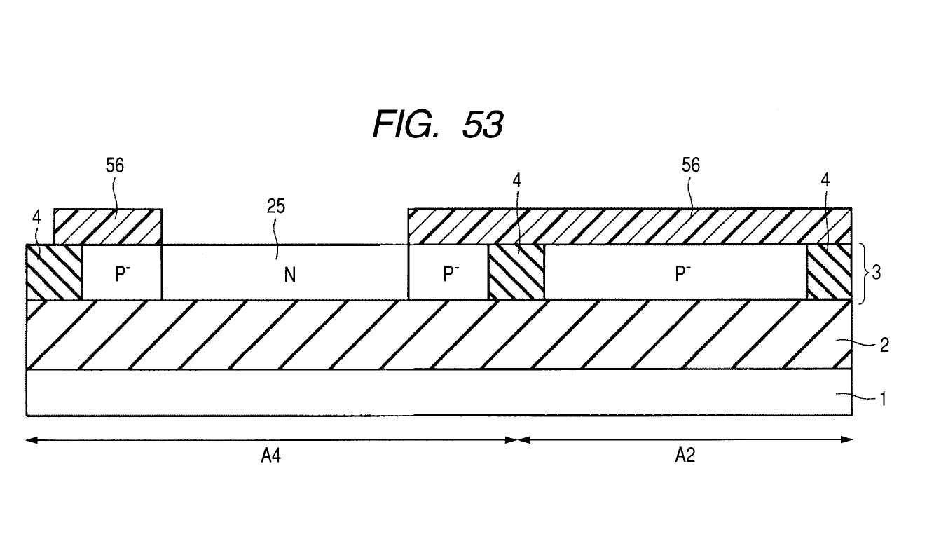

And as shown in FIG. 53, resist pattern 56 which has an opening in the central part (high concentration region formation area) of MOS capacitor formation area A4 is formed. Phosphorus is implanted by using resist pattern 56 as a mask, and high concentration region 25 of an N type is formed in SOI layer 3 of MOS capacitor formation area A4. As for implantation of phosphorus, it is possible to implant on the implantation conditions of 40-80 keV for implantation energy, and 1-10*10¹⁵/cm² for impurity concentration, for example.

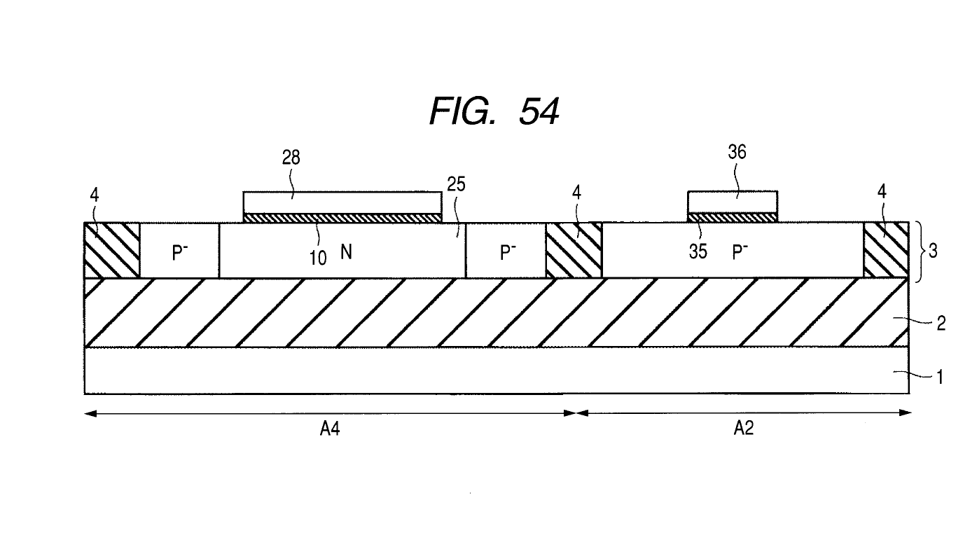

Next, as shown in FIG. 54, the native oxide film (not shown in FIG. 52 and FIG. 53) formed in the front surface is removed, an oxide film is deposited in several nanometers thickness, and polysilicon is deposited in about tens-100 nm thickness one by one. Then, by patterning, while obtaining the laminated structure of gate oxide film 10 and gate electrode 8 on high concentration region 25 of MOS capacitor formation area A4, the laminated structure of gate oxide film 35 and gate electrode 36 is obtained in N type transistor region A2.

And the resist pattern (not shown) patterned so that the SOI layer 3 whole surface comprising high concentration region 25 of MOS capacitor formation area A4 might be covered is formed like the step in the second structure of Embodiment 3 shown by FIG. 50.

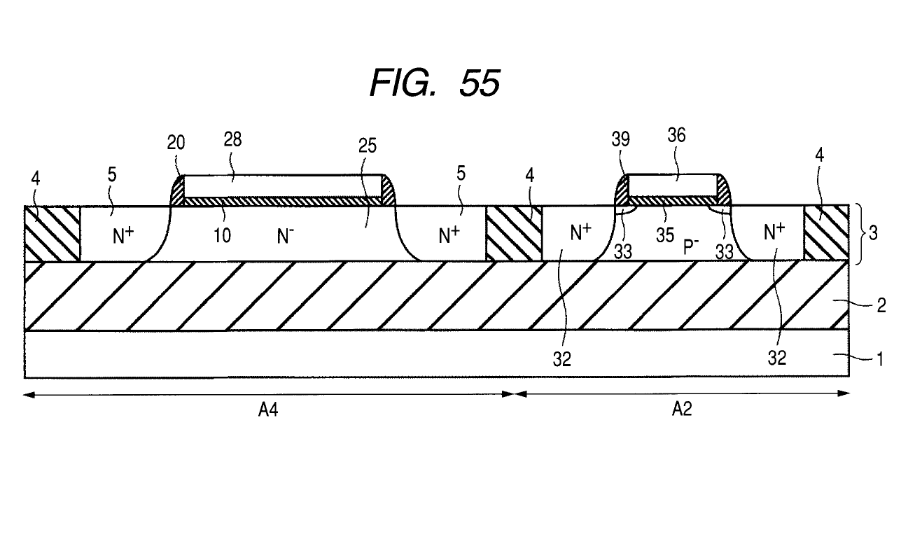

Then, as shown in FIG. 55, in N type transistor region A2, impurity implantation processing of an N type for N type LDD region formation is performed by using gate electrode 36 as a mask, and N type LDD region 33 is formed only in N type transistor region A2.

It is possible as impurity implantation processing of an N type for N type LDD region formation to implant arsenic on the implantation conditions of several to tens keV for implantation energy, and several number*10¹⁴-1*10¹⁵/cm² for impurity concentration, for example. It is possible as impurity implantation processing of a P type for P type LDD region formation to implant a boron on the implantation conditions of several keV for implantation energies, and several number*10¹⁴-1*10¹⁵/cm² for impurity concentration, for example.

Sidewall 39 is formed in the side surface of gate electrode 36 while forming sidewall 20 in the side surface of gate electrode 8 by depositing a silicon oxide film on the whole surface, and etching back it, as shown in FIG. 55 after removing the above-mentioned resist pattern.

And impurity implantation processing of an N type is performed by using gate electrode 8 and sidewall 20, and gate electrode 36 and sidewall 39 as a mask. N⁺ diffusion regions 5 and 5 are formed in MOS capacitor formation area A4, and N⁺ diffusion regions 32 and 32 are formed in N type transistor region A2, respectively.

As impurity implantation processing of an N type at this time, it is possible to implant arsenic on the implantation conditions of tens keV for implantation energy, and several number*10¹⁵/cm² for impurity concentration, for example. As impurity implantation processing of a P type for P⁺ diffusion region formation, it is possible to implant a boron on the implantation conditions of tens keV for implantation energy, and several number*10¹⁵/cm² for impurity concentration, for example.

Henceforth, a semiconductor device including the capacitor dope MOS capacitor and NMOS transistor which are other structures of Embodiment 4 is completed through the same processing as Embodiment 1 shown by FIG. 33-FIG. 35.

### <Application>

### (Application of Embodiment 1)

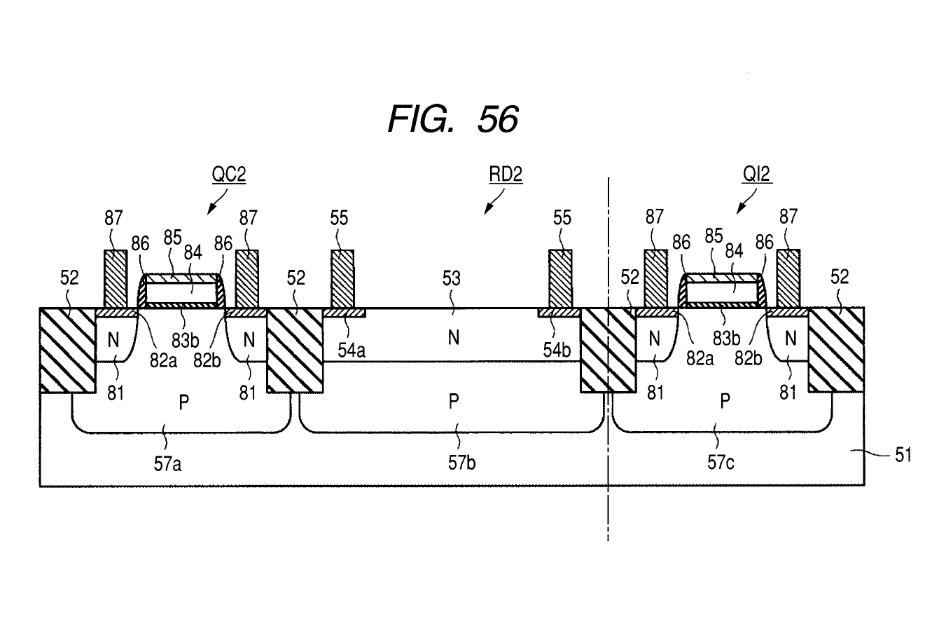

FIG. 56 is a cross-sectional view showing the structure of the semiconductor device which formed diffusion resistance RD2 on the conventional bulk substrate with two or more sorts of transistors (core transistor QC2, I/O transistor QI2).

As shown in the same drawing, P well regions 57a-57c are selectively formed in the upper layer portion of Si substrate 51 of a P type, and P well regions 57a-57c are separated by STI region 52 formed between each.

N⁺ diffusion regions 81 and 81 are selectively formed in the upper layer portion of P well region 57a, and gate electrode 84 is formed via gate oxide film 83a on P well region 57a between N⁺ diffusion regions 81 and 81. Silicide region 85 is formed on gate electrode 84, and sidewall 86 is formed in the side surface of gate oxide film 83a, gate electrode 84, and silicide region 85. Silicide regions 82a and 82b are formed in the front surface of N⁺ diffusion region 81, and metal plugs 87 and 87 are formed on silicide region 82a and 82b. Thus, core transistor QC2 is formed in P well region 57a. A core transistor means the transistor which forms a logical circuit, SRAM, etc.

N⁺ diffusion region 53 is formed in the upper layer portion of P well region 57b, silicide regions 54a and 54b are selectively formed in the front surface of the both ends of N⁺ diffusion region 53, and metal plugs 55 and 55 are formed on silicide region 54a and 54b. Thus, diffusion resistance RD2 is formed in P well region 57b.

N⁺ diffusion regions 81 and 81 are selectively formed in the upper layer portion of P well region 57c, gate electrode 84 is formed via gate oxide film 83b on P well region 57c between N⁺ diffusion regions 81 and 81, and silicide region 85 is formed on gate electrode 84. Sidewall 86 is formed in the side surface of gate oxide film 83b, gate electrode 84, and silicide region 85. Silicide regions 82a and 82b are formed in the front surface of N⁺ diffusion region 81, and metal plugs 87 and 87 are formed on silicide region 82a and 82b. Thus, I/O transistor QI2 is formed in P well region 57c. An I/O transistor means the transistor which forms an electrical power system circuit etc.

Core transistor QC2, diffusion resistance RD2, and I/O transistor QI2 which were mentioned above are formed on Si substrate 51, and element isolation is done by STI region 52. However, for example, leakage current occurs between well regions, such as a channel of P well region 57a, Si substrate 51 of the P type under STI region 52, and P well region 57b. In order to avoid the above-mentioned leakage current, the restrictions which perform optimization of the gap of isolation (distance between well regions) or the impurity profile implanted etc. occurred, and there was a problem that the flexibility of a circuit layout was restricted.

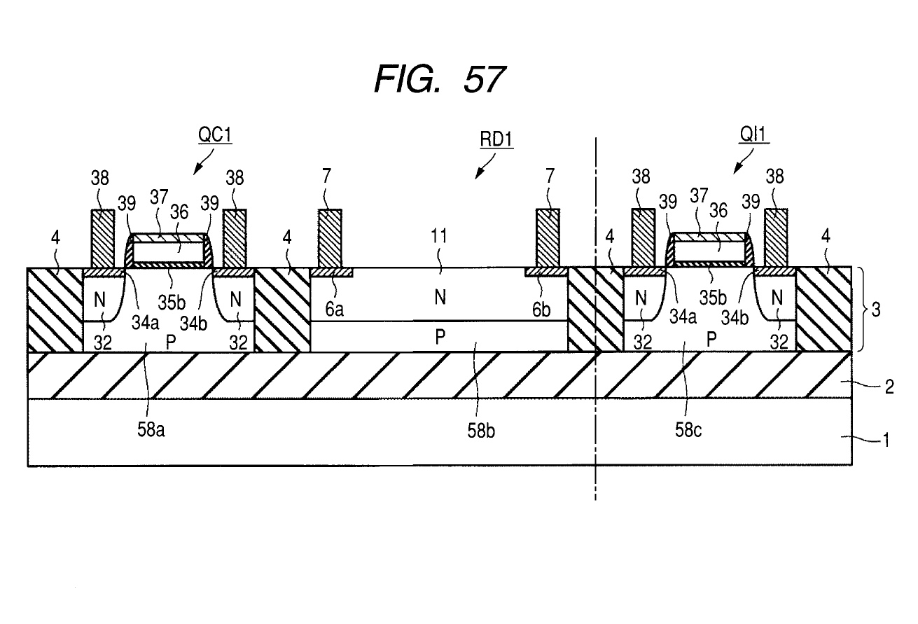

FIG. 57 is a cross-sectional view showing the structure of the semiconductor device which formed diffusion resistance RD1 of Embodiment 1 with two or more sorts of transistors (core transistor QC1, I/O transistor QI1).

As shown in the same drawing, P well regions 58a-58c are formed in SOI layer 3 of the SOI substrate which consists of supporting substrate 1, buried oxide film 2, and SOI layer 3 of a P type. P well regions 58a-58c are separated by full isolation region 4 formed by penetrating SOI layer 3 between each.

N⁺ diffusion regions 32 and 32 are selectively formed in the upper layer portion of P well region 58a, and gate electrode 36 is formed via gate oxide film 35a on P well region 58a between N⁺ diffusion regions 32 and 32. Silicide film 37 is formed on gate electrode 36, and sidewall 39 is formed in the side surface of gate oxide film 35a, gate electrode 36, and silicide film 37. Silicide films 34a and 34b are formed in the front surface of N⁺ diffusion region 32, and metal plugs 38 and 38 are formed on silicide film 34a and 34b. Thus, core transistor QC1 is formed in P well region 58a.

N⁺ diffusion region 11 is formed in the upper layer portion of P well region 58b, silicide films 6a and 6b are selectively formed in the front surface of the both ends of N⁺ diffusion region 11, and metal plugs 7 and 7 are formed on silicide film 6a and 6b. Thus, diffusion resistance RD1 is formed in P well region 58b.

N⁺ diffusion regions 32 and 32 are selectively formed in the upper layer portion of P well region 58c, gate electrode 36 is formed via gate oxide film 35b on P well region 58c between N⁺ diffusion regions 32 and 32, and silicide film 37 is formed on gate electrode 36. Sidewall 39 is formed in the side surface of gate oxide film 35b, gate electrode 36, and silicide film 37. Silicide films 34a and 34b are formed in the front surface of N⁺ diffusion region 32, and metal plugs 38 and 38 are formed on silicide film 34a and 34b. Thus, I/O transistor QI1 is formed in P well region 58c.

Core transistor QC1, diffusion resistance RD1, and I/O transistor QI1 which were mentioned above are formed in SOI layer 3, and they are mutually electrically thoroughly insulated by full isolation region 4 and buried oxide film 2.

Therefore, it is not necessary to take into consideration a problem of leakage current like the case of forming on the bulk substrate shown by FIG. 56, the restrictions regarding element isolation are not received, and the effect that the flexibility of a circuit design can be extended is performed.

### (Application of Embodiment 2)

The semiconductor device which manufactures a core transistor and an I/O transistor simultaneously with body resistance of Embodiment 2 can be considered as an application of Embodiment 2. Generally, the impurity implantation conditions of well region formation and the impurity implantation conditions of a channel dope differ between a core transistor and an I/O transistor.

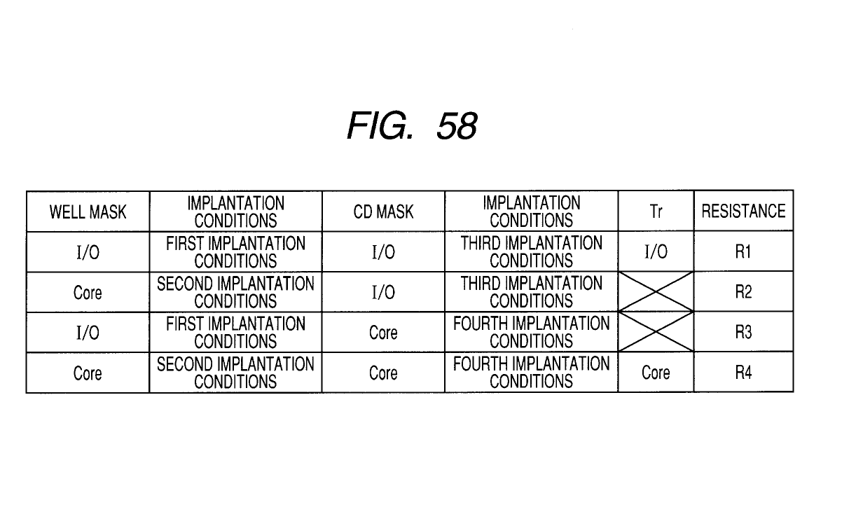

FIG. 58 is an explanatory diagram showing the variation of resistance in the case of forming N⁻ body region 21 of body resistance of Embodiment 2 according to tabular form, using the mask for well region formation (Well mask) and the mask for channel dope region formation (CD mask) of an I/O transistor and a core transistor.

In FIG. 58, the impurity conditions of well region formation of a core transistor and an I/O transistor are made into the first and the second implantation conditions, and the impurity conditions of well region formation of a core transistor and an I/O transistor are shown as the third and the fourth implantation conditions. When forming a core transistor and an I/O transistor from an NMOS transistor, as the first and the second implantation conditions, impurity implantation of different contents using boron can be considered. The impurity implantation using arsenic can be considered as the third implantation condition, and the impurity implantation using the boron can be considered as the fourth implantation condition.

As shown in FIG. 58, when the mask for I/O transistors is used as a CD mask using the mask for I/O transistors as a Well mask, the body region (resistance main part) of resistance R1 can be obtained with an I/O transistor.

When the mask for I/O transistors is used as a CD mask using the mask for core transistors as a Well mask, the body region (resistance main part) of resistance R2 can be obtained.

When the mask for core transistors is used as a CD mask using the mask for I/O transistors as a Well mask, the body region (resistance main part) of resistance R3 can be obtained.

When the mask for core transistors is used as a CD mask using the mask for core transistors as a Well mask, the body region (resistance main part) of resistance R4 can be obtained with a core transistor.

Thus, the body resistance which has four kinds of resistance (R1-R4) can be obtained by forming a body region using the Well mask and CD mask of an I/O transistor and a core transistor. Since a core transistor and the I/O transistor need to set threshold voltage as a desired value, the number of them is one, respectively and they are manufactured a total of two kinds.

When making and dividing a transistor in SoC (System On Chip) etc. and it has a mask only for a memory (SRAM) further as a CD mask, body resistance of a total of six kinds (2×3) of resistance can be obtained combining two kinds (the object for I/O transistors, for core transistors (for memories)) of Well masks, and three kinds (the object for I/O transistors, the object for core transistors, for memories) of CD masks. Further, the body resistance which has 12 kinds (6×2) of resistance can be obtained by combining the conductivity type (a P type, an N type) of a transistor.

Thus, two or more sorts of resistance can be set up with sufficient accuracy by separating each element, such as body resistance and a transistor, by full isolation region 4. When the variation of resistance becomes abundant, the effect which leads also to the reduction of area of a body region is performed. The body resistance with a gate electrode of Embodiment 3 can demonstrate this effect similarly.

### (Concrete Structure)

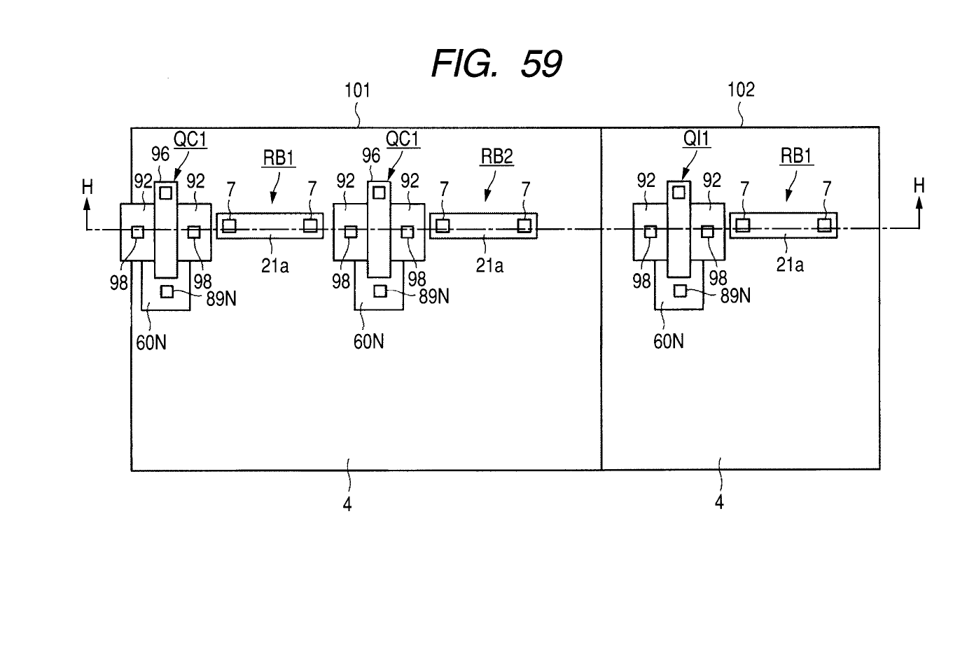

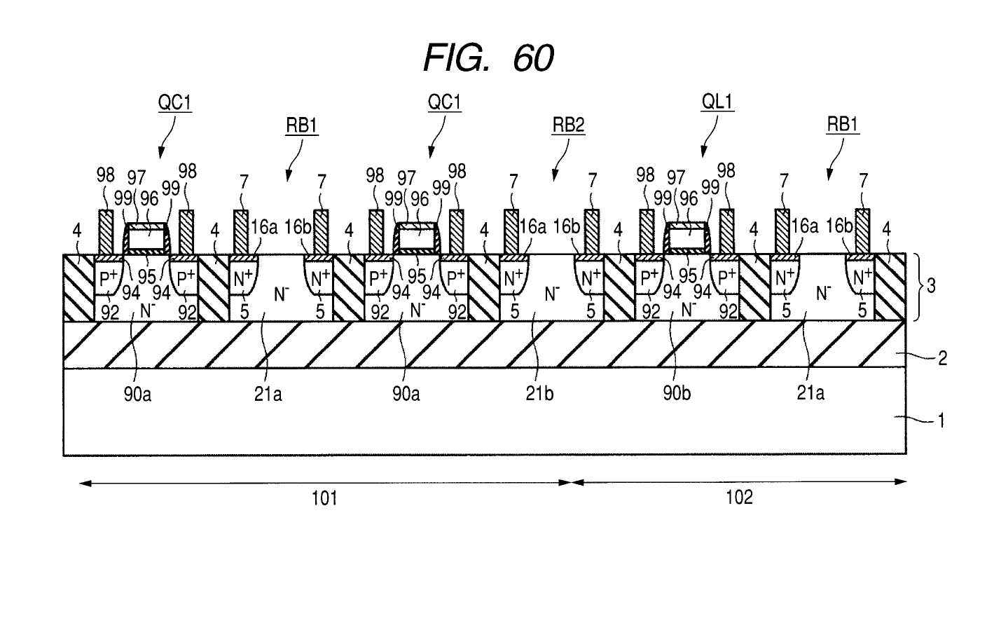

FIG. 59 is a plan view showing the semiconductor device which is an application of Embodiment 2, and FIG. 60 is a cross-sectional view showing the H-H section of FIG. 59. As shown in these drawings, the semiconductor device with which two kinds of body resistance RB1 and RB2 of Embodiment 2 is formed in Core circuit part 101 and I/O circuit part 102 is shown.

As shown in these drawings, an SOI substrate is formed by forming buried oxide film 2 on supporting substrate 1, and forming SOI layer 3 on buried oxide film 2. SOI layer 3 is separated into six element (from the left of FIG. 60, core transistor QC1, body resistance RB1, core transistor QC1 and body resistance RB2 in the inside of Core circuit part 101, and I/O transistor QI1 and body resistance RB1 in the inside of I/O circuit part 102) formation area by full isolation region 4 formed by penetrating SOI layer 3.

P⁺ diffusion regions 92 and 92 are selectively formed in the upper layer portion of two N well regions 90a formed in Core circuit part 101. Gate electrode 96 is formed via gate oxide film 95 on N well region 90a between P⁺ diffusion regions 92 and 92, and silicide film 97 is formed on gate electrode 96. Sidewall 99 is formed in the side surface of gate oxide film 95, gate electrode 96, and silicide film 97.

And silicide film 94 is formed in the front surface of P⁺ diffusion region 92. Metal plug 98 is formed on silicide film 94. Thus, core transistor QC1 of PMOS structure is formed in N well region 90a. As for core transistor QC1, body contact region 60N for body potential fixation is formed in the gate length extending direction of gate electrode 96, and metal plug 89N is formed on body contact region 60N.

N⁻ body region 21a is formed in SOI layer 3 in Core circuit part 101, and N⁺ diffusion regions 5 and 5 are formed in the upper layer portion of the ends of N⁻ body region 21a, respectively.

Silicide film 16a is formed in the front surface of N⁺ diffusion region 5 at the side of one end, silicide film 16b is formed in the front surface of N⁺ diffusion region 5 at the side of the other end, and metal plugs 7 and 7 are formed on silicide film 16a and 16b. Thus, body resistance RB1 is formed in N⁻ body region 21a.

N⁻ body region 21b is formed in SOI layer 3 in Core circuit part 101, and N⁺ diffusion regions 5 and 5 are formed in the upper layer portion of the ends of N⁻ body region 21b, respectively.

Silicide film 16a is formed in the front surface of N⁺ diffusion region 5 at the side of one end, silicide film 16b is formed in the front surface of N⁺ diffusion region 5 at the side of the other end, and metal plugs 7 and 7 are formed on silicide film 16a and 16b. Thus, body resistance RB2 is formed in N⁻ body region 21b.

P⁺ diffusion regions 92 and 92 are selectively formed in the upper layer portion of N well region 90b formed in I/O circuit part 102. Gate electrode 96 is formed via gate oxide film 95 on N well region 90b between P⁺ diffusion regions 92 and 92, and silicide film 97 is formed on gate electrode 96. Sidewall 99 is formed in the side surface of gate oxide film 95, gate electrode 96, and silicide film 97.

And silicide film 94 is formed in the front surface of P⁺ diffusion region 92. Metal plug 98 is formed on silicide film 94. Thus, I/O transistor QI1 is formed in N well region 90b. As for I/O transistor QI1, body contact region 60N for body potential fixation is formed in the gate length extending direction of gate electrode 96, and metal plug 89N is formed on body contact region 60N.

N well region 90a means the well region formed on the first implantation conditions that used the Well mask for core transistors. N well region 90b means the well region formed on the second implantation conditions that used the Well mask for I/O transistors. N⁻ body region 21a means the body region formed simultaneously with N well region 90a on the first implantation conditions that used the Well mask for core transistors. N⁻ body region 21b means the body region formed simultaneously with N well region 90b on the second implantation conditions that used the Well mask for I/O transistors.

One implantation conditions are adopted among the first and the second implantation conditions in order to form N well region 90a and 90b, and N⁻ body region 21 (N-body regions 21a and 21b) is formed. Hereby, in Core circuit part 101 and I/O circuit part 102, body resistance RB1 and RB2 for which a resistor main part has two kinds of resistance (resistance determined by N⁻ body region 21a and 21b) can be formed. Diversification of the variation of resistance can be aimed at.

The reason why N⁻ body region 21b formed simultaneously with N well region 90b of an I/O transistor can be formed in Core circuit part 101, and N⁻ body region 21a formed simultaneously with N well region 90a can be formed in I/O circuit part 102 is because the impurity implantation conditions to N⁻ body region 21 can be set up arbitrarily, without taking junction leak, a latch up, etc. into consideration, since between each element can separate thoroughly by full isolation region 4 on an SOI substrate. Since the separation distance between each element can be narrowly set up by separating between elements by full isolation region 4, reduction of a circuit area can be aimed at.

The example shown by FIG. 59 and FIG. 60 shows only 1 kind of body resistance RB1 to I/O circuit part 102. However, naturally body resistance RB2 which has the resistance of the other can be formed with body resistance RB1 by forming N⁻ body region 21b formed simultaneously with N well region 90b in I/O circuit part 102.

### (Forming Step of Two or More Sorts of Transistors)

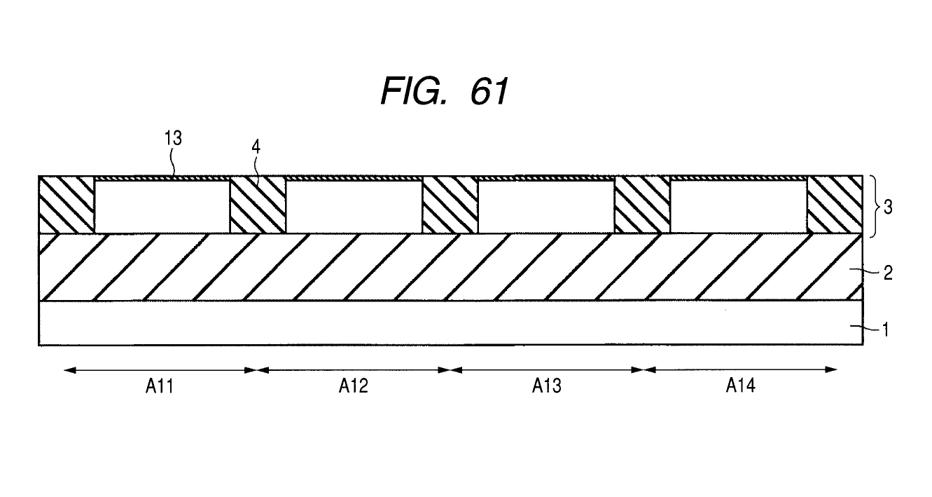

FIG. 61-FIG. 82 are the cross-sectional views showing the forming step of two or more sorts of transistors. The forming step of four kinds of transistors of the core transistor and I/O transistor of NMOS transistor structure, and the core transistor and I/O transistor of PMOS structure is shown as two or more sorts of transistors.

The step shown by FIG. 61-FIG. 82 shows the example which uses a Well mask in common with the core transistor and I/O transistor of the same conductivity type, and uses different masks with a core transistor and an I/O transistor as to CD masks.

First, as shown in FIG. 61, passing the element isolation step shown by FIG. 21-FIG. 29, the structure where element isolation of Core NMOS region A1, I/O NMOS region A12, Core PMOS region A13, and I/O PMOS region A14 in SOI layer 3 was done by full isolation region 4 is acquired.

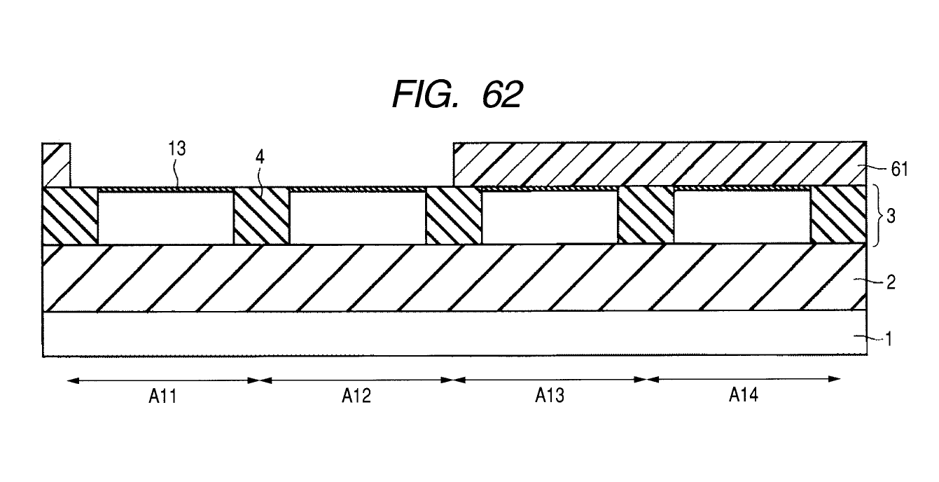

Next, as shown in FIG. 62, resist is applied, resist is patterned with photolithography process technology, and resist pattern 61 (Well mask) which covers only a PMOS formation area (Core PMOS region A13 and I/O PMOS region A14) is obtained.

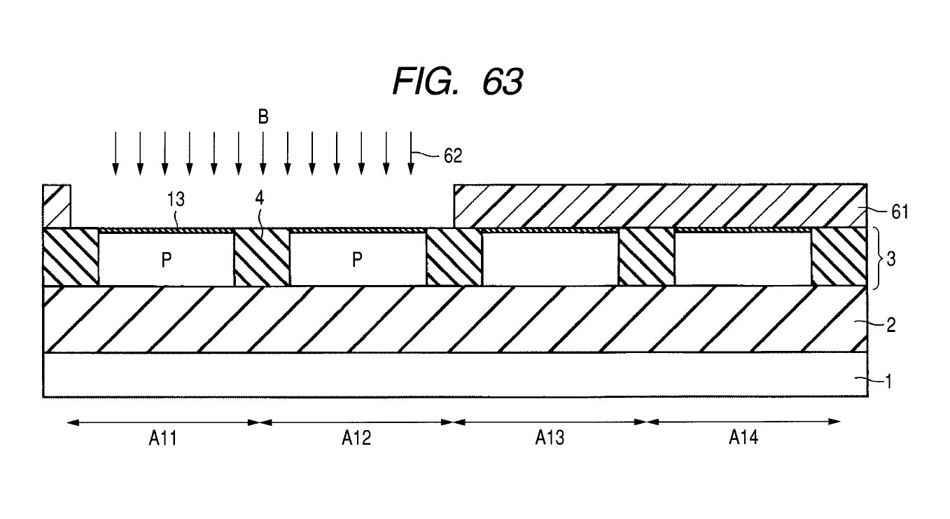

And as shown in FIG. 63, using resist pattern 61 as a mask, boron ion 62 is implanted into SOI layer 3 of an NMOS formation area (Core NMOS region A11 and I/O NMOS region A12) on the implantation conditions of tens keV for implantation energy, and several 10¹³/cm² for impurity concentration. As a result, the conductivity type of SOI layer 3 of Core NMOS region A11 and I/O NMOS region A12 is set as a P type, and P well region is formed.

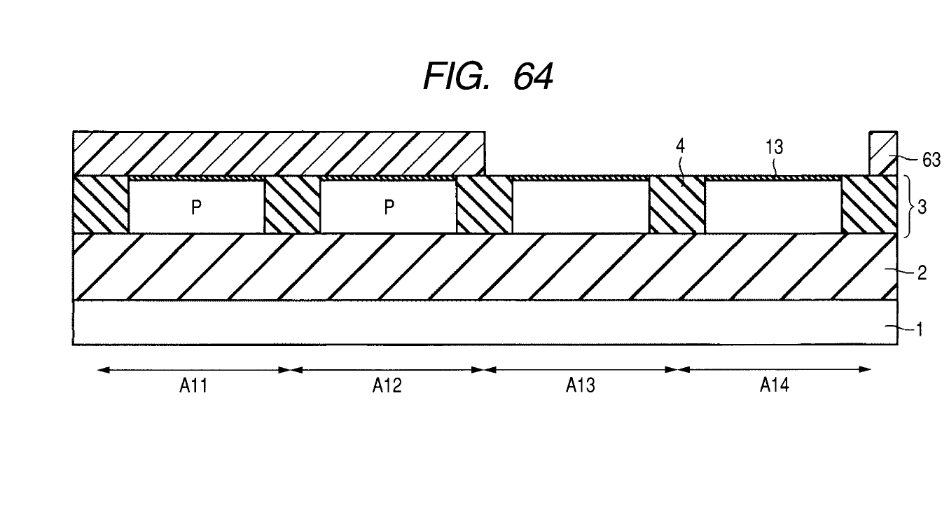

Next, as shown in FIG. 64, resist pattern 61 is removed, resist is applied again, resist is patterned with photolithography process technology, and resist pattern 63 (Well mask) which covers only an NMOS formation area is obtained.

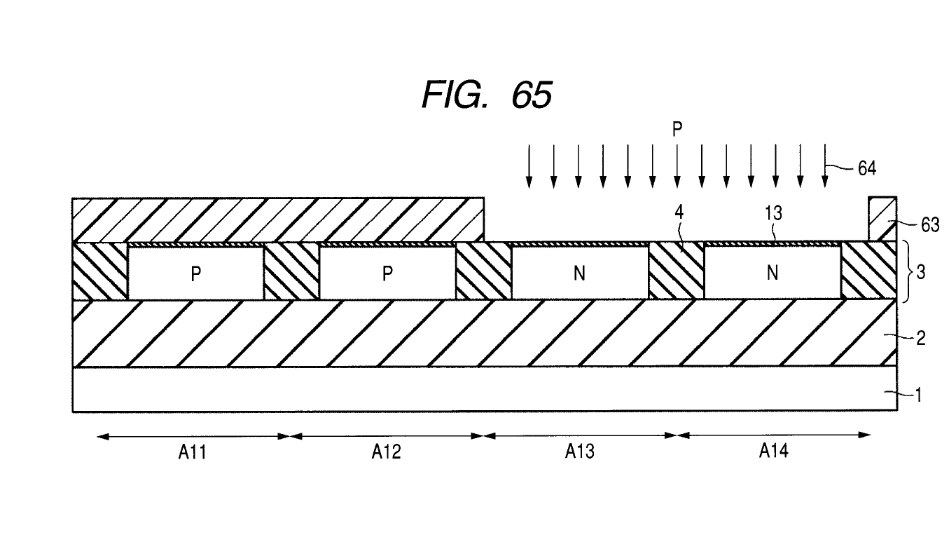

And as shown in FIG. 65, phosphorus ion 64 is implanted into SOI layer 3 of a PMOS formation area by using resist pattern 63 as a mask on the implantation conditions of hundreds keV for implantation energy, and several 10¹³/cm² for impurity concentration. As a result, the conductivity type of SOI layer 3 of Core PMOS region A13 and I/O PMOS region A14 is set as an N type, and N well region is formed.

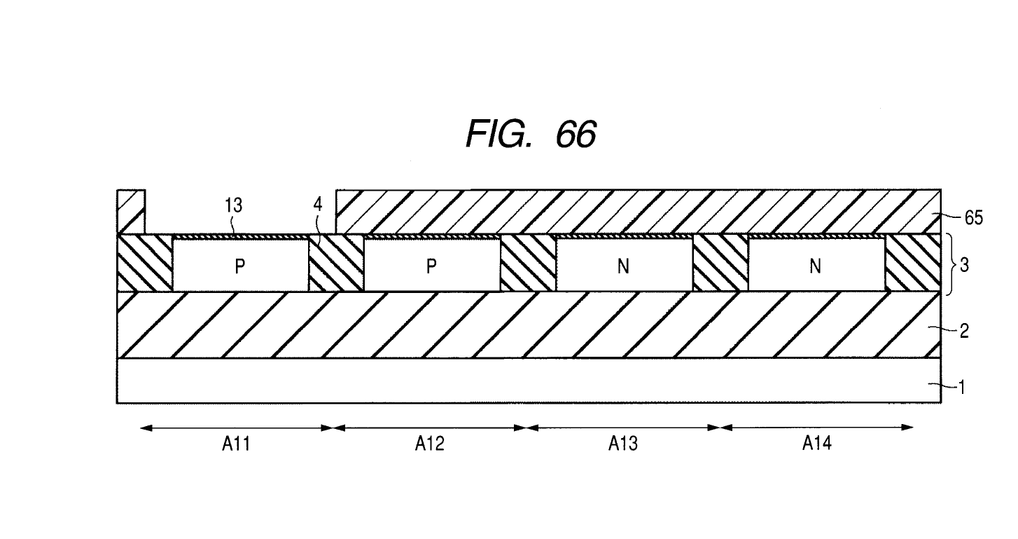

Next, as shown in FIG. 66, resist pattern 63 is removed, resist is applied again, resist is patterned with photolithography process technology, and resist pattern 65 (CD mask) which made only Core NMOS region A11 have an opening is obtained.

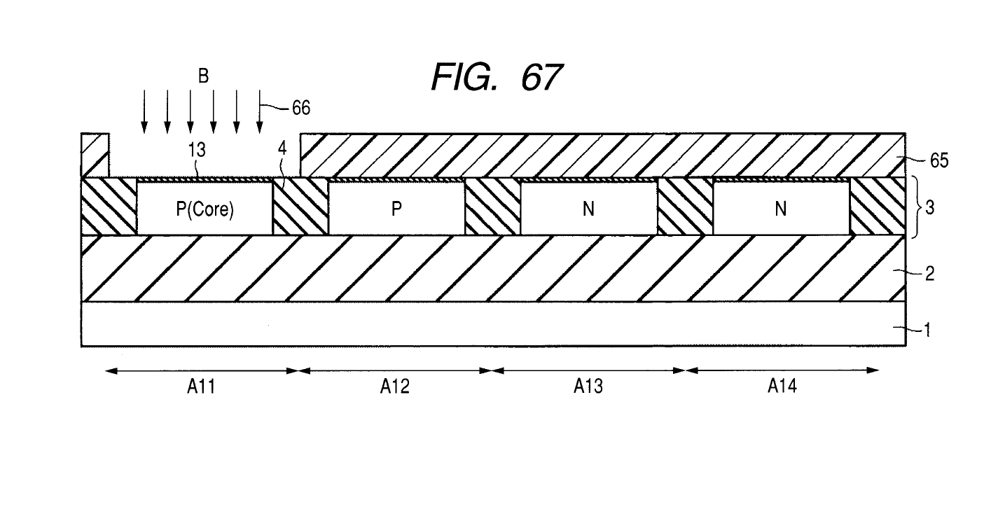

And as shown in FIG. 67, boron ion 66 is implanted into SOI layer 3 of Core NMOS region A11 by using resist pattern 65 as a mask on the implantation conditions of tens keV for implantation energy, and several 10¹³/cm² for impurity concentration. As a result, P well region (for core transistors (Core)) is formed in Core NMOS region A11.

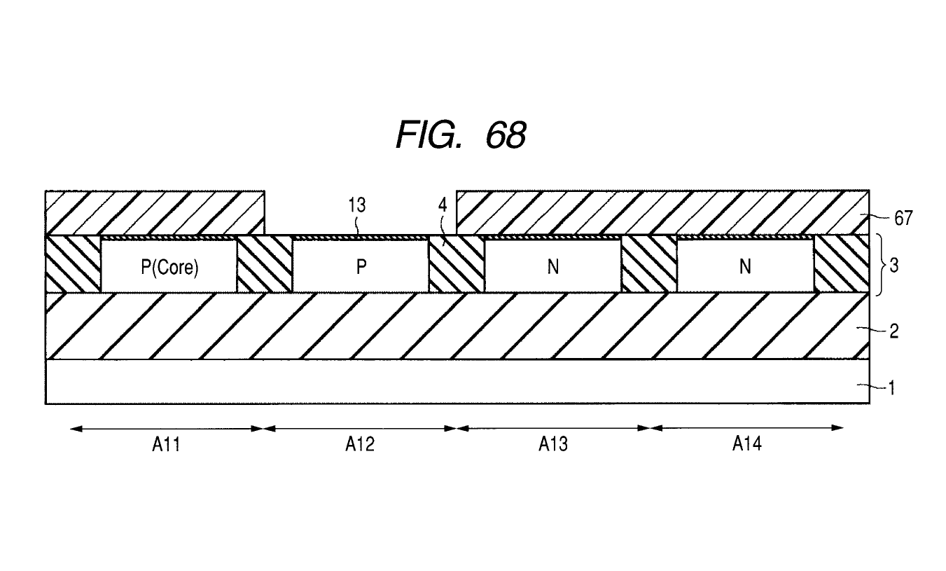

Next, as shown in FIG. 68, resist pattern 65 is removed, resist is applied again, resist is patterned with photolithography process technology, and resist pattern 67 (CD mask) which made only I/O NMOS region A12 have an opening is obtained.

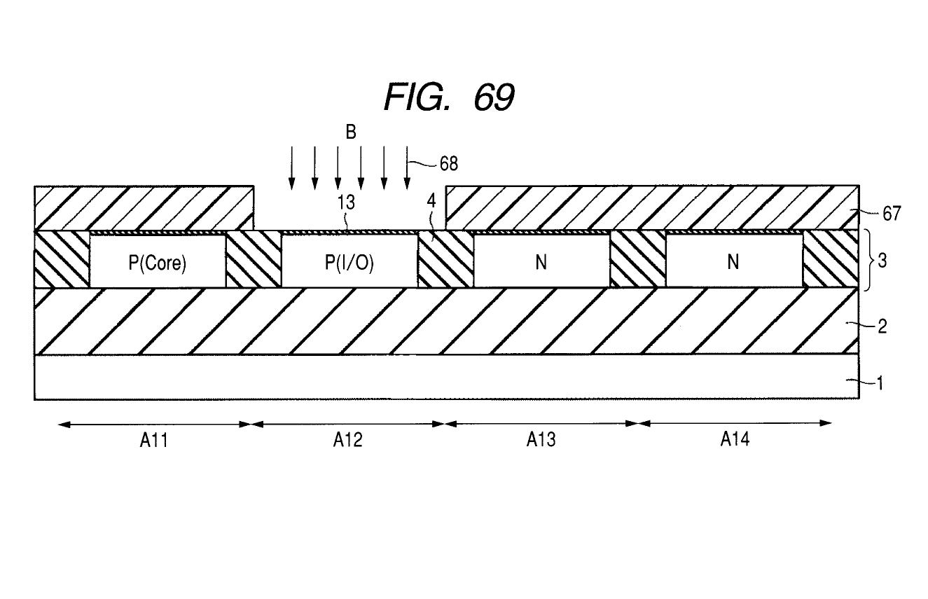

And as shown in FIG. 69, boron ion 68 is implanted into SOI layer 3 of I/O NMOS region A12 by using resist pattern 67 as a mask on the implantation conditions of tens keV for implantation energy, and several 10¹³/cm² for impurity concentration. However, the implantation conditions of boron ion 68 are set as different conditions from the implantation conditions (refer to FIG. 67) of boron ion 66. As a result, P well region (I/O transistor (I/O)) is formed in I/O NMOS region A12.

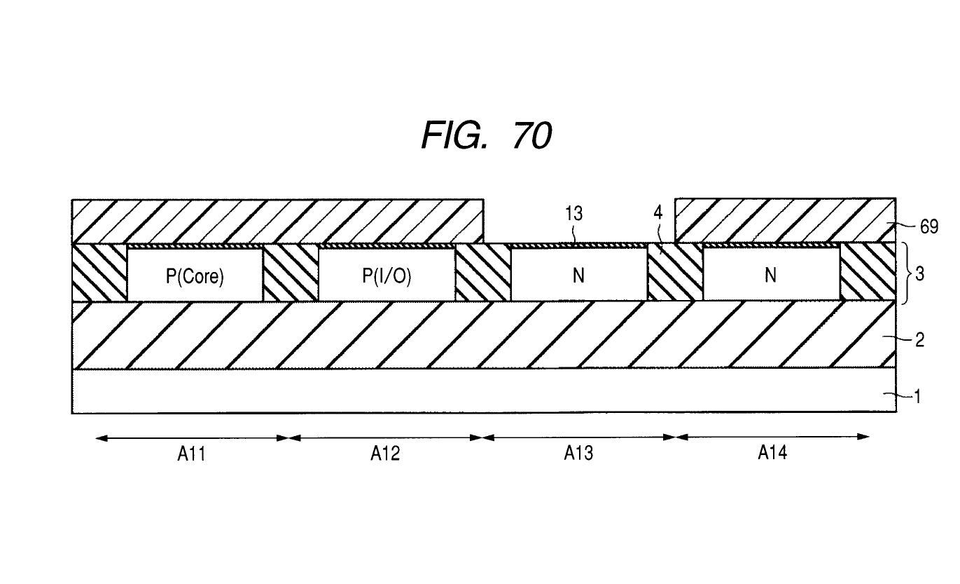

Next, as shown in FIG. 70, resist pattern 67 is removed, resist is applied again, resist is patterned with photolithography process technology, and resist pattern 69 (CD mask) which made only Core PMOS region A13 have an opening is obtained.

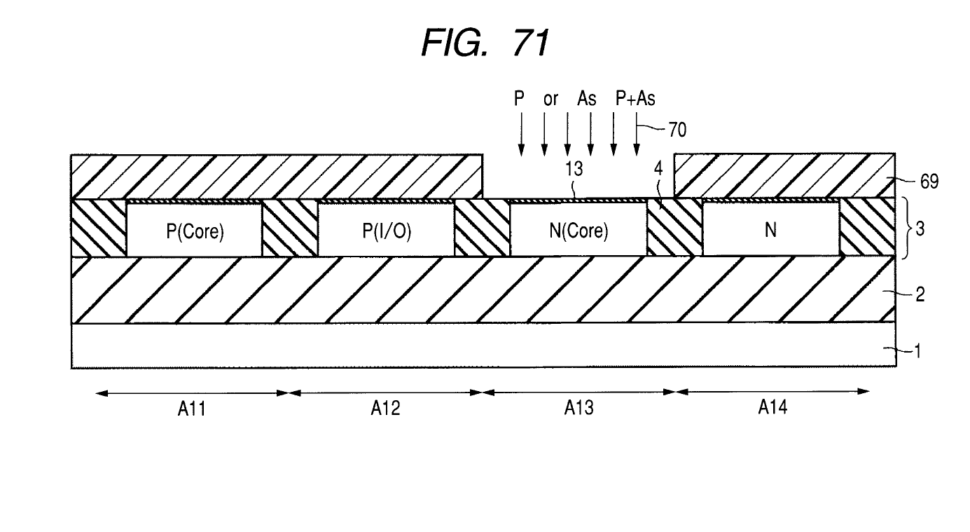

And as shown in FIG. 71, ion 70, such as phosphorus, is implanted into SOI layer 3 of Core PMOS region A13 by using resist pattern 69 as a mask on the implantation conditions of hundreds keV for implantation energy, and several 10¹³/cm² for impurity concentration (when it is phosphorus). As a result, N well region (for core transistors (Core)) is formed in Core PMOS region A13. Implanting arsenic, or both arsenic and phosphorus instead of phosphorus is also considered. In the case of arsenic, it implants on the implantation conditions of tens keV for implantation energy, and several 10¹²/cm² for impurity concentration.

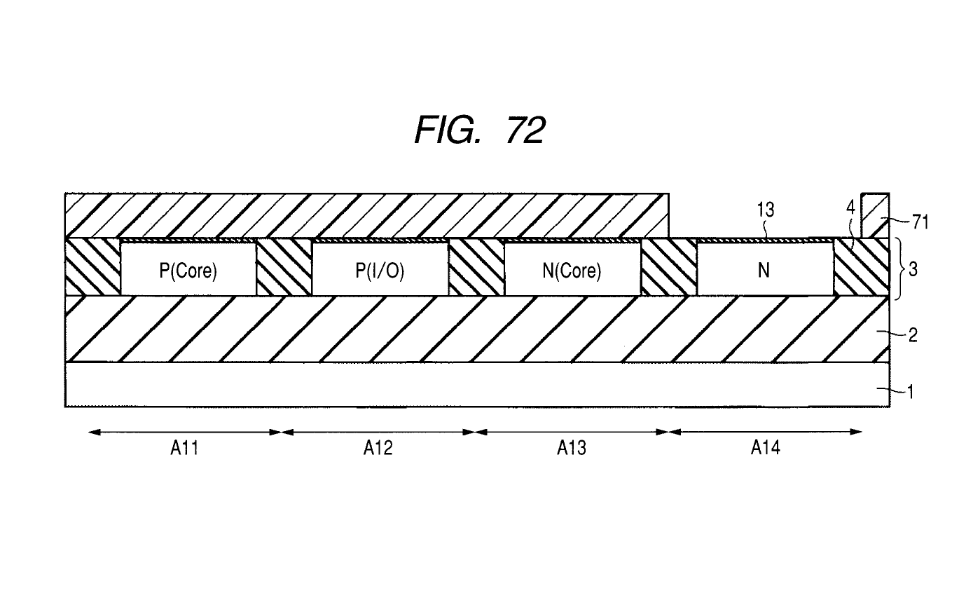

Next, as shown in FIG. 72, resist pattern 69 is removed, resist is applied again, resist is patterned with photolithography process technology, and resist pattern 71 (CD mask) which made only I/O PMOS region A14 have an opening is obtained.

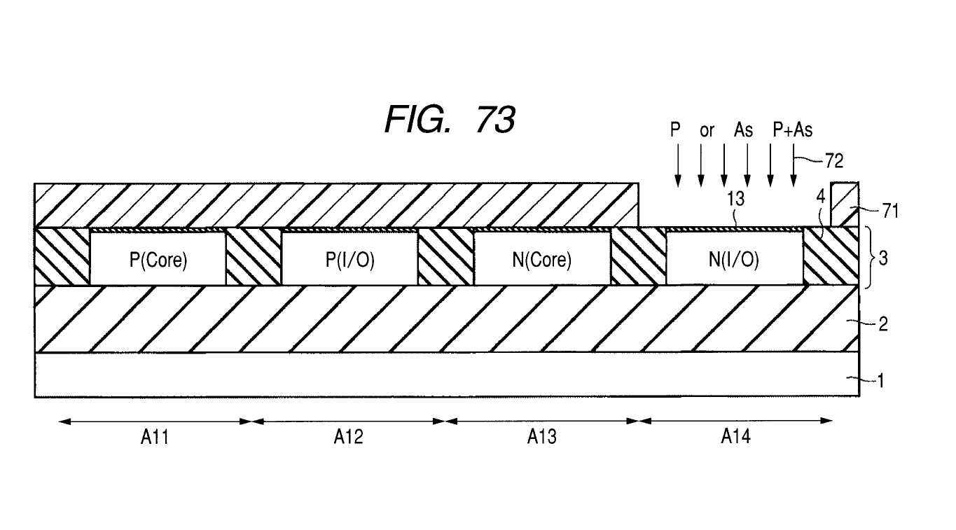

And as shown in FIG. 73, ion 72, such as phosphorus, is implanted into SOI layer 3 of I/O PMOS region A14 by using resist pattern 71 as a mask on the implantation conditions of tens keV for implantation energy, and several 10¹²/cm² for impurity concentration (when it is phosphorus). However, the implantation conditions of ion 72, such as phosphorus, and the implantation conditions of ion 70, such as phosphorus, are set up by different contents. As a result, N well region (for I/O transistors (I/O)) is formed in I/O PMOS region A14. Implanting arsenic, or both arsenic and phosphorus instead of phosphorus is also considered. In the case of arsenic, it implants on the implantation conditions of tens keV for implantation energy, and several 10¹²/cm² for impurity concentration.

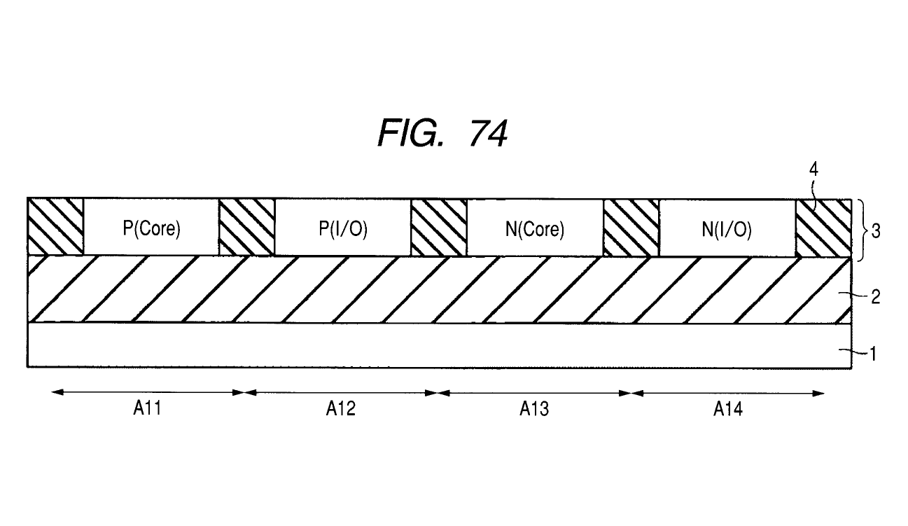

Then, as shown in FIG. 74, resist pattern 71 is removed and silicon oxide film 13 formed on the front surface of SOI layer 3 is removed further.

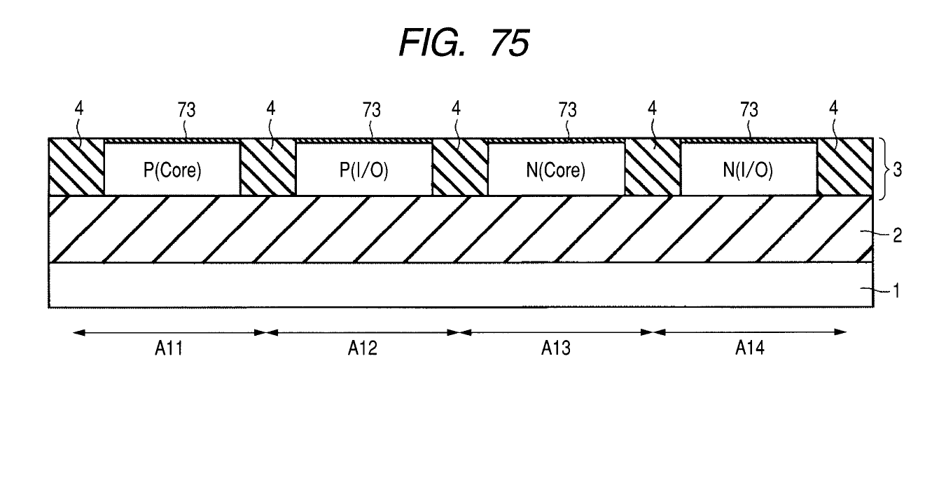

Then, as shown in FIG. 75, gate oxide film 73 is formed in the front surface of SOI layer 3 by tens of nm thickness.

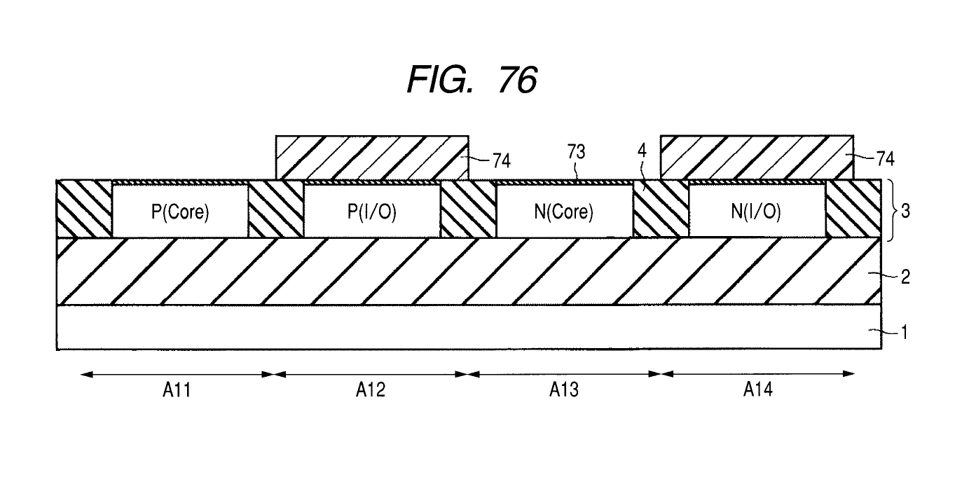

And as shown in FIG. 76, resist is applied, resist is patterned with photolithography process technology, and resist pattern 74 which made Core NMOS region A11 and Core PMOS region A13 have an opening is obtained.

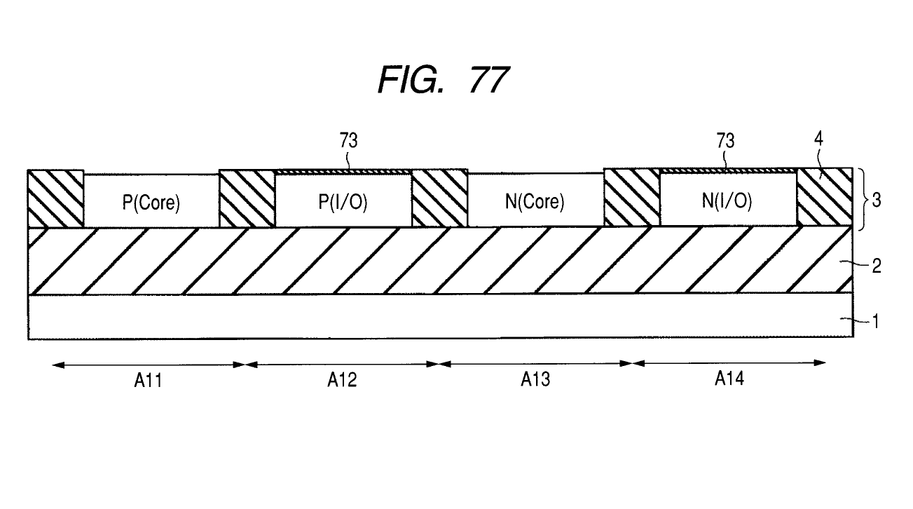

Next, as shown in FIG. 77, gate oxide film 73 formed in Core NMOS region A11 and Core PMOS region A13 is removed by using resist pattern 74 as a mask, and wet etching treatment removes resist pattern 74.

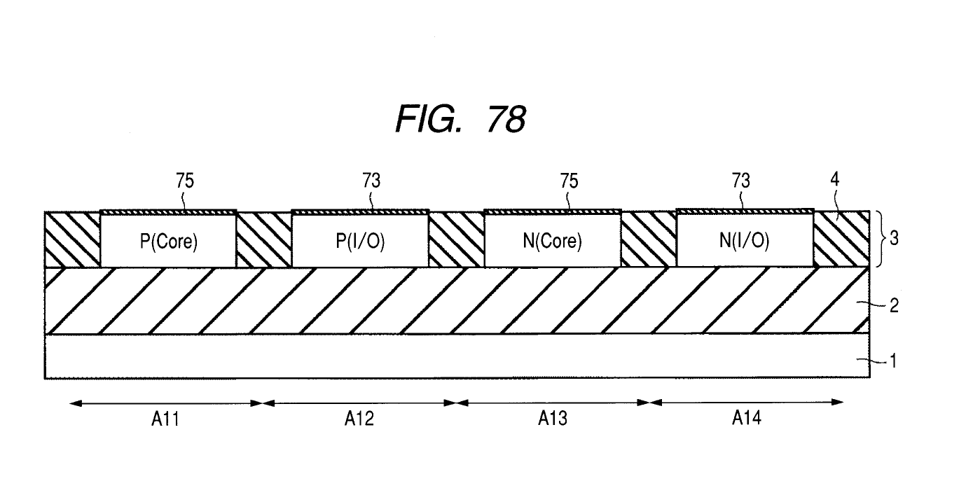

And as shown in FIG. 78, in Core NMOS region A11 and Core PMOS region A13, gate oxide film 75 of several nanometers-tens of nm thickness is formed by oxidizing front surface upper part of SOI layer 3. On this occasion, the thickness of gate oxide film 73 in I/O NMOS region A12 and I/O PMOS region A14 increases.

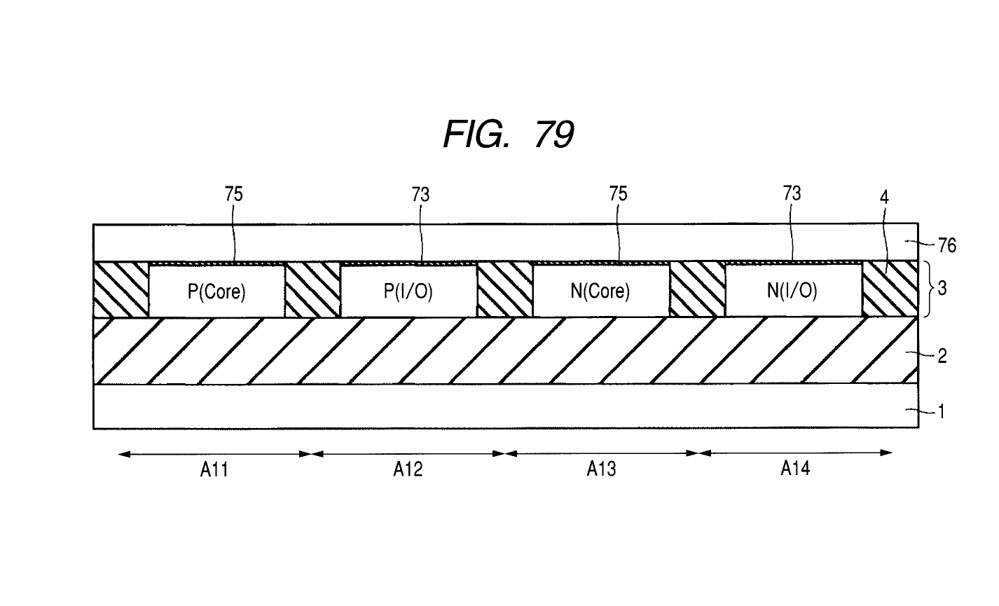

Then, as shown in FIG. 79, polysilicon layer 76 of the P type of the thickness of tens-several 100 nm is deposited on the whole surface.

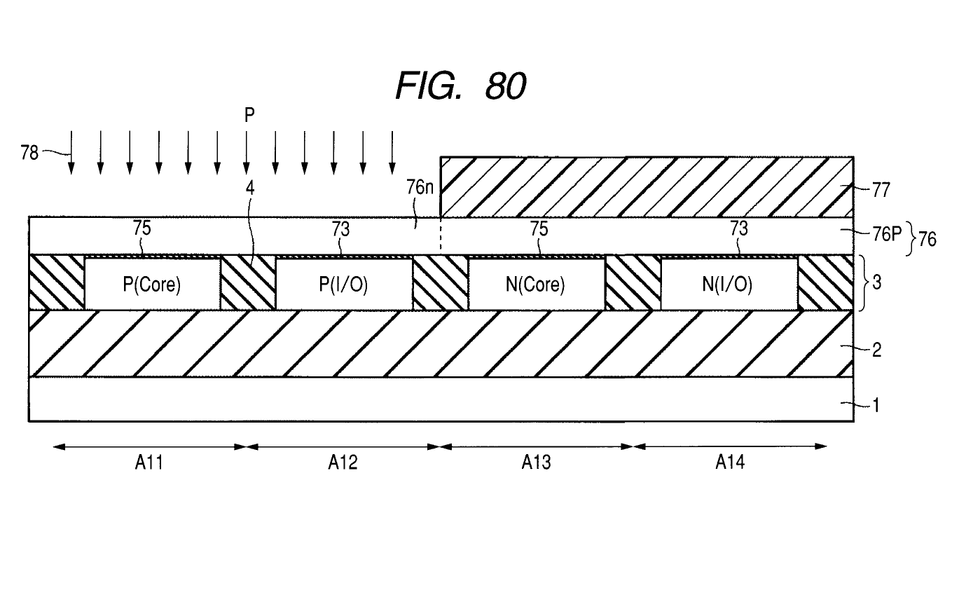

And as shown in FIG. 80, resist is applied, resist is patterned with photolithography process technology, and resist pattern 77 which made the NMOS formation area have an opening is obtained. Then, phosphorus ion 78 is implanted by using resist pattern 77 as a mask on the implantation conditions of tens keV for implantation energy, and several 10¹⁵/cm² for impurity concentration. N type gate part 76n is formed in polysilicon layer 76 on an NMOS formation area. As a result, polysilicon layer 76 under resist pattern 77 constitutes P type gate part 76p.

To control a work function (threshold voltage), the resist pattern which has an opening in a PMOS formation area may be formed with photolithography process technology etc., and boron ion may be implanted to polysilicon layer 76 on the implantation conditions of several keV for implantation energy, and several 10¹⁵/cm² for impurity concentration.

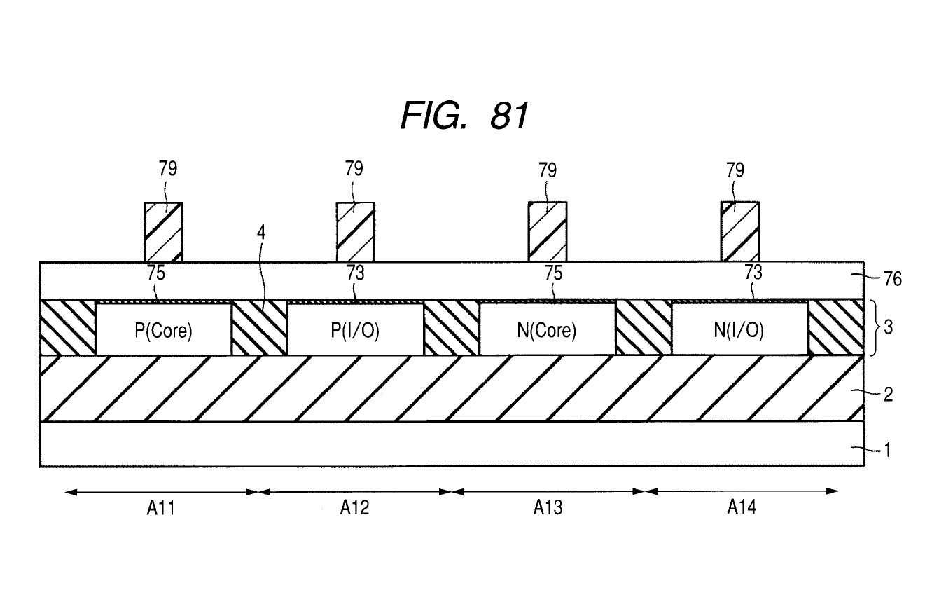

And as shown in FIG. 81, resist is applied, resist is patterned with photolithography process technology, and resist pattern 79 which made only the gate electrode formation area remain is obtained.

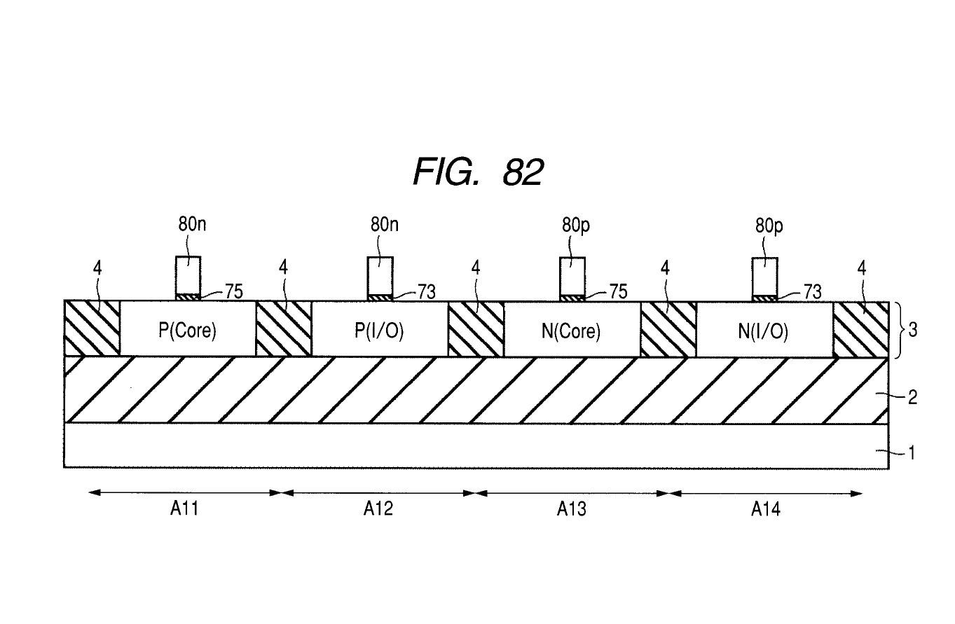

Then, as shown in FIG. 82, by etching polysilicon layer 76 and gate oxide film 73 (75) by using resist pattern 79 as a mask, N type gate electrodes 80n are formed in an NMOS formation area, and P type gate electrode 80p is formed in a PMOS formation area.

Subsequent steps are performed like the steps of Embodiment 1 shown by FIG. 32-FIG. 35.

The combination of the well region forming step which is impurity implantation processing using the Well mask at the time of the forming step of four kinds of transistors of such core transistor and I/O transistor of NMOS transistor structure and the core transistor and I/O transistor of PMOS structure, and the channel dope step using CD mask is chosen suitably, and the body resistance which has a plurality of resistance can be formed simultaneously.

### EXAMPLE OF A LAYOUT PATTERN

### First Example

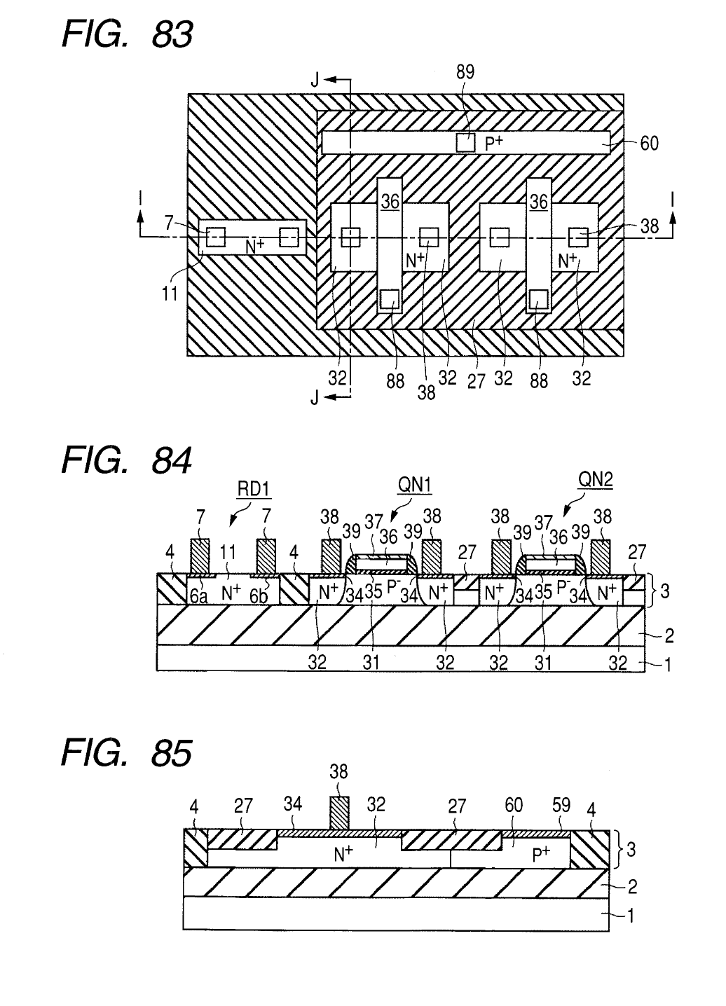

FIG. 83 is a plan view showing the first example of the layout pattern of the semiconductor device which has the diffusion resistance RD1, etc. of Embodiment 1. FIG. 84 is a cross-sectional view showing the I-I section of FIG. 83, and FIG. 85 is a cross-sectional view showing the J-J section of FIG. 83. In FIG. 83, silicide regions, such as silicide films 6a and 6b, are not shown on account of explanation.

As shown in these drawings, buried oxide film 2 is formed on supporting substrates 1, such as a Si substrate, and SOI layer 3 is formed on buried oxide film 2. An SOI substrate is formed by these supporting substrate 1, buried oxide film 2, and SOI layer 3.

N⁺ diffusion region 11 is selectively formed in SOI layer 3, and full isolation region 4 is formed covering all the peripheral regions of N⁺ diffusion region 11 in plan view.

Silicide film 6a is formed in the front surface at the side of one end of N⁺ diffusion region 11, silicide film 6b is formed in the front surface at the side of the other end, and metal plugs 7 and 7 are formed on silicide film 6a and 6b.

Thus, N⁺ diffusion region 11 has a resistor main part, and diffusion resistance RD1 which used silicide film 6a as one end, and used silicide film 6b as the other end is formed.

On the other hand, NMOS transistor QN1 and QN2 by which element isolation is done to diffusion resistance RD1 by full isolation region 4, and element isolation is done to each other by partial isolation region 27 are collectively formed.

In the formation area of NMOS transistor QN1 and QN2 in SOI layer 3, N⁺ diffusion regions 32 and 32 are formed at the both sides of P⁻ body region 58 in SOI layer 3. Gate electrode 36 is formed via gate oxide film 35 on P⁻ body region 31 between N⁺ diffusion regions 32 and 32, silicide film 37 is formed on gate electrode 36, and sidewall 39 is formed in the side surface of gate oxide film 35, gate electrode 36, and silicide film 37.

And silicide film 34 is formed in the front surface of N⁺ diffusion region 32, and metal plug 38 is formed on silicide film 34.

As shown in FIG. 84, partial isolation region 27 where a part of SOI layer 3 remained in the lower layer separates between NMOS transistors QN1 and QN2, and full isolation region 4 separates between NMOS transistor QN1 and diffusion resistance RD1. Correctly, in FIG. 84, although partial isolation region 27 exists also between diffusion resistance RD1 and NMOS transistor QN1, illustration is omitted on account of explanation.

As shown in FIG. 83, body contact region 60 shared by NMOS transistor QN1 and QN2 is formed, and fixed potential is given to body contact region 60 via metal plug 89.

As shown in FIG. 85, P⁻ body region 31 of NMOS transistor QN1 (QN2) is electrically connected with body contact region 60 via SOI layer 3 under partial isolation region 27. And silicide region 59 is formed in the front surface of body contact region 60.

Diffusion resistance RD1 of Embodiment 1 was represented with FIG. 83-FIG. 85 among Embodiment 1-Embodiment 4, and it was shown by them. However, even when using body resistance of Embodiment 2, the body resistance with a gate electrode of Embodiment 3, or the MOS capacitor of Embodiment 4 instead of diffusion resistance RD1, the same layout structure is possible.

Although the first example of the layout pattern showed the NMOS transistor as an MOS transistor formed with diffusion resistance RD1, in a PMOS transistor, of course, it can form similarly.

### Second Example

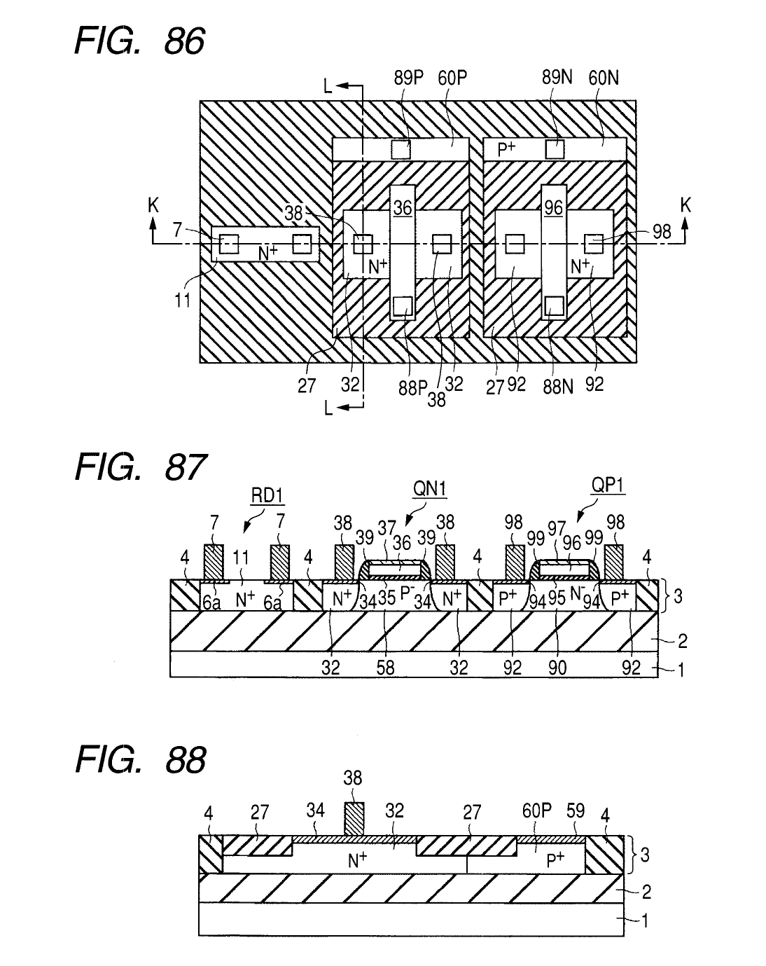

FIG. 86 is a plan view showing the second example of the layout pattern of the semiconductor device which has the diffusion resistance RD1, etc. of Embodiment 1. FIG. 87 is a cross-sectional view showing the K-K section of FIG. 86, and FIG. 88 is a cross-sectional view showing the L-L section of FIG. 86. In FIG. 86, silicide regions, such as silicide films 6a and 6b, are not shown on account of explanation.

As shown in these drawings, diffusion resistance RD1 by which element isolation was done by full isolation region 4 is formed in SOI layer 3 like the first example.

On the other hand, element isolation of NMOS transistor QN1 and diffusion resistance RD1 is done by full isolation region 4, and element isolation of NMOS transistor QN1 and PMOS transistor QP1 is mutually done by full isolation region 4. And each of NMOS transistor QN1 and PMOS transistor QP1 is separated to body contact region 60 (60P, 60N) by partial isolation region 27.

NMOS transistor QN1 is formed like the first example. On the other hand, in the formation area of PMOS transistor QP1 of SOI layer 3, P⁺ diffusion regions 92 and 92 are formed at the both sides of N⁻ body region 90 in SOI layer 3. Gate electrode 96 is formed via gate oxide film 95 on N⁻ body region 90 between P⁺ diffusion regions 92 and 92, silicide film 97 is formed on gate electrode 96, and sidewall 99 is formed in the side surface of gate oxide film 95, gate electrode 96, and silicide film 97.

And silicide film 94 is formed in the front surface of P⁺ diffusion region 92, and metal plug 98 is formed on silicide film 94.

As shown in FIG. 87, full isolation of NMOS transistor QN1 and PMOS transistor QP1 is done by full isolation region 4, and between NMOS transistor QN1 and diffusion resistance RD1 is also separated by full isolation region 4.

As shown in FIG. 86, body contact region 60P of NMOS transistor QN1 is formed, and fixed potential is given to body contact region 60P via metal plug 89P. And body contact region 60N of PMOS transistor QP1 is independently formed via full isolation region 4 to P type body contact region 60P. Fixed potential is given to body contact region 60N via metal plug 89N.

As shown in FIG. 88, P⁻ body region 31 of NMOS transistor QN1 is electrically connected with body contact region 60P via SOI layer 3 under partial isolation region 27. And silicide region 59 is formed in the front surface of body contact region 60P. Similarly, N⁻ body region 90 of PMOS transistor QP1 is electrically connected with body contact region 60N via SOI layer 3 under partial isolation region 27. And silicide region 59 is formed in the front surface of body contact region 60N.

Thus, in addition to the leak component from diffusion resistance RD1, in the second example, merits, such as latch-up free, are also generated by separating between NMOS transistor QN1 and PMOS transistor QP1 by full isolation region 4.

Diffusion resistance RD1 of Embodiment 1 was represented with FIG. 86-FIG. 88 among Embodiment 1-Embodiment 4, and it was shown by them. However, instead of diffusion resistance RD1, even when using body resistance of Embodiment 2, the body resistance with a gate electrode of Embodiment 3, or the MOS capacitor of Embodiment 4, the same layout structure is possible.

### Third Example

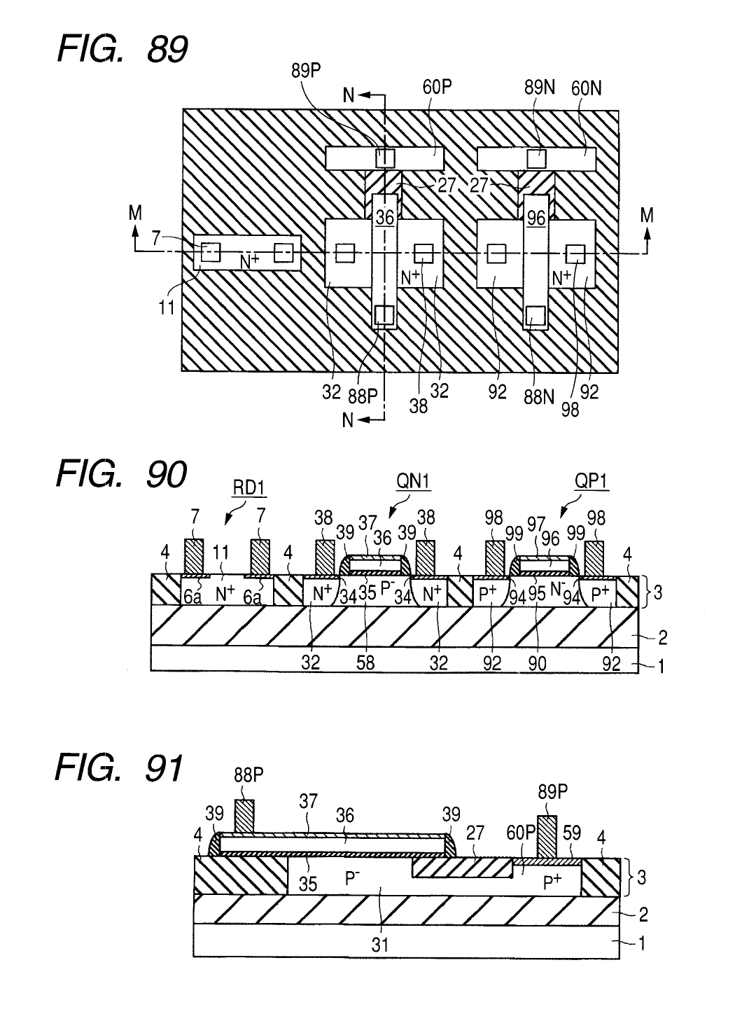

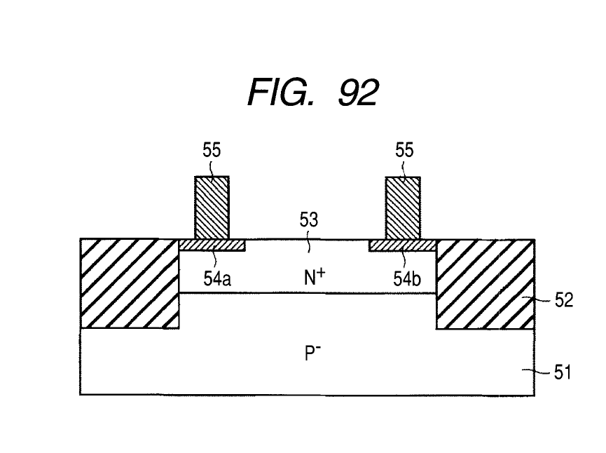

FIG. 89 is a plan view showing the third example of the layout pattern of the semiconductor device which has the diffusion resistance RD1, etc. of Embodiment 1. FIG. 90 is a cross-sectional view showing the M-M section of FIG. 89, and FIG. 91 is a cross-sectional view showing the N-N section of FIG. 89. In FIG. 89, silicide regions, such as silicide films 6a and 6b, are not shown on account of explanation.

As shown in these drawings, diffusion resistance RD1 by which element isolation was done by full isolation region 4 is formed in SOI layer 3 like the first example.

On the other hand, element isolation of NMOS transistor QN1 and diffusion resistance RD1 is done by full isolation region 4. Element isolation of NMOS transistor QN1 and PMOS transistor QP1 is mutually done by full isolation region 4. And in each of NMOS transistor QN1 and PMOS transistor QP1, only the straight line channel of the central part of body contact region 60 (60P, 60N), and gate electrode 36 (96), and its neighboring region are separated by partial isolation region 27, and the others are separated by full isolation region 4.

NMOS transistor QN1 and PMOS transistor QP1 are fundamentally formed like the second example.

As shown in FIG. 90, full isolation of NMOS transistor QN1 and PMOS transistor QP1 is done by full isolation region 4, and between NMOS transistor QN1 and diffusion resistance RD1 is also separated by full isolation region 4.

As shown in FIG. 89, body contact region 60P of NMOS transistor QN1 and N type body contact region 60N of PMOS transistor QP1 are formed like the second example.

As shown in FIG. 91, P⁻ body region 31 of NMOS transistor QN1 is electrically connected with body contact region 60P via SOI layer 3 under partial isolation region 27 like the second example. However, as clearly from FIG. 89, partial isolation region 27 and SOI layer 3 of the lower part are formed only in one extension line upper part of gate length direction of gate electrode 36, and its neighboring region. Similarly, N⁻ body region 90 of PMOS transistor QP1 is electrically connected with body contact region 60N via SOI layer 3 under partial isolation region 27. However, partial isolation region 27 and SOI layer 3 of the lower part are formed only in one extension line upper part of gate length direction of gate electrode 96, and its neighboring region.

Thus, in addition to the leak component from diffusion resistance RD1, in the third example, merits, such as a latch-up free, are also generated by separating between NMOS transistor QN1 and PMOS transistor QP1 by full isolation region 4. The PN-junction capacity generated in N⁺ diffusion region 32 (P⁺ diffusion region 92) used as a source/drain region is reducible by forming partial isolation region 27, and its lower layer SOI layer 3 only in a region required for body fixation.

Diffusion resistance RD1 of Embodiment 1 was represented with FIG. 89-FIG. 91 among Embodiment 1-Embodiment 4, and it was shown by them. However, instead of diffusion resistance RD1, even when using body resistance of Embodiment 2, the body resistance with a gate electrode of Embodiment 3, or the MOS capacitor of Embodiment 4, the same layout structure is possible.

When doing contiguity arrangement of NMOS transistors and the PMOS transistors, of course, they can be formed similarly.

What is claimed is:

1. A semiconductor device which comprises a diffusion resistance formed in an SOI layer of an SOI substrate which has a semiconductor substrate, a buried insulating film formed over the semiconductor substrate, and the SOI layer formed over the buried insulating film,
wherein the diffusion resistance includes
a diffusion region of a first conductivity type formed in the SOI layer; and
a one side and an other side silicide films formed in a front surface of the diffusion region only in a neighboring region of a one side end and an other side end in a predetermined formation direction, respectively; wherein a region which does not have the one side and the other side silicide films in an upper layer portion in the diffusion region is specified as a resistor main part;
wherein the semiconductor device further comprises a full isolation region which is formed in all regions of a peripheral region of the diffusion region by penetrating the SOI layer and which has insulation.

2. A semiconductor device which comprises a body resistance formed in an SOI layer of an SOI substrate which has a semiconductor substrate, a buried insulating film formed over the semiconductor substrate, and the SOI layer formed over the buried insulating film,
wherein the body resistance includes
a body region of a first conductivity type formed in the SOI layer; and
a one side and an other side diffusion regions of a first conductivity type which is formed in the SOI layer and which is respectively formed adjoining one side and other side of a predetermined formation direction of the body region; wherein an impurity concentration of a first conductivity type of the one side and the other side diffusion regions is set up more highly than the body region;
further including a one side and an other side silicide films which are formed at least in a front surface of the one side and the other side diffusion regions, and which are mutually independent; wherein a region which does not have the one side and the other side silicide films in an upper layer portion in the body region is specified as a resistor main part;
wherein the semiconductor device further comprises a full isolation region which is formed in all regions of a peripheral region of the body region and the one side and the other side diffusion regions by penetrating the SOI layer and which has insulation.

3. A semiconductor device according to claim 2, wherein
the one side and the other side silicide films are formed only in a front surface of the one side and the other side diffusion regions.

4. A semiconductor device according to claim 2, wherein
the one side and the other side silicide films are formed from an inside of a front surface of the one side and the other side diffusion regions to a portion in a front surface of the body region, respectively.

5. A semiconductor device according to claim 2, wherein
the body resistance further includes a gate electrode formed via a gate insulating film over the body region.

6. A semiconductor device according to claim 5, further comprising a MOS transistor of a first conductivity type,
wherein the MOS transistor includes
a one side and an other side electrode regions of a first conductivity type selectively formed in the SOI layer;
a body region of a second conductivity type that is formed in the SOI layer and inserted into the one side electrode region and the other side electrode region;
a gate electrode formed via a gate insulating film over the body region; and
a low concentration area of a first conductivity type that adjoins the one side and the other side electrode regions, and is formed in a portion in a front surface of the body region of the gate electrode lower part; wherein the low concentration area is set as predetermined impurity concentration with impurity concentration of a first conductivity type lower than the one side and the other side electrode regions, and impurity concentration of a first conductivity type higher than the body region of the body resistance;
wherein the body region of the body resistance has impurity concentration of a first conductivity type lower than the predetermined impurity concentration in a bottom of the gate electrode of the body resistance, and all its neighboring regions.

7. A semiconductor device according to claim 5, wherein
the body resistance includes a plurality of body resistance; and
the semiconductor device further comprises a plurality of MOS transistors of a second conductivity type;
wherein each of the MOS transistors includes
a well region of a first conductivity type to which element isolation is done in the full isolation region, and which is formed in the SOI layer;
a one side and an other side electrode regions of a second conductivity type selectively formed in an upper layer portion in the well region; and
a gate electrode formed via a gate insulating film over the well region inserted into the one side and the other side electrode regions;
wherein the MOS transistors have two or more sorts of mutually different impurity concentration as impurity concentration of a first conductivity type of the well region; and
the resistor main part of the body resistance of a plurality of is set as a plurality of resistance with the two or more sorts of impurity concentration.

8. A semiconductor device according to claim 1, wherein
a plan view form of the resistor main part assumes a rectangular shape specified by a first and a second length of a first and a second direction, the first length is 10 or more times of a minimum dimension specified at a time of manufacturing process of the semiconductor device, and the second length is more than the first length.

9. A semiconductor device according to claim 5, wherein
the gate electrode of the body resistance includes a polysilicon electrode of a first conductivity type.

10. A semiconductor device which comprises a MOS capacitor formed in an SOI layer of an SOI substrate which has a semiconductor substrate, a buried insulating film formed over the semiconductor substrate, and the SOI layer formed over the buried insulating film,
wherein the MOS capacitor includes
a capacitor electrode region of a first impurity concentration of a first conductivity type formed in the SOI layer; and
a one side and an other side diffusion regions of a first conductivity type which is formed in the SOI layer, and which is formed adjoining one side and other side of a predetermined formation direction of the capacitor electrode region; wherein an impurity concentration of a first conductivity type of the one side and the other side diffusion regions is set up more highly than the first impurity concentration;
further including a gate electrode formed via a gate insulating film over the capacitor electrode region; wherein the MOS capacitor is specified by the gate electrode, the gate insulating film, and the capacitor electrode region;
further including a one side and an other side silicide films which are formed in a front surface of the one side and the other side diffusion regions, and which are mutually independent; and
a full isolation region which is formed in all regions of a peripheral region of the capacitor electrode region and the one side and the other side diffusion regions by penetrating the SOI layer and which has insulation;
wherein the capacitor electrode region has only the first impurity concentration in a region of a bottom of the gate electrode, and its neighboring region.

11. A semiconductor device according to claim 10, wherein
the first impurity concentration of the capacitor electrode region includes an impurity concentration by which a capacitance value is not influenced with a potential given to the gate electrode.

12. A semiconductor device according to claim 10, further comprising a MOS transistor of a first conductivity type,
wherein the MOS transistor includes
a one side and an other side electrode regions of a first conductivity type selectively formed in the SOI layer;
a body region of a second conductivity type which is formed in the SOI layer, and which is inserted into the one side electrode region and the other side electrode region;
a gate electrode formed via a gate insulating film over the body region; and
a low concentration area of a first conductivity type that adjoins the one side and the other side electrode regions, and is formed in a front surface of the body region of the gate electrode lower part; wherein in the low concentration area, an impurity concentration of a first conductivity type is set up lower than the one side and the other side electrode regions.

13. A semiconductor device according to claim 10, wherein
the gate electrode of the MOS capacitor includes a polysilicon electrode of a first conductivity type.

14. A semiconductor device according to claim 1, wherein
the first conductivity type includes an N type.

15. A semiconductor device according to claim 1, wherein
the first conductivity type includes a P type.
